(19) United States
(12) Patent Application Publication
(10) Pub. No.: US 2023/0110947 A1
(43) Pub. Date: Apr. 13, 2023

(54) METAL OXIDE, DEPOSITION METHOD OF METAL OXIDE, AND DEPOSITION APPARATUS FOR METAL OXIDE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Yasuhiro JINBO, Isehara, Kanagawa (JP); Yuji EGI, Atsugi, Kanagawa (JP); Tetsuya KAKEHATA, Isehara, Kanagawa (JP)

(21) Appl. No.: 17/904,015

(22) PCT Filed: Feb. 17, 2021
(86) PCT No.: PCT/IB2021/051306

§ 371 Date: Aug. 11, 2022

(30) Foreign Application Priority Data
Feb. 28, 2020 (JP) 2020-034262

(51) Int. Cl. C23C 16/455; C23C 16/40; C23C 16/46

(52) U.S. Cl. CPC C23C 16/45553; C23C 16/45536; C23C 16/401; C23C 16/45544; C23C 16/46

(57) ABSTRACT

A novel deposition method of a metal oxide is provided. The deposition method includes a first step of supplying a first precursor to a chamber; a second step of supplying a second precursor to the chamber; a third step of supplying a third precursor to the chamber; and a fourth step of introducing an oxidizer into the chamber after the first step, the second step, and the third step. The first to third precursors are different kinds of precursors, and a substrate placed in the chamber in the first to fourth steps is heated to a temperature higher than or equal to 300° C. and lower than or equal to decomposition temperatures of the first to third precursors.

### TECHNICAL FIELD

One embodiment of the present invention relates to a deposition method of a metal oxide and a deposition apparatus for a metal oxide. Another embodiment of the present invention relates to a semiconductor device using the above metal oxide and a manufacturing method of the semiconductor device. Another embodiment of the present invention relates to a semiconductor wafer, a module, and an electronic device.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an imaging device, an electronic device, and the like include a semiconductor device.

Note that one embodiment of the present invention is not limited to the above technical field. One embodiment of the invention disclosed in this specification and the like relates to an object, a method, or a manufacturing method. Another embodiment of the present invention relates to a process, a machine, manufacture, or a composition of matter.

### BACKGROUND ART

A technique by which a transistor is formed using a semiconductor thin film formed over a substrate having an insulating surface has been attracting attention. The transistor is used in a wide range of electronic devices such as an integrated circuit (IC) or an image display device (also simply referred to as a display device). A silicon-based semiconductor material is widely known as a semiconductor thin film applicable to the transistor; in addition, an oxide semiconductor has attracted attention as another material.

A CAAC (c-axis aligned crystalline) structure and an nc (nanocrystalline) structure, which are neither single crystal nor amorphous, have been found in an oxide semiconductor (see Non-Patent Document 1 and Non-Patent Document 2).

Non-Patent Document 1 and Non-Patent Document 2 disclose a technique for manufacturing a transistor using an oxide semiconductor having a CAAC structure.

### REFERENCE

### Non-Patent Document

[Non-Patent Document 1] S. Yamazaki et al., “SID Symposium Digest of Technical Papers”, 2012, volume 43, issue 1, pp. 183-186

[Non-Patent Document 2] S. Yamazaki et al., “Japanese Journal of Applied Physics”, 2014, volume 53, Number 4S, pp. 04ED18-1-04ED18-10

### SUMMARY OF THE INVENTION

### Problems to be Solved by the Invention

An object of one embodiment of the present invention is to provide a novel metal oxide and a deposition method thereof. Another object of one embodiment of the present invention is to provide a deposition apparatus for a novel metal oxide. Another object of one embodiment of the present invention is to provide a semiconductor device with a high on-state current. Another object of one embodiment of the present invention is to provide a semiconductor device with high field-effect mobility. Another object of one embodiment of the present invention is to provide a semiconductor device having favorable reliability. Another object of one embodiment of the present invention is to provide a semiconductor device having favorable electrical characteristics. Another object of one embodiment of the present invention is to provide a semiconductor device that can be miniaturized or highly integrated. Another object of one embodiment of the present invention is to provide a method for manufacturing the above semiconductor device.

Note that the description of these objects does not preclude the existence of other objects. One embodiment of the present invention does not have to achieve all these objects. Other objects will be apparent from the description of the specification, the drawings, the claims, and the like, and other objects can be derived from the description of the specification, the drawings, the claims, and the like.

### Means for Solving the Problems

One embodiment of the present invention is a deposition method of a metal oxide, including a first step of supplying a first precursor to a chamber; a second step of supplying a second precursor to the chamber; a third step of supplying a third precursor to the chamber; and a fourth step of introducing an oxidizer into the chamber after the first step, the second step, and the third step. The first to third precursors are different kinds of precursors, and a substrate placed in the chamber in the first to fourth steps is heated to a temperature higher than or equal to 300° C. and lower than or equal to a lowest temperature among decomposition temperatures of the first to third precursors.

Another embodiment of the present invention is a deposition method of a metal oxide, including a first step of supplying a first precursor to a chamber; a second step of supplying a second precursor to the chamber; a third step of supplying a third precursor to the chamber; and a fourth step of making an oxidizer into a plasma state and introducing the oxidizer into the chamber after the first step, the second step, and the third step. The first to third precursors are different kinds of precursors, and a substrate placed in the chamber in the first to fourth steps is heated to a temperature higher than or equal to 300° C. and lower than or equal to a lowest temperature among decomposition temperatures of the first to third precursors.

In the above, it is preferable that the first precursor contain indium; the second precursor contain an element M (M is one or more of gallium, aluminum, yttrium, and tin); and the third precursor contain zinc.

In the above, it is preferable that the first to third precursors do not contain carbon or hydrogen. In the above, the first to third precursors may contain chlorine.

In the above, it is preferable that performing each of the first to fourth steps one or more times be regarded as one cycle and the one cycle be repeated a plurality of times.

In the above, it is preferable that in the deposition method of a metal oxide containing indium, the element M (M is one or more of gallium, aluminum, yttrium, and tin), and zinc, the first precursor contain indium; the second precursor contain the element M (M is one or more of gallium, aluminum, yttrium, and tin); the third precursor contain zinc; and a ratio of the number of the first steps, the number of the second steps, and the number of the third steps in the one cycle be the same as a ratio of the indium, the element M, and the gallium in the metal oxide.

In the above, it is preferable that after the one cycle is repeated a plurality of times, heat treatment be performed.

Another embodiment of the present invention is a deposition apparatus for a metal oxide, including a chamber; first to fourth source material supply portions; and a heater. The first to fourth source material supply portions are connected to the chamber through valves; the first to third source material supply portions include means for supplying different kinds of precursors; the fourth source material supply portion includes a means for supplying an oxidizer; and the heater includes a means for heating a substrate placed in the chamber to a temperature higher than or equal to 300° C. and lower than or equal to a lowest temperature among decomposition temperatures of the precursors.

Another embodiment of the present invention is a deposition apparatus for a metal oxide, including a chamber; first to fourth source material supply portions; a heater; and a plasma generation apparatus. The first to third source material supply portions are connected to the chamber through valves; the fourth source material supply portion is connected to the chamber through the plasma generation apparatus; the first to third source material supply portions include means for supplying different kinds of precursors; the fourth source material supply portion includes a means for supplying an oxidizer; and the heater includes a means for heating a substrate placed in the chamber to a temperature higher than or equal to 300° C. and lower than or equal to a lowest temperature among decomposition temperatures of the precursors.

In the above, it is preferable that the plasma generation apparatus include a coil connected to a high-frequency power source.

In the above, it is preferable that the first source material supply portion include a means for supplying a precursor containing indium; the second source material supply portion include a means for supplying a precursor containing an element M (M is one or more of gallium, aluminum, yttrium, and tin); and the third source material supply portion include a means for supplying a precursor containing zinc.

In the above, it is preferable that the precursor containing indium, the precursor containing the element M, and the precursor containing zinc do not contain carbon or hydrogen. In the above, the precursor containing indium, the precursor containing the element M, and the precursor containing zinc may contain chlorine.

In the above, it is preferable that a pipe heater covering pipes provided between the first to fourth source material supply portions and the chamber be included.

In the above, it is preferable that a transfer chamber and a treatment chamber be included; the chamber be connected to the treatment chamber through the transfer chamber; the transfer chamber include a means for transferring a substrate from the chamber to the treatment chamber; and the treatment chamber include a heating apparatus.

### Effect of the Invention

One embodiment of the present invention can provide a novel metal oxide and a deposition method thereof. Another embodiment of the present invention can provide a deposition apparatus for a novel metal oxide. Another embodiment of the present invention can provide a semiconductor device with a high on-state current. Another embodiment of the present invention can provide a semiconductor device with high field-effect mobility. Another embodiment of the present invention can provide a semiconductor device having favorable reliability. Another embodiment of the present invention can provide a semiconductor device having favorable electrical characteristics. Another embodiment of the present invention can provide a semiconductor device that can be miniaturized or highly integrated. Another embodiment of the present invention can provide a method for manufacturing the above semiconductor device.

Note that the description of these effects does not preclude the existence of other effects. One embodiment of the present invention does not have to have all these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A to FIG. 1E are cross-sectional views illustrating a method for depositing a metal oxide of one embodiment of the present invention.

FIGS. 2A to 2D are cross-sectional views of metal oxides of embodiments of the present invention.

FIGS. 3A to 3D are cross-sectional views of metal oxides of embodiments of the present invention.

FIG. 4A to FIG. 4C are diagrams illustrating an atomic ratio range of a metal oxide of one embodiment of the present invention.

FIG. 5A to FIG. 5D are cross-sectional views illustrating a method for depositing a metal oxide of one embodiment of the present invention.

FIG. 6A to FIG. 6C are cross-sectional views illustrating a method for depositing a metal oxide of one embodiment of the present invention.

FIG. 7 is a top view and a cross-sectional view illustrating a deposition apparatus.

FIG. 8A and FIG. 8B are cross-sectional views illustrating deposition apparatuses.

FIG. 9A to FIG. 9C are cross-sectional views illustrating deposition apparatuses.

FIG. 10A and FIG. 10B are diagrams illustrating deposition methods of a metal oxide according to one embodiment of the present invention.

FIG. 11A and FIG. 11B are diagrams illustrating deposition methods of a metal oxide according to one embodiment of the present invention.

FIG. 12 is a diagram illustrating a deposition method of a metal oxide according to one embodiment of the present invention.

FIG. 13A is a diagram showing the classification of crystal structures of IGZO. FIG. 13B is a diagram showing an XRD spectrum of a CAAC-IGZO film. FIG. 13C is an image showing a nanobeam electron diffraction pattern of a CAAC-IGZO film.

FIG. 14A is a top view of a semiconductor device of one embodiment of the present invention.

FIG. 14B to FIG. 14D are cross-sectional views of the semiconductor device of one embodiment of the present invention.

FIG. 15A and FIG. 15B are cross-sectional views of a semiconductor device of one embodiment of the present invention.

FIG. 16A is a top view illustrating a method for manufacturing a semiconductor device of one embodiment of the present invention. FIG. 16B to FIG. 16D are cross-sectional views illustrating the method for manufacturing the semiconductor device of one embodiment of the present invention.

FIG. 17A is a top view illustrating the method for manufacturing the semiconductor device of one embodiment of the present invention. FIG. 17B to FIG. 17D are cross-sectional views illustrating the method for manufacturing the semiconductor device of one embodiment of the present invention.

FIG. 18A is a top view illustrating the method for manufacturing the semiconductor device of one embodiment of the present invention. FIG. 18B to FIG. 18D are cross-sectional views illustrating the method for manufacturing the semiconductor device of one embodiment of the present invention.

FIG. 19A is a top view illustrating the method for manufacturing the semiconductor device of one embodiment of the present invention. FIG. 19B to FIG. 19D are cross-sectional views illustrating the method for manufacturing the semiconductor device of one embodiment of the present invention.

FIG. 20A is a top view illustrating the method for manufacturing the semiconductor device of one embodiment of the present invention. FIG. 20B to FIG. 20D are cross-sectional views illustrating the method for manufacturing the semiconductor device of one embodiment of the present invention.

FIG. 21A is a top view illustrating the method for manufacturing the semiconductor device of one embodiment of the present invention. FIG. 21B to FIG. 21D are cross-sectional views illustrating the method for manufacturing the semiconductor device of one embodiment of the present invention.

FIG. 22A is a top view illustrating the method for manufacturing the semiconductor device of one embodiment of the present invention. FIG. 22B to FIG. 22D are cross-sectional views illustrating the method for manufacturing the semiconductor device of one embodiment of the present invention.

FIG. 23A is a top view illustrating the method for manufacturing the semiconductor device of one embodiment of the present invention. FIG. 23B to FIG. 23D are cross-sectional views illustrating the method for manufacturing the semiconductor device of one embodiment of the present invention.

FIG. 24A is a top view illustrating the method for manufacturing the semiconductor device of one embodiment of the present invention. FIG. 24B to FIG. 24D are cross-sectional views illustrating the method for manufacturing the semiconductor device of one embodiment of the present invention.

FIG. 25A is a top view illustrating the method for manufacturing the semiconductor device of one embodiment of the present invention. FIG. 25B to FIG. 25D are cross-sectional views illustrating the method for manufacturing the semiconductor device of one embodiment of the present invention.

FIG. 26 is a top view illustrating a microwave treatment apparatus of one embodiment of the present invention.

FIG. 27 is a cross-sectional view illustrating a microwave treatment apparatus of one embodiment of the present invention.

FIG. 28 is a cross-sectional view illustrating a microwave treatment apparatus of one embodiment of the present invention.

FIG. 29 is a cross-sectional view illustrating a microwave treatment apparatus of one embodiment of the present invention.

FIG. 30A is a top view of a semiconductor device of one embodiment of the present invention.

FIG. 30B and FIG. 30C are cross-sectional views of the semiconductor device of one embodiment of the present invention.

FIG. 31 is a cross-sectional view illustrating a structure of a storage device of one embodiment of the present invention.

FIG. 32 is a cross-sectional view illustrating a structure of a storage device of one embodiment of the present invention.

FIG. 33 is a cross-sectional view of a semiconductor device of one embodiment of the present invention.

FIG. 34A and FIG. 34B are cross-sectional views of a semiconductor device of one embodiment of the present invention.

FIG. 35 is a cross-sectional view of a semiconductor device of one embodiment of the present invention.

FIG. 36A and FIG. 36B are block diagrams illustrating structure examples of a storage device of one embodiment of the present invention.

FIG. 37A to FIG. 37H are circuit diagrams illustrating structure examples of storage devices of embodiments of the present invention.

FIG. 38A and FIG. 38B are schematic views of semiconductor devices of embodiments of the present invention.

FIG. 39A and FIG. 39B are diagrams illustrating examples of electronic components.

FIG. 40A to FIG. 40E are schematic views of storage devices of embodiments of the present invention.

FIG. 41A to FIG. 41H are diagrams illustrating electronic devices of embodiments of the present invention.

### MODE FOR CARRYING OUT THE INVENTION

Hereinafter, embodiments will be described with reference to the drawings. Note that the embodiments can be implemented with many different modes, and it is readily understood by those skilled in the art that modes and details thereof can be changed in various ways without departing from the spirit and scope thereof. Thus, the present invention should not be interpreted as being limited to the description of the embodiments below.

In the drawings, the size, the layer thickness, or the region is exaggerated for clarity in some cases. Therefore, they are not limited to the illustrated scale. Note that the drawings schematically illustrate ideal examples, and embodiments of the present invention are not limited to shapes, values, and the like shown in the drawings. For example, in the actual manufacturing process, a layer, a resist mask, or the like might be unintentionally reduced in size by treatment such as etching, which might not be reflected in the drawings for easy understanding of the invention. Furthermore, in the drawings, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases.

Furthermore, especially in a top view (also referred to as a “plan view”), a perspective view, or the like, the description of some components might be omitted for easy understanding of the invention. In addition, some hidden lines and the like might not be shown.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

In this specification and the like, terms for describing arrangement, such as “over” and “under”, are used for convenience to describe the positional relation between components with reference to drawings. The positional relation between components is changed as appropriate in accordance with a direction in which the components are described. Thus, without limitation to terms described in this specification, the description can be changed appropriately depending on the situation.

For example, when this specification and the like explicitly state that X and Y are connected, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or text, a connection relation other than one shown in drawings or text is regarded as being disclosed in the drawings or the text. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of current is changed in circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where current flows in a semiconductor when a transistor is in an on state) and a gate electrode overlap with each other or a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, and the average value in a channel formation region.

The channel width refers to, for example, the length of a channel formation region in a direction perpendicular to a channel length direction in a region where a semiconductor (or a portion where current flows in a semiconductor when a transistor is in an on state) and a gate electrode overlap with each other, or a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, and the average value in a channel formation region.

Note that in this specification and the like, depending on the transistor structure, a channel width in a region where a channel is actually formed (hereinafter also referred to as an “effective channel width”) is sometimes different from a channel width shown in a top view of a transistor (hereinafter also referred to as an “apparent channel width”). For example, in a transistor whose gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is increased in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that values of a channel length, a channel width, an effective channel width, an apparent channel width, and the like can be determined, for example, by analyzing a cross-sectional TEM image and the like.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases or the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (referred to as V_{O} in some cases) are formed in an oxide semiconductor in some cases by entry of impurities, for example.

Note that in this specification and the like, an oxynitride is a material that contains more oxygen than nitrogen in its composition. For example, silicon oxynitride contains more oxygen than nitrogen in its composition. Moreover, a nitride oxide is a material that contains more nitrogen than oxygen in its composition. For example, silicon nitride oxide contains more nitrogen than oxygen in its composition.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be called a transistor including a metal oxide or an oxide semiconductor.

Note that in this specification and the like, a metal oxide containing nitrogen is also collectively referred to as a metal oxide in some cases. A metal oxide containing nitrogen may be referred to as a metal oxynitride.

In this specification and the like, “normally off” means that a drain current per micrometer of channel width flowing through a transistor when no potential is applied to a gate or the gate is supplied with a ground potential is 1×10⁻²⁰ A or lower at room temperature, 1×10⁻¹⁸ A or lower at 85° C., or 1×10⁻¹⁶ A or lower at 125° C.

In this specification and the like, in the case where the maximum value and the minimum value are specified, a structure in which the maximum value and the minimum value are freely combined is disclosed.

### Embodiment 1

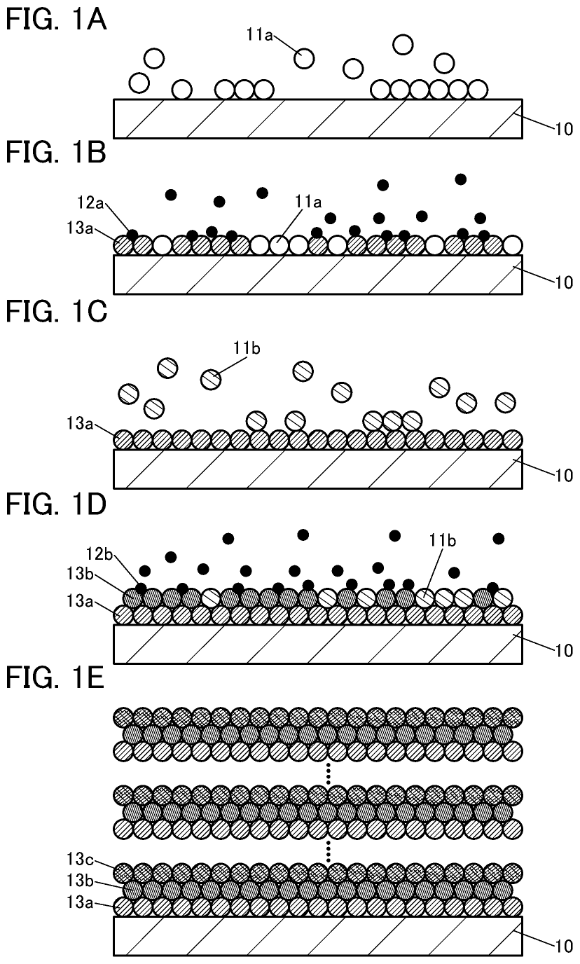

In this embodiment, a metal oxide (hereinafter, also referred to as an oxide semiconductor or an oxide in some cases) that can be used for a semiconductor layer of a transistor and a deposition method thereof are described with reference to FIG. 1 to FIG. 12. Note that a metal oxide of one embodiment of the present invention is used for not only a semiconductor layer of a transistor but also an insulating material or a conductive material depending on the kind, combination, composition, or the like of constituent elements of the metal oxide.

A metal oxide has a lattice defect in some cases. Examples of the lattice defect include point defects such as an atomic vacancy and an exotic atom, linear defects such as transition, plane defects such as a grain boundary, and volume defects such as a cavity. The lattice defect is generated due to a deviation of the proportion of the number of constituent element atoms (excess or deficiency of constituent atoms), an impurity, and the like.

When a metal oxide is used for a semiconductor layer of a transistor, a lattice defect in the metal oxide might cause generation, capture, or the like of a carrier. Thus, when a metal oxide with a large number of lattice defects is used for a semiconductor layer of a transistor, the electrical characteristics of the transistor might be unstable. Therefore, a metal oxide used for a semiconductor layer of a transistor preferably has a small number of lattice defects.

A transistor using a metal oxide is likely to change its electrical characteristics especially in the case where oxygen vacancies (V_{O}) and impurities exist in a region of the metal oxide where a channel is formed, which might degrade the reliability. In some cases, hydrogen in the vicinity of an oxygen vacancy forms a defect that is an oxygen vacancy into which hydrogen enters (hereinafter, sometimes referred to as a V_{O}H defect), which generates an electron serving as a carrier. Therefore, when the channel formation region in the metal oxide includes oxygen vacancies, the transistor is likely to have normally-on characteristics (characteristics with which, even when no voltage is applied to the gate electrode, the channel exists and current flows through the transistor). Therefore, oxygen vacancies and impurities are preferably reduced as much as possible in the channel formation region in the metal oxide. In other words, the metal oxide preferably includes an i-type (intrinsic) or substantially i-type channel formation region with a low carrier concentration.

The kind of a lattice defect that is likely to exist in a metal oxide and the number of lattice defects that exist vary depending on the structure of the metal oxide, a method for depositing the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. An a-like structure has a structure between an nc structure and an amorphous structure. Note that the classification of crystal structures will be described later.

A metal oxide having an a-like structure and a metal oxide having an amorphous structure each include a void or a low-density region. That is, a metal oxide having an a-like structure and a metal oxide having an amorphous structure each have low crystallinity compared with a metal oxide having an nc structure and a metal oxide having a CAAC structure. Moreover, a metal oxide having an a-like structure has higher hydrogen concentration in the metal oxide than a metal oxide having an nc structure and a metal oxide having a CAAC structure. Thus, a lattice defect is likely to be generated in a metal oxide having an a-like structure and a metal oxide having an amorphous structure.

Therefore, a metal oxide with high crystallinity is preferably used for a semiconductor layer of a transistor. For example, a metal oxide having a CAAC structure or a metal oxide having a single crystal structure is preferably used. The use of the metal oxide for a transistor enables a transistor having favorable electrical characteristics. In addition, a transistor having high reliability can be fabricated.

Note that the metal oxide with high crystallinity does not include a metal oxide having a polycrystalline structure. A polycrystalline structure is a crystal structure in which a clear grain boundary is observed. In the case where a metal oxide having a polycrystalline structure is used for a semiconductor layer of a transistor, it is highly probable that the grain boundary becomes a recombination center and captures carriers and thus decreases the on-state current and field-effect mobility of a transistor, for example.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS which is described later, and the like.

The c-axis of the above crystal is preferably aligned in the normal direction with respect to the formation surface or film surface of the metal oxide. This enables the plurality of layers to be placed substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

The metal oxide preferably contains at least indium or zinc. It is particularly preferable that indium and zinc be contained. In addition to them, a metal element with the same valence as that of indium or zinc is preferably contained. Examples of the metal element are aluminum, gallium, yttrium, and the like. One or more kinds selected from iron, cobalt, nickel, lanthanum, cerium, neodymium, magnesium, calcium, and the like may be contained.

Here, the case where the oxide semiconductor is an In-M-Zn oxide that contains indium (In), an element M, and zinc (Zn) is considered. The element M is aluminum, gallium, yttrium, or the like. Examples of other elements that can be used as the element M include iron, cobalt, nickel, lanthanum, cerium, neodymium, magnesium, and calcium. Note that two or more of the above-described elements may be used in combination as the element M.

For the formation of a metal oxide having the layered crystal structure, atoms are preferably deposited for each layer. For example, an ALD (Atomic Layer Deposition) method can be used as the formation method of the metal oxide.

In an ALD method, one atomic layer can be deposited at a time using self-regulating characteristics of precursor molecules or atoms contained in the precursor. Hence, an ALD method has effects such as deposition of an extremely thin film, deposition of a film on a component with a high aspect ratio, deposition of a film with a small number of defects such as pinholes, deposition of a film with excellent coverage, and deposition of a film at a low temperature. An ALD method includes a plasma ALD (PEALD: Plasma Enhanced ALD) method, which is a deposition method using plasma. The use of plasma is sometimes preferable because deposition at a lower temperature is possible. Note that a precursor used in an ALD method sometimes contains an element such as carbon or chlorine. Thus, in some cases, a film provided by an ALD method contains a larger amount of an element such as carbon or chlorine than a film provided by another deposition method. Note that these elements can be quantified by X-ray photoelectron spectroscopy (XPS).

Unlike a deposition method in which particles ejected from a target or the like are deposited, an ALD method is a deposition method in which a film is formed by reaction at a surface of an object. Thus, an ALD method is a deposition method that enables favorable step coverage almost regardless of the shape of an object to be processed. In particular, an ALD method has excellent step coverage and excellent thickness uniformity and thus is suitable for covering a surface of an opening portion with a high aspect ratio, for example. On the other hand, an ALD method has a relatively low deposition rate, and thus is preferably used in combination with another deposition method with a high deposition rate, such as a CVD method, in some cases.

When an ALD method is employed, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film in which the composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is omitted. Thus, the productivity of the semiconductor device can be increased in some cases.

### <Deposition Method Using ALD Apparatus and ALD Method>

Here, a deposition apparatus employing an ALD method (hereinafter, also referred to as an ALD apparatus) which can be used for forming the metal oxide of one embodiment of the present invention and a deposition method employing an ALD method are described.

In a deposition apparatus employing an ALD method, deposition is performed in such a manner that a first source gas (also referred to as a precursor or a metal precursor in some cases) and a second source gas (also referred to as a reactant, an oxidizer, or a nonmetallic precursor in some cases) are alternately introduced into a chamber for reaction, and then the introduction of these source gases is repeated. Note that the source gases to be introduced can be switched by switching the respective switching valves (also referred to as high-speed valves in some cases), for example. When the source gases are introduced, an inert gas such as nitrogen (N₂), argon (Ar), or helium (He) may be introduced as a carrier gas with the source gases into the chamber. With the use of a carrier gas, the source gases can be inhibited from being adsorbed onto an inner side of a pipe and an inner side of a valve and can be introduced into the chamber, even in the case where the volatility of the source gases is low or the vapor pressure is low. Moreover, uniformity of the formed film is improved, which is preferable.

An example of a method employing an ALD method for depositing a metal oxide having the layered crystal structure including three layers is described with reference to FIG. lA to FIG. 1E. First, precursors 11a are introduced into a chamber and the precursors 11a are adsorbed onto a surface of a substrate 10 (see FIG. 1A; hereinafter, the step is referred to as a first step in some cases). Here, as illustrated in FIG. 1A, the precursor 11a is adsorbed onto the surface of the substrate 10, whereby a self-limiting mechanism of surface chemical reaction works and no more precursor 11a is adsorbed onto a layer of the precursor 11a over the substrate 10. Note that the proper range of substrate temperatures at which the self-limiting mechanism of surface chemical reaction works is also referred to as an ALD Window. The ALD Window is determined by the temperature characteristics, vapor pressure, decomposition temperature, and the like of a precursor and is sometimes set to higher than or equal to 100° C. and lower than or equal to 600° C., preferably higher than or equal to 200° C. and lower than or equal to 400° C., for example.

Next, an inert gas (e.g., argon, helium, or nitrogen) or the like is introduced into the chamber, so that excess precursors 11a, a reaction product, and the like are released from the chamber (hereinafter, the step is referred to as a second step in some cases). Instead of introduction of an inert gas into the chamber, vacuum evacuation may be performed to release excess precursors, a reaction product, and the like from the chamber. The second step is also called purge.

Next, a reactant 12a (e.g., an oxidizer (ozone (O₃), oxygen (O₂), water (H₂O), and plasma, a radical, and an ion thereof)) is introduced into the chamber to react with the precursor 11a adsorbed onto the surface of the substrate 10, whereby part of components contained in the precursor 11a is released while the component molecules of the precursor 11a are kept adsorbed onto the substrate 10 (see FIG. 1B; hereinafter, the step is referred to as a third step in some cases). Thus, a layer of an oxide 13a, which is formed by oxidation of part of the precursor 11a, is formed on the surface of the substrate 10.

In the case where a plasma ALD method is employed, oxygen may be constantly supplied as an oxidizer and plasma may be generated in the third step. Accordingly, in the third step, oxygen plasma is formed and serves as the reactant 12a. In this case, the precursor 11a that does not react with oxygen that has been heated to the above temperature is used in a step other than the third step.

Next, introduction of an inert gas or vacuum evacuation is performed, whereby an excess reactant 12a, a reaction product, and the like are released from the chamber (hereinafter, the step is referred to as a fourth step in some cases).

Then, a precursor 11b containing a metal element different from that in the precursor 11 a is introduced and a step similar to the first step is performed, so that the precursor 11b is adsorbed onto a surface of the layer of the oxide 13a (see FIG. 1C). Here, as illustrated in FIG. 1C, the precursor 11b is adsorbed onto the layer of the oxide 13a, whereby a self-limiting mechanism of surface chemical reaction works and no more precursor 11b is adsorbed onto a layer of the precursor 11b over the substrate 10.

Next, as in the second step, introduction of an inert gas or vacuum evacuation is performed, whereby an excess precursor 11b, a reaction product, and the like are released from the chamber.

Next, as in the third step, the reactant 12b is introduced into the chamber. Here, the reactant 12b that is the same as or different from the reactant 12a may be used (see FIG. 1D). Thus, a layer of an oxide 13b, which is formed by oxidation of part of the precursor 11 b, is formed over the layer of the oxide 13a.

Then, as in the fourth step, introduction of an inert gas or vacuum evacuation is performed, whereby an excess reactant 12b, a reaction product, and the like are released from the chamber.

Furthermore, the first to fourth steps are performed in a similar manner, whereby a layer of an oxide 13c can be formed over the layer of the oxide 13b. As described above, by performing the steps for forming the oxide 13a to the oxide 13c repeatedly, a metal oxide having a layered crystal structure in which the stacked-layer structure including the oxide 13a to the oxide 13c is repeated can be formed (see FIG. 1E). That is, an oxide layer can be formed through the first to fourth steps, which are regarded as one set, and by repeating the set, a layered crystal structure in which a plurality of oxide layers are stacked can be formed.

In the formation of a metal oxide having a layered crystal structure, specifically, a metal oxide having the CAAC structure, it is preferable that the steps illustrated in FIG. 1 be performed while the substrate is being heated. The substrate temperature is higher than or equal to 200° C. and lower than or equal to 600° C., preferably higher than or equal to 300° C. and lower than or equal to the precursor decomposition temperature. In the case where deposition is performed by an ALD method with use of different kinds of precursors, the substrate temperature is preferably lower than or equal to the lowest precursor decomposition temperature among the precursors. Accordingly, during deposition by an ALD method, the precursors that are used can be adsorbed onto an object (e.g., a substrate) without being decomposed.

By performing the deposition while the substrate is being heated in such a temperature range, an impurity such as hydrogen or carbon contained in the precursor, the reactant, or the like can be removed from the metal oxide in each of the step 1 to the step 4. For example, carbon in the metal oxide can be released as CO₂ and CO, and hydrogen in the metal oxide can be released as H₂O. Furthermore, metal atoms and oxygen atoms are rearranged concurrently with removal of the impurity, so that layers of oxides can be arranged orderly. Thus, a metal oxide having a layered crystal structure with high crystallinity, specifically, a metal oxide having a CAAC structure can be formed. Note that FIG. 1A shows an example in which the precursor 11a is formed over the substrate 10; however, the present invention is not limited thereto. For example, an insulating film (an insulating film containing oxygen, nitrogen, silicon, aluminum, hafnium, or the like), a conductive film (a conductive film containing tungsten, tantalum, molybdenum, zirconium, aluminum, titanium, or the like), or the like may be provided over the substrate 10 and the precursor 11a may be formed thereover. Alternatively, the precursor 11a may be formed over a component formed using an insulating film, a conductive film, and the like over the substrate 10.

In order to perform deposition while the substrate is being heated in the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, a precursor formed of an inorganic material (hereinafter, referred to as an inorganic precursor) is preferably used. In general, an inorganic precursor tends to have a higher decomposition temperature than a precursor formed of an organic material (hereinafter, referred to as an organic precursor); thus, some inorganic precursors have the ALD Window in the above temperature range. Moreover, an inorganic precursor does not contain an impurity such as hydrogen or carbon, which can prevent an increase in the concentration of an impurity such as hydrogen or carbon in a metal oxide to be deposited.

Furthermore, after the deposition of the metal oxide, heat treatment is preferably performed. In particular, the heat treatment is preferably performed without exposure to the air successively after the deposition by an ALD method. The heat treatment is performed at a temperature higher than or equal to 100° C. and lower than or equal to 1200° C., preferably higher than or equal to 200° C. and lower than or equal to 1000° C., further preferably higher than or equal to 250° C. and lower than or equal to 650° C., still further preferably higher than or equal to 300° C. and lower than or equal to 600° C., still further preferably higher than or equal to 400° C. and lower than or equal to 550° C., still further preferably higher than or equal to 420° C. and lower than or equal to 480° C. Note that the heat treatment is performed in a nitrogen gas or inert gas atmosphere, or an atmosphere containing an oxidizing gas at 10 ppm or more, 1% or more, or 10% or more. The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. In the case where the temperature of the heat treatment is high, the metal oxide may have a polycrystalline structure; thus, the temperature of the heat treatment is set as appropriate within a range where the metal oxide does not have a polycrystalline structure.

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which improves crystallinity. Thus, a metal oxide having a layered crystal structure with high crystallinity, specifically, a metal oxide having the CAAC structure can be formed.

Note that FIG. 1 illustrates the structure in which the stacked-layer structure including the oxide 13a to the oxide 13c is repeated; however, the present invention is not limited thereto. For example, a single layer, two layers, or four or more layers of an oxide may be repeatedly formed in a metal oxide. In FIG. 1, the oxide 13a, the oxide 13b, and the oxide 13c are repeatedly stacked without changing the order; however, the present invention is not limited thereto. For example, the order of the oxide 13a, the oxide 13b, and the oxide 13c may be changed. Alternatively, the compositions of the oxide 13a, the oxide 13b, and the oxide 13c may be changed in the film. In FIG. 1, different oxide layers are provided to be adjacent to each other in the order of the oxide 13a, the oxide 13b, and the oxide 13c; however, the present invention is not limited thereto. A structure may be employed in which the same oxide layers are successively provided in the order of, for example, the oxide 13a, the oxide 13a, the oxide 13b, the oxide 13b, the oxide 13c, and the oxide 13c.

In the following description of this specification, in the case of using ozone, oxygen, and water as a reactant or an oxidizer, they include not only those in gas and molecular states but also those in a plasma state, a radical state, and an ion state, unless otherwise specified. In the case where a film is deposited using an oxidizer in a plasma state, a radical state, or an ion state, a radical ALD apparatus or a plasma ALD apparatus, which will be described later, is used.

In order to remove an impurity such as carbon or hydrogen contained in a precursor, the precursor is preferably made to react with an oxidizer sufficiently. For example, pulse time for introducing an oxidizer is made longer. Alternatively, an oxidizer is introduced a plurality of times. In the case where an oxidizer is introduced a plurality of times, the same kind of oxidizer may be introduced or different kinds of oxidizers may be introduced. For example, after water is introduced as a first oxidizer to the chamber, vacuum evacuation may be performed, ozone or oxygen which does not contain hydrogen may be introduced as a second oxidizer to the chamber, and vacuum evacuation may be performed.

Note that in the above description, an example in which the second source gas is introduced into the chamber after the first source gas is introduced into the chamber is shown; however, the present invention is not limited thereto. The first source gas may be introduced into the chamber after the second source gas is introduced into the chamber. In other words, deposition may be performed in such a manner that the third step and the fourth step are performed first, the first step, the second step, the third step, and the fourth step are performed, and then the first step to the fourth step are repeated. Alternatively, deposition may be performed in such a manner that the third step and the fourth step are repeated a plurality of times, and then the first step to the fourth step are repeated.

In this manner, the third step and the fourth step are preferably performed once or more before the first step because the deposition atmosphere in the chamber can be controlled. For example, O₃ and O₂ are introduced as oxidizers in the third step, so that the chamber can have an oxygen atmosphere. Deposition performed in the chamber having an oxygen atmosphere is preferable because the formed film can have a high concentration of oxygen. Furthermore, oxygen can also be supplied to the insulator and the oxide that are to be bases of the film. A semiconductor device formed by such a method can have favorable characteristics and obtain high reliability. Moreover, for example, introduction of water as an oxidizer in the third step can form a hydrophilic group on the formation surface. Accordingly, the precursor can have a much improved adsorption property.

After the first step and the second step, introduction of the second source gas in the third step and vacuum evacuation or introduction of an inert gas in the fourth step may be repeated a plurality of times. That is, after the first step, the second step, the third step, the fourth step, the third step, and the fourth step are performed, that is, after the third step and the fourth step are repeated, the first step and the second step may be performed.

For example, O₃ and O₂ are introduced as oxidizers in the third step, introduction of an inert gas is performed in the fourth step, and then these steps may be repeated a plurality of times. In the case where the third step and the fourth step are repeated, it is not necessary to repeat the introduction of the same kind of source gas. For example, H₂O may be used as an oxidizer in the third step in the first cycle, and O₃ may be used as an oxidizer in the third steps in and after the second cycle.

In this manner, the introduction of an oxidizer and the introduction of an inert gas (or vacuum evacuation) in the chamber are repeated a plurality of times in a short time, whereby excess hydrogen atoms, carbon atoms, chlorine atoms, and the like can be more certainly removed from the precursor adsorbed onto the substrate surface, and can be released to the outside of the chamber. When the number of the kinds of the oxidizer is increased to two, more excess hydrogen atoms and the like can be removed from the precursor adsorbed onto the substrate surface. In this manner, hydrogen atoms are prevented from being taken into the film during the deposition, so that water, hydrogen, and the like contained in the formed film can be reduced.

With the use of such a method, it is possible to form a film of which the released amount of water molecules is greater than or equal to 1.0×10¹³ molecules/cm² and less than or equal to 1.0×10¹⁶ molecules/cm², preferably greater than or equal to 1.0×10¹³ molecules/cm² and less than or equal to 3.0×10¹⁵ molecule/cm² in TDS analysis in a film-surface temperature range from 100° C. to 700° C. or from 100° C. to 500° C.

An ALD method is a method in which deposition is performed through reaction of a precursor and a reactant using thermal energy. A temperature required for the reaction between the precursor and the reactant is determined by the temperature characteristics, vapor pressure, decomposition temperature, and the like thereof and is set to higher than or equal to 100° C. and lower than or equal to 600° C., preferably higher than or equal to 200° C. and lower than or equal to 600° C., further preferably higher than or equal to 300° C. and lower than or equal to 600° C.

Moreover, an ALD method in which treatment is performed by introducing a plasma-excited reactant into the chamber as a third source gas in addition to the precursor and the reactant which react with each other is referred to as a plasma ALD method in some cases. In this case, a plasma generation apparatus is provided in the introduction portion of the third source gas. Inductively coupled plasma (ICP) can be used for plasma generation. On the other hand, an ALD method in which reaction between the precursor and the reactant is performed using thermal energy is sometimes referred to as a thermal ALD method.

In a plasma ALD method, deposition is performed by introducing a plasma-excited reactant in the third step. Alternatively, deposition is performed in such a manner that the first step to the fourth step are repeated while a plasma-excited reactant (a second reactant) is introduced. In this case, the reactant introduced in the third step is referred to as a first reactant. In the plasma ALD method, the same material as the above-described oxidizer can be used for the second reactant used as the third source gas. In other words, plasma-excited ozone, oxygen, and water can be used as the second reactant. Other than oxidizer, a nitriding agent may be used as the second reactant. As the nitriding agent, nitrogen (N₂) or ammonia (NH₃) can be used. A mixed gas of nitrogen (N₂) and hydrogen (H₂) can also be used as the nitriding agent. For example, a mixed gas of nitrogen (N₂) of 5% and hydrogen (H₂) of 95% can be used as the nitriding agent. Deposition is performed while plasma-excited nitrogen or ammonia is introduced, whereby a nitride film such as a metal nitride film can be formed.

Argon (Ar), helium (He), or nitrogen (N₂) may be used as a carrier gas for the second reactant. The use of a carrier gas such as argon, helium, or nitrogen is preferable because plasma is easily discharged and the plasma-excited second reactant is easily generated. Note that in the case where an oxide film such as a metal oxide film is formed by a plasma ALD method and nitrogen is used as a carrier gas, nitrogen enters the film and a desired film quality cannot be obtained in some cases. In this case, argon or helium is preferably used as the carrier gas.

By an ALD method, an extremely thin film can be deposited to have a uniform thickness. In addition, the coverage of a surface having projections and depressions with the film is high.

When deposition is performed by a plasma ALD method, deposition can be performed at a lower temperature than that by a thermal ALD method. By a plasma ALD method, for example, deposition can be performed without decreasing the deposition rate even at 100° C. or lower in some cases. Furthermore, in a plasma ALD method, not only an oxidizer but also any of a variety of reactants such as a nitriding agent can be used; therefore, it is possible to form various kinds of films of a nitride, a fluoride, a metal, and the like as well as an oxide.

In the case where a plasma ALD method is employed, by generating plasma while a plasma source for inductively coupled plasma (ICP), electron cyclotron resonance plasma (ECR), or the like is apart from a substrate, plasma damage can be reduced.

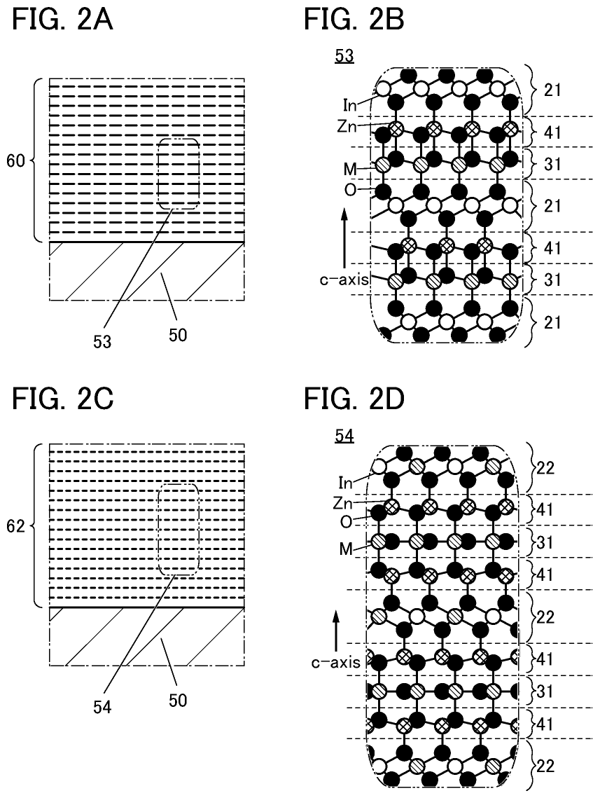

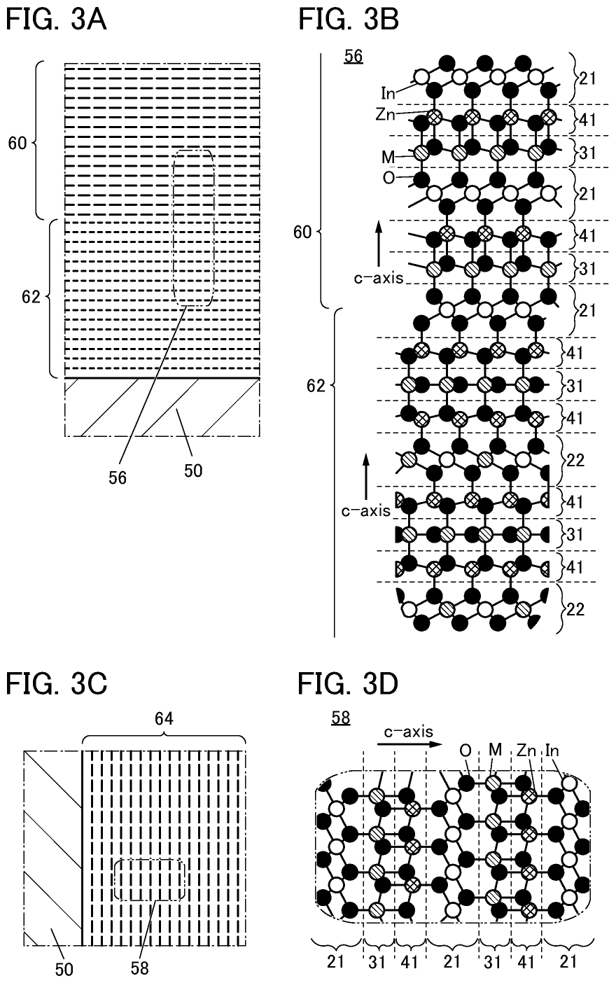

Here, atomic arrangement in the crystal when the metal oxide having a layered crystal structure is an In-M-Zn oxide is described with reference to FIG. 2A to FIG. 3D. In FIG. 2B, FIG. 2D, FIG. 3B, and FIG. 3D, an atom is represented by a sphere (a circle) and a bond between a metal atom and an oxygen atom is represented by a line. In FIG. 2B, FIG. 2D, FIG. 3B, and FIG. 3D, the c-axis direction in the crystal structure of the In-M-Zn oxide is indicated by the arrows in the drawings. The a-b plane direction in the crystal structure of the In-M-Zn oxide is the direction perpendicular to the c-axis direction indicated by the arrows in FIG. 2B, FIG. 2D, FIG. 3B, and FIG. 3D.

FIG. 2A is a diagram illustrating an oxide 60 including an In-M-Zn oxide formed on a structure body 50. Here, the structure body refers to a component included in a semiconductor device such as a transistor. The structure body 50 includes a substrate, conductors such as a gate electrode, a source electrode, and a drain electrode, an insulator such as a gate insulating film, an interlayer insulating film, and a base insulating film, a semiconductor such as a metal oxide or silicon, and the like. In FIG. 2A, a deposition surface of the structure body 50 is placed parallel to a substrate (or a base, not illustrated).

FIG. 2B is an enlarged view illustrating the atomic arrangement in the crystal in a region 53, which is part of the oxide 60 in FIG. 2A. The composition of the oxide 60 illustrated in FIG. 2A and FIG. 2B is In:M:Zn=1:1:1 [atomic ratio], and the crystal structure is a YbFe₂O₄ type structure. The element M is a metal element having a valence of +3.

As illustrated in FIG. 2B, the crystal included in the oxide 60 has repetitive stacking of a layer 21 containing indium (In) and oxygen, a layer 31 containing the element M and oxygen, and a layer 41 containing zinc (Zn) and oxygen in this order. The layer 21, the layer 31, and the layer 41 are placed substantially parallel to the deposition surface of the structure body 50. That is, the a-b plane of the oxide 60 is substantially parallel to the deposition surface of the structure body 50, and the c-axis of the oxide 60 is substantially parallel to the normal direction of the deposition surface of the structure body 50.

When the layer 21, the layer 31, and the layer 41 included in the above crystal are each composed of one metal element and oxygen as illustrated in FIG. 2B, arrangement with favorable crystallinity is achieved to increase the mobility of the metal oxide.

Note that the In-M-Zn oxide with In:M:Zn=1:1:1 [atomic ratio] is not limited to the structure illustrated in FIG. 2B. The stacking order of the layer 21, the layer 31, and the layer 41 may be changed. For example, the layer 21, the layer 41, and the layer 31 may be stacked repeatedly in this order. Alternatively, the layer 21, the layer 31, the layer 41, the layer 21, the layer 41, and the layer 31 may be stacked repeatedly in this order. Part of the element M in the layer 31 may be substituted by zinc and part of zinc in the layer 41 may be substituted by the element M.

Although an example of forming the In-M-Zn oxide whose composition is In:M:Zn=1:1:1 [atomic ratio] is described above, a crystalline In-M-Zn oxide whose composition formula is represented by In_{(1+α)}M_{(1-α)}O₃(ZnO)ₘ (α is a real number greater than 0 and less than 1 and m is a positive number) can have a layered crystal structure in a similar manner. As an example, an In-M-Zn oxide with In:M:Zn=1:3:4 [atomic ratio] is described with reference to FIG. 2C and FIG. 2D.

FIG. 2C is a diagram illustrating an oxide 62 including an In-M-Zn oxide formed on the structure body 50. FIG. 2D is an enlarged view illustrating the atomic arrangement in the crystal in a region 54, which is part of the oxide 62 in FIG. 2C.

As illustrated in FIG. 2D, the crystal included in the oxide 62 includes a layer 22 containing indium (In), the element M, and oxygen, the layer 41 containing zinc (Zn) and oxygen, and the layer 31 containing the element M and oxygen. In the oxide 62, the plurality of layers are stacked repeatedly in the order of the layer 22, the layer 41, the layer 31, and the layer 41. The layer 22, the layer 31, and the layer 41 are placed substantially parallel to the deposition surface of the structure body 50. That is, the a-b plane of the oxide 62 is substantially parallel to the deposition surface of the structure body 50, and the c-axis of the oxide 62 is substantially parallel to the normal direction of the deposition surface of the structure body 50.

Note that the In-M-Zn oxide with In:M:Zn=1:3:4 [atomic ratio] is not limited to the structure illustrated in FIG. 2D, and the structure may change within a range where In:M:Zn=1:3:4 [atomic ratio] is maintained. The stacking order of the layer 22, the layer 31, and the layer 41 may be changed, for example. Part of the element M in the layer 31 may be substituted by zinc and part of zinc in the layer 41 may be substituted by the element M. The layer 21 or the layer 31 may be formed instead of the layer 22.

Alternatively, as illustrated in FIG. 3A, a stacked-layer structure may be employed in which the oxide 62 is formed over the structure body 50 and the oxide 60 is formed thereover. Here, FIG. 3B is an enlarged view illustrating the atomic arrangement in the crystal in a region 56, which is part of the oxide 62 and the oxide 60 in FIG. 3A.

As described above, the oxide 62 is an In-M-Zn oxide with In:M:Zn=1:3:4 [atomic ratio], and the oxide 60 is an In-M-Zn oxide with In:M:Zn=1:1:1 [atomic ratio]. That is, the oxide illustrated in FIG. 3A is an oxide film in which the atomic ratio changes in the film. Furthermore, when the oxide 62 has a layered crystal structure as illustrated in FIG. 3B, the crystallinity of the oxide 60 over the oxide 62 can be favorable.

Note that the oxide 62 and the oxide 60 are not limited to the structure illustrated in FIG. 3B, and the structures of the oxide 62 and the oxide 60 may be changed as described above. The layer 21 is placed at the boundary between the oxide 62 and the oxide 60 in FIG. 3B; however, the present invention is not limited thereto. For example, the layer 22 may be formed at the boundary between the oxide 62 and the oxide 60.

As described above, an ALD method enables deposition of a film on a component with a large aspect ratio and also enables deposition of a film with excellent coverage on a side surface of a structure body. By employing an ALD method, a metal oxide having crystallinity classified as a CAAC structure or the like can be easily formed regardless of the orientation of the deposition surface. For example, a metal oxide with favorable coverage can be formed on a top surface, a bottom surface, a side surface, and a surface with a slope of a structure body even when the structure body has a projected shape or a recessed shape. In other words, a metal oxide that has a substantially uniform thickness in the normal direction can be formed on each deposition surface. As for the metal oxide that is formed on each of the top surface, the bottom surface, the side surface, and the surface with the slope of the structure body, the ratio of the minimum thickness to the maximum thickness can be greater than or equal to 0.5 and less than or equal to 1, preferably greater than or equal to 0.7 and less than or equal to 1, more preferably greater than or equal to 0.9 and less than or equal to 1. At this time, in the case where the metal oxide has a crystal structure, the c-axis thereof is aligned in a direction substantially parallel to the normal direction of each of the deposition surfaces. In other words, the c-axis is aligned perpendicularly to each of the deposition surfaces.

Here, FIG. 3C illustrates a case where a deposition surface of the structure body 50 is placed perpendicular to a substrate (or a base, not illustrated) and an oxide 64 is formed on the surface of the structure body 50. FIG. 3D is an enlarged view of a region 58, which is part of the oxide 64 in FIG. 3C. FIG. 3D illustrates a state where, on the side surface of the structure body 50, the layer 21 containing indium (In), the layer 31 containing the element M, and the layer 41 containing zinc (Zn) are stacked with respect to the deposition surface. The layer 21 containing indium is placed parallel to the deposition surface of the structure body 50, the layer 31 containing the element M is placed thereover to be parallel to the deposition surface of the structure body 50, and further the layer 41 containing zinc is placed thereover to be parallel to the deposition surface of the structure body 50. That is, the a-b plane of the oxide 60 is substantially parallel to the deposition surface of the structure body 50, and the c-axis of the oxide 60 is substantially parallel to the normal direction of the deposition surface of the structure body 50. Note that FIG. 3C and FIG. 3D show the example of the In-M-Zn oxide with In:M:Zn=1:1:1 [atomic ratio], but an oxide with a different atomic ratio can also be formed on the surface of the structure body 50 whose deposition surface is placed perpendicular to the substrate.

The examples of the metal oxide with In:M:Zn=1:1:1 [atomic ratio] and the metal oxide with In:M:Zn=1:3:4 [atomic ratio] are shown in the above; however, the present invention is not limited thereto.

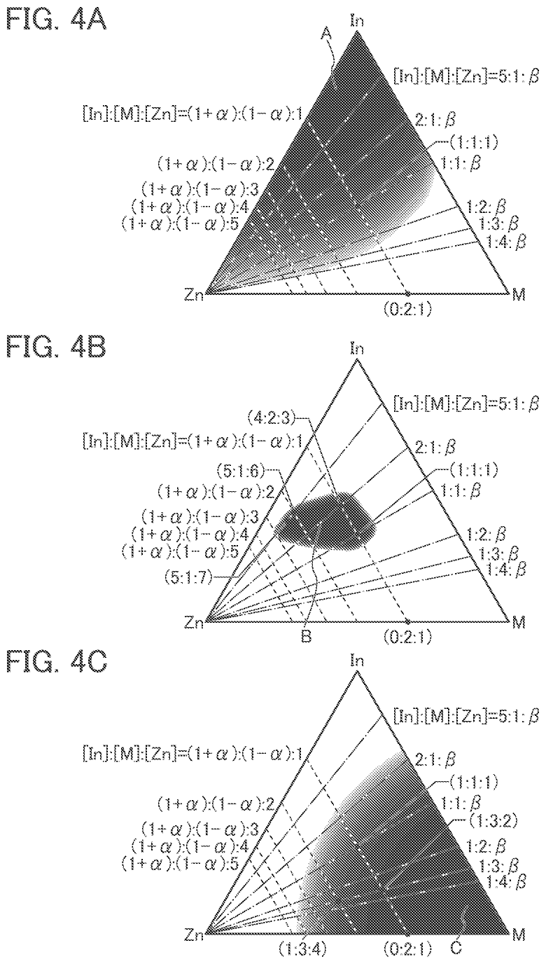

Preferred ranges of the atomic ratio of indium, the element M, and zinc contained in the metal oxide that can be used as the oxide described in one embodiment of the present invention are described below with reference to FIG. 4A, FIG. 4B, and FIG. 4C. Note that the proportion of oxygen atoms is not illustrated in FIG. 4A, FIG. 4B, and FIG. 4C. In addition, the terms of the atomic ratio of indium, the element M, and zinc contained in the metal oxide are denoted by [In], [M], and [Zn], respectively.

In FIG. 4A, FIG. 4B, and FIG. 4C, dashed lines indicate a line where the atomic ratio of [In]:[M]:[Zn]=(131 α):(1−α):1 (−1≤α≤1), a line where the atomic ratio of [In]:[M]:[Zn]=(1+α):(1−α):2, a line where the atomic ratio of [In]:[M]:[Zn]=(1+α):(1−α): 3, a line where the atomic ratio of [In]:[M]:[Zn]=(1+α): (1−α):4, and a line where the atomic ratio [In]:[M]:[Zn]=(1+α):(1−α):5.

Furthermore, dashed-dotted lines indicate a line where the atomic ratio of [In]:[M]:[Zn]=5:1:β (β≥0), a line where the atomic ratio of [In]:[M]:[Zn]=2:1:β, a line where the atomic ratio of [In]:[M]:[Zn]=1:1:β, a line where the atomic ratio of [In]:[M]:[Zn]=1:2:β, a line where the atomic ratio of [In]:[M]:[Zn]=1:3:β, and a line where the atomic ratio of [In]:[M]:[Zn]=1:4:β.

A metal oxide having the atomic ratio of [In]:[M]:[Zn]=0:2:1 or a value in the neighborhood thereof in FIG. 4A, FIG. 4B, and FIG. 4C tends to have a spinel crystal structure.

In addition, a plurality of phases coexist in the metal oxide in some cases (two-phase coexistence, three-phase coexistence, or the like). For example, with an atomic ratio having a value in the neighborhood of [In]:[M]:[Zn]=0:2:1, two phases of a spinel crystal structure and a layered crystal structure are likely to coexist. In addition, with an atomic ratio having a value in the neighborhood of [In]:[M]:[Zn]=1:0:0, two phases of a bixbyite crystal structure and a layered crystal structure are likely to coexist. In the case where a plurality of phases coexist in the metal oxide, a grain boundary is formed between different crystal structures in some cases.

A region A illustrated in FIG. 4A represents an example of the preferred range of the atomic ratio of indium, the element M, and zinc contained in the metal oxide.

When the metal oxide has a higher content of indium, the carrier mobility (electron mobility) of the metal oxide can be increased. Thus, a metal oxide having a high content of indium has higher carrier mobility than a metal oxide having a low content of indium.

By contrast, when the content of indium and zinc in a metal oxide becomes lower, the carrier mobility becomes lower. Thus, in the case of an atomic ratio of [In]:[M]:[Zn]=0:1:0 and a value in the neighborhood thereof (e.g., a region C illustrated in FIG. 4C), insulation performance becomes better. Note that since the region C includes a region that is likely to have the above spinel crystal structure, it is preferable to employ a composition with which the region that is likely to have the spinel crystal structure is avoided.

For example, the metal oxide used in a channel formation region and a low-resistance region preferably has an atomic ratio represented by the region A in FIG. 4A, with which high carrier mobility is obtained. The metal oxide used in a channel formation region and a low-resistance region may have an atomic ratio of In:Ga:Zn=4:2:3 to 4.1 and approximately a value in the neighborhood thereof, for example. Alternatively, the metal oxide may have an atomic ratio of In:Ga:Zn=1:1:1 and approximately a value in the neighborhood thereof, for example. On the other hand, in the case where the metal oxide is provided to surround a channel formation region and a low-resistance region, the metal oxide preferably has the atomic ratio represented by the region C in FIG. 4C, with which a relatively high insulating property is obtained. The metal oxide provided to surround the channel formation region and the low-resistance region may have an atomic ratio of In:Ga:Zn=1:3:4 and approximately a value in the neighborhood thereof, or an atomic ratio of In:Ga:Zn=1:3:2 and approximately a value in the neighborhood thereof. Alternatively, the metal oxide provided to surround the channel formation region and the low-resistance region may be formed using a metal oxide that is equivalent to a metal oxide used as the channel formation region and the low-resistance region.

In the region A, particularly in a region B illustrated in FIG. 4B, an excellent metal oxide having high carrier mobility and high reliability can be obtained.

Note that the region B includes [In]:[M]:[Zn]=4:2:3 to 4.1 and a value in the neighborhood thereof. The value in the neighborhood includes [In]:[M]:[Zn]=5:3:4. In addition, the region B includes [In]:[M]:[Zn]=5:1:6 and a value in the neighborhood thereof and [In]:[M]:[Zn]=5:1:7 and a value in the neighborhood thereof. The region B includes [In]:[M]: [Zn]=1:1:1 and a value in the neighborhood thereof.

As described above, the electrical conductivity of the metal oxide largely varies depending on the atomic ratio. By depositing a metal oxide by an ALD method as described above, a metal oxide having a layered crystal structure corresponding to the atomic ratio can be deposited. Thus, by employing an ALD method, a metal oxide corresponding to required characteristics can be deposited.

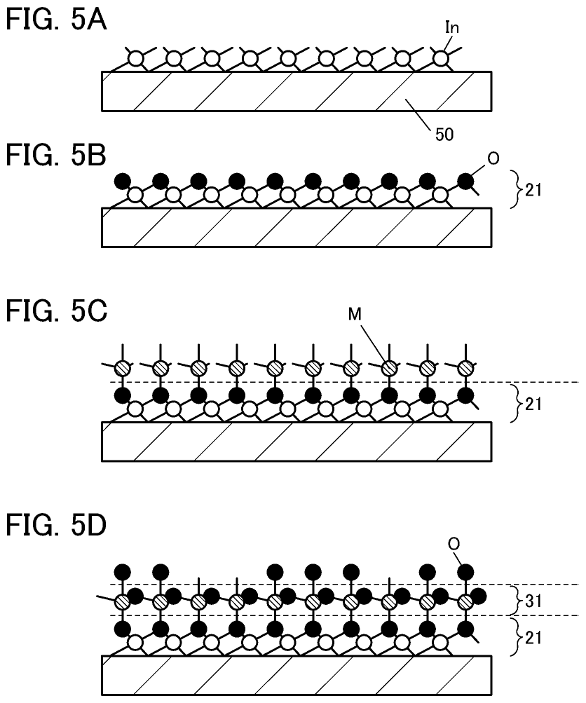

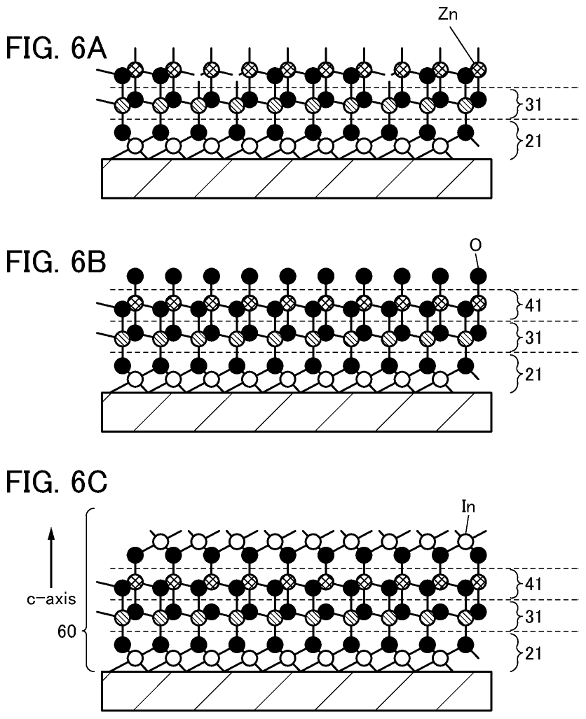

Next, details of a method for forming the oxide 60 including the In-M-Zn oxide illustrated in FIG. 2A and FIG. 2B are described with reference to FIG. 5A to FIG. 6C.

First, a source gas that contains a precursor containing indium is introduced into a chamber, so that the precursor is adsorbed onto the surface of the structure body 50 (see FIG. 5A). Here, the source gas contains a carrier gas such as argon, helium, or nitrogen in addition to the precursor. As the precursor containing indium, trimethylindium, triethylindium, tris(2,2,6,6-tetramethyl-3,5-heptanedione acid)indium, cyclopentadienylindium, indium(III) acetylacetonate, (3-(dimethylamino)propyl)dimethylindium, or the like can be used.

As the precursor containing indium, an inorganic precursor not containing hydrocarbon may be used. As the precursor containing indium, a halogen-based indium compound such as indium trichloride, indium tribromide, or indium triiodide can be used. The decomposition temperature of indium trichloride is approximately higher than or equal to 500° C. and lower than or equal to 700° C. Thus, with use of indium trichloride, deposition can be performed by an ALD method while a substrate is being heated at approximately higher than or equal to 400° C. and lower than or equal to 600° C., for example, at 500° C.

Next, introduction of the source gas is stopped and the chamber is purged, whereby an excess precursor, a reaction product, and the like are released from the chamber.

Then, an oxidizer is introduced as a reactant into the chamber to react with the adsorbed precursor, and components other than indium are released while indium is adsorbed onto the substrate, so that the layer 21 in which indium and oxygen are bonded to each other is formed (see FIG. 5B). Ozone, oxygen, water, or the like can be used as the oxidizer. After that, introduction of the oxidizer is stopped and the chamber is purged, whereby an excess reactant, a reaction product, and the like are released from the chamber.

Subsequently, a source gas that contains a precursor containing the element M is introduced into the chamber, so that the precursor is adsorbed onto the layer 21 (see FIG. 5C). The source gas contains a carrier gas such as argon, helium, or nitrogen in addition to the precursor. In the case where gallium is used as the element M, trimethylgallium, triethylgallium, tris(dimethylamide)gallium, gallium(III) acetylacetonate, tris(2,2,6,6-tetramethyl-3,5-heptanedione acid)gallium, dimethylchlorogallium, diethylchlorogallium, dimethyl gallium isopropoxide, or the like can be used as the precursor containing gallium.

As the precursor containing gallium, an inorganic precursor not containing hydrocarbon may be used. As the precursor containing gallium, a halogen-based gallium compound such as gallium trichloride, gallium tribromide, or gallium triiodide can be used. The decomposition temperature of gallium trichloride is approximately higher than or equal to 550° C. and lower than or equal to 700° C. Thus, with use of gallium trichloride, deposition can be performed by an ALD method while a substrate is being heated at approximately higher than or equal to 450° C. and lower than or equal to 650° C., for example, at 550° C.

Next, introduction of the source gas is stopped and the chamber is purged, whereby an excess precursor, a reaction product, and the like are released from the chamber.

Then, an oxidizer is introduced as a reactant into the chamber to react with the adsorbed precursor, and components other than the element Mare released while the element M is adsorbed onto the substrate, so that the layer 31 in which the element M and oxygen are bonded to each other is formed (see FIG. 5D). At this time, part of oxygen adsorbed onto the layer 31 may be included in the layer 41 described later. After that, introduction of the oxidizer is stopped and the chamber is purged, whereby an excess reactant, a reaction product, and the like are released from the chamber.

Subsequently, a source gas that contains a precursor containing zinc is introduced into the chamber, so that the precursor is adsorbed onto the layer 31 (see FIG. 6A). At this time, part of the layer 41 in which zinc is bonded to oxygen is formed in some cases. The source gas contains a carrier gas such as argon, helium, or nitrogen in addition to the precursor. Dimethylzinc, diethylzinc, bis(2,2,6,6,tetramethyl-3,5-heptanedione acid)zinc, zinc acetate, or the like can be used as the precursor containing zinc.

As the precursor containing zinc, an inorganic precursor not containing hydrocarbon may be used. As the precursor containing zinc, a halogen-based zinc compound such as zinc dichloride, zinc dibromide, or zinc diiodide can be used. The decomposition temperature of zinc dichloride is approximately higher than or equal to 450° C. and lower than or equal to 700° C. Thus, with use of zinc dichloride, deposition can be performed by an ALD method while a substrate is being heated at approximately higher than or equal to 350° C. and lower than or equal to 550° C., for example, at 450° C.

Next, introduction of the source gas is stopped and the chamber is purged, whereby an excess precursor, a reaction product, and the like are released from the chamber.

Then, an oxidizer is introduced as a reactant into the chamber to react with the adsorbed precursor, and components other than zinc are released while zinc is adsorbed onto the substrate, so that the layer 41 in which zinc and oxygen are bonded to each other is formed (see FIG. 6B). After that, introduction of the oxidizer is stopped and the chamber is purged, whereby an excess reactant, a reaction product, and the like are released from the chamber.

Next, the layer 21 is formed again over the layer 41 by the above-described method (see FIG. 6C). By repeating the above-described method, the oxide 60 can be formed over the substrate or the structure body.

Other than above-described precursors containing the metal elements, there is a precursor that contains one or both of carbon and chlorine. A film that is formed using a precursor containing carbon may contain carbon. A film that is formed using a precursor containing halogen such as chlorine may contain halogen such as chlorine.

As described above, the oxide 60 is formed by an ALD method, whereby the metal oxide having a CAAC structure, in which the c-axis is aligned substantially parallel to the normal direction of the deposition surface, can be obtained.

The steps illustrated in FIG. 5A to FIG. 6C are preferably performed while the substrate is being heated. The substrate temperature is higher than or equal to 200° C. and lower than or equal to 600° C., preferably higher than or equal to 300° C. and lower than or equal to the precursor decomposition temperature. By performing the deposition while the substrate is being heated in such a temperature range, an impurity such as hydrogen or carbon contained in the precursor, the reactant, or the like can be removed from the metal oxide in each of the steps in FIG. 5A to FIG. 6C. For example, carbon in the metal oxide can be released as CO₂ and CO, and hydrogen in the metal oxide can be released as H₂O. Furthermore, metal atoms and oxygen atoms are rearranged concurrently with removal of the impurity, so that layers of oxides can be arranged orderly. Thus, a metal oxide having a layered crystal structure with high crystallinity, for example, a metal oxide having a CAAC structure can be formed.

In order to perform deposition while the substrate is being heated in the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, an inorganic precursor is preferably used. In general, an inorganic precursor tends to have a higher decomposition temperature than an organic precursor, so that even when deposition is performed while the substrate is being heated as described above, the precursor is hardly decomposed.

As the inorganic precursor, for example, the above indium trichloride, gallium trichloride, or zinc dichloride can be used. As described above, the decomposition temperature of each of these precursors is approximately higher than or equal to 350° C. and lower than or equal to 700° C., which is much higher than the decomposition temperature of a common organic precursor. Note that as described above, the decomposition temperatures of indium trichloride, gallium trichloride, and zinc dichloride are different from each other. In the case where deposition is performed by an ALD method with use of different kinds of precursors, the substrate temperature is preferably lower than or equal to the lowest precursor decomposition temperature among the precursors. In the above example, the substrate temperature is set within a range where zinc dichloride having the lowest precursor decomposition temperature is not decomposed. Accordingly, indium trichloride and gallium trichloride can also be adsorbed onto an object (e.g., a substrate) without being decomposed.

In the above, the inorganic precursor is described as an example; however, the present invention is not limited thereto. The above example can also be applied to an ALD method using an organic precursor, for example. In the case where a metal oxide (e.g., an In-M-Zn metal oxide) is deposited with use of organic precursors, for example, the substrate temperature is preferably lower than or equal to the lowest precursor decomposition temperature among the organic precursors. Accordingly, during ALD deposition, the precursors that are used can be adsorbed onto an object (e.g., a substrate) without being decomposed. In this case, the substrate temperature can be within a range from 100° C. to the lowest precursor decomposition temperature (typically, from 200° C. to 300° C.).

Furthermore, after the deposition of the metal oxide, heat treatment is preferably performed. In particular, the heat treatment is preferably performed without exposure to the air successively after the deposition by an ALD method. The heat treatment is preferably performed at a temperature higher than or equal to 250° C. and lower than or equal to 650° C., further preferably higher than or equal to 300° C. and lower than or equal to 600° C., still further preferably higher than or equal to 400° C. and lower than or equal to 550° C., still further preferably higher than or equal to 420° C. and lower than or equal to 480° C. By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which improves crystallinity. Thus, a metal oxide having a layered crystal structure with high crystallinity, specifically, a metal oxide having the CAAC structure can be formed.

FIG. 5A to FIG. 6C show an example in which the layer 21 is formed as a layer containing indium, the layer 31 is formed thereover as a layer containing the element M, and further the layer 41 is formed thereover as a layer containing zinc; however, this embodiment is not limited thereto. One of the layer 31 and the layer 41 may be formed, the layer 21 may be formed thereover, and further the other of the layer 31 and the layer 41 may be formed thereover. Alternatively, one of the layer 31 and the layer 41 may be formed, the other of the layer 31 and the layer 41 may be formed thereover, and further the layer 21 may be formed thereover.

In the case of forming a metal oxide with an atomic ratio that is different from In:M:Zn=1:1:1 [atomic ratio], the above-described layer 21, layer 31, and layer 41 are formed as appropriate in accordance with the atomic ratio. For example, the formation of the layer 41 is repeated a plurality of times before and after the formation of the layer 31 illustrated in FIG. 6A so that a stack including the layers 31 and the layers 41 and having the desired number of atoms and layers and a desired thickness is formed between two layers 21.

### <Structure Example of Deposition Apparatus>

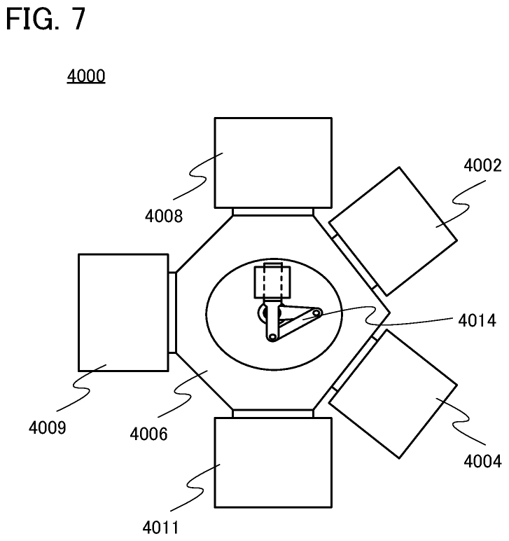

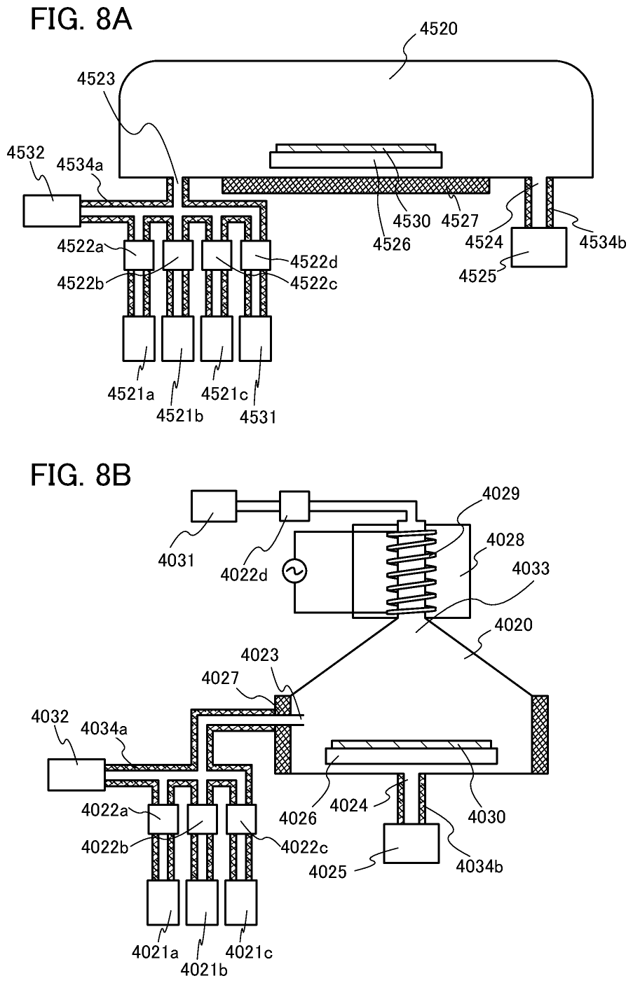

The structure of a deposition apparatus 4000 is described with reference to FIG. 7, FIG. 8A, and FIG. 8B as an example of an apparatus with which deposition can be performed by an ALD method. FIG. 7 is a schematic view of the multi-chamber type deposition apparatus 4000, and FIG. 8A and FIG. 8B are cross-sectional views of ALD apparatuses that can be used for the deposition apparatus 4000.

The deposition apparatus 4000 includes a carrying-in/out chamber 4002, a carrying-in/out chamber 4004, a transfer chamber 4006, a deposition chamber 4008, a deposition chamber 4009, a treatment chamber 4011, and a transfer arm 4014. Here, the carrying-in/out chamber 4002, the carrying-in/out chamber 4004, the deposition chamber 4008, the deposition chamber 4009, and the treatment chamber 4011 are each independently connected to the transfer chamber 4006 through a gate valve. Thus, successive treatment can be performed in the deposition chamber 4008, the deposition chamber 4009, and the treatment chamber 4011 without exposure to the air, whereby entry of impurities into a film can be prevented. Moreover, contamination of an interface between a substrate and a film and interfaces between films can be reduced, so that clean interfaces can be obtained.

Note that in order to prevent attachment of moisture and the like, the carrying-in/out chamber 4002, the carrying-in/out chamber 4004, the transfer chamber 4006, the deposition chamber 4008, the deposition chamber 4009, and the treatment chamber 4011 are preferably filled with an inert gas (such as a nitrogen gas) whose dew point is controlled, and desirably maintain reduced pressure.

An ALD apparatus can be used in the deposition chamber 4008 and the deposition chamber 4009. A structure using a deposition apparatus other than an ALD apparatus in either of the deposition chamber 4008 and the deposition chamber 4009 may be employed. Examples of the deposition apparatus that can be used in the deposition chamber 4008 and the deposition chamber 4009 include a sputtering apparatus, a plasma CVD (PECVD: Plasma Enhanced CVD) apparatus, a thermal CVD (TCVD) apparatus, a photo CVD apparatus, a metal CVD (MCVD) apparatus, and a metal organic CVD (MOCVD) apparatus.

The treatment chamber 4011 is provided with an apparatus having a function other than that of a deposition apparatus such as a heating apparatus (typically, a vacuum heating apparatus) and a plasma generation apparatus (typically, a μ-wave plasma generation apparatus).

For example, in the case where an ALD apparatus is used in the deposition chamber 4008, a sputtering apparatus is used in the deposition chamber 4009, and a heating apparatus is used in the deposition chamber 4011, a base insulating film can be deposited in the deposition chamber 4009, an oxide semiconductor film functioning as an active layer can be deposited in the deposition chamber 4008, and heat treatment after the deposition of the oxide semiconductor film can be performed in the treatment chamber 4011. At that time, the deposition of the base insulating film, the deposition of the oxide semiconductor film, and the heat treatment can be performed successively without exposure to the air.

Although the deposition apparatus 4000 includes the carrying-in/out chamber 4002, the carrying-in/out chamber 4004, the deposition chamber 4008, the deposition chamber 4009, and the treatment chamber 4011, the present invention is not limited thereto. The number of the deposition chambers in the deposition apparatus 4000 may be one or three or more. The number of the treatment chambers in the deposition apparatus 4000 may be two or more. The deposition apparatus 4000 may be of a single-wafer type or may be of a batch type, in which case deposition is performed on a plurality of substrates at a time.

### <Heating Apparatus>

Next, a heating apparatus that can be used in the treatment chamber 4011 will be described. A heating mechanism used for the heating apparatus may be a mechanism using a resistance heater for heating, for example. Alternatively, a heating mechanism that uses heat conduction or heat radiation from a medium such as a heated gas for heating may be used. For example, an RTA (Rapid Thermal Anneal) apparatus such as a GRTA (Gas Rapid Thermal Anneal) apparatus or an LRTA (Lamp Rapid Thermal Anneal) apparatus can be used. In the LRTA, an object is heated through radiation of light (electromagnetic wave) emitted from a lamp such as a halogen lamp, a metal halide lamp, a xenon arc lamp, a carbon arc lamp, a high-pressure sodium lamp, or a high-pressure mercury lamp. In the GRTA, heat treatment is performed using a high-temperature gas.

The heat treatment is performed at a temperature higher than or equal to 100° C. and lower than or equal to 1200° C., preferably higher than or equal to 200° C. and lower than or equal to 1000° C., further preferably higher than or equal to 250° C. and lower than or equal to 650° C., still further preferably higher than or equal to 300° C. and lower than or equal to 600° C., still further preferably higher than or equal to 400° C. and lower than or equal to 550° C., still further preferably higher than or equal to 420° C. and lower than or equal to 480° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. In the case where the temperature of the heat treatment is high, the metal oxide may have a polycrystalline structure; thus, the temperature of the heat treatment is set as appropriate within a range where the metal oxide does not have a polycrystalline structure. Note that in one embodiment of the present invention, the metal oxide may have a polycrystalline structure.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment performed using a highly purified gas can prevent entry of moisture or the like into the metal oxide as much as possible.

For example, as the above heat treatment, treatment at a temperature higher than or equal to 400° C. and lower than or equal to 550° C., preferably higher than or equal to 420° C. and lower than or equal to 480° C. for one hour is performed with a flow rate ratio of a nitrogen gas and an oxygen gas of 4 slm: 1 slm after the deposition of the metal oxide. By the heat treatment, impurities such as water and hydrogen contained in the metal oxide can be reduced, for example.

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. As described above, since the treatment chamber 4011 is connected to the deposition chamber 4008 and the deposition chamber 4009 through the transfer chamber 4006, the deposition of the metal oxide to the heat treatment can be performed successively without exposure to the air. Thus, the heat treatment can be performed after the deposition of the metal oxide without increasing an impurity such as hydrogen or carbon in the film. Furthermore, metal atoms and oxygen atoms are rearranged concurrently with removal of the impurity, which improves crystallinity. Thus, a metal oxide having a layered crystal structure with high crystallinity, specifically, a metal oxide having the CAAC structure can be formed.

The example in which the heat treatment apparatus is used in the treatment chamber 4011 is described above; however, the present invention is not limited thereto. For example, a microwave treatment apparatus may be used in the treatment chamber 4011. By performing microwave treatment, an impurity such as hydrogen or carbon contained in the metal oxide can be removed. For the details of the microwave treatment and the microwave treatment apparatus, the description in a later embodiment can be referred to.

### <ALD Apparatus>

Next, a structure of a thermal ALD apparatus that can be used as the deposition apparatus 4000 is described with reference to FIG. 8A. The thermal ALD apparatus includes a deposition chamber (a chamber 4520), a source material supply portion 4521 (a source material supply portion 4521a to a source material supply portion 4521c), a source material supply portion 4531, a high-speed valve 4522a to a high-speed valve 4522d that are introduction amount controllers, a gas supply portion 4532, a source material introduction port 4523, a source material exhaust port 4524, and an evacuation unit 4525. The source material introduction port 4523 provided in the chamber 4520 is connected to the source material supply portion 4521a, the source material supply portion 4521b, the source material supply portion 4521c, the source material supply portion 4531, and the gas supply portion 4532 through supply tubes and valves, and the source material exhaust port 4524 is connected to the evacuation unit 4525 through an exhaust tube, a valve, and a pressure controller.

A substrate holder 4526 is positioned in the chamber 4520, and a substrate 4530 is placed on the substrate holder 4526. The substrate holder 4526 may include a rotation mechanism. A heater 4527, which is provided on an outside wall of the chamber 4520, can control the temperature inside the chamber 4520 and the temperatures of the substrate holder 4526, the surface of the substrate 4530, and the like. It is preferable that the heater 4527 be capable of controlling the temperature of the surface of the substrate 4530 to higher than or equal to 100° C. and lower than or equal to 600° C., preferably higher than or equal to 200° C. and lower than or equal to 600° C., further preferably higher than or equal to 300° C. and lower than or equal to the precursor decomposition temperature, and be capable of setting the temperature of the heater 4527 itself to higher than or equal to 100° C. and lower than or equal to 600° C. By performing the deposition while the substrate is being heated in such a temperature range, an impurity such as hydrogen or carbon contained in the precursor, the reactant, or the like can be appropriately reduced from the metal oxide. Furthermore, metal atoms and oxygen atoms are rearranged concurrently with removal of the impurity, so that layers of oxides can be arranged orderly. Thus, a metal oxide having a layered crystal structure with high crystallinity can be formed. In addition, the heat treatment after the deposition of the metal oxide may be performed with the use of the heater 4527.

In the source material supply portion 4521a, the source material supply portion 4521b, the source material supply portion 4521c, and the source material supply portion 4531, a source gas is formed from a solid source material or a liquid source material using a vaporizer, a heating unit, or the like. Alternatively, the source material supply portion 4521a, the source material supply portion 4521b, the source material supply portion 4521c, and the source material supply portion 4531 may supply a source gas.

In the deposition apparatus illustrated in FIG. 8A, a metal oxide can be formed by appropriate selection of source materials (e.g., a volatile organic metal compound) used in the source material supply portion 4521 and the source material supply portion 4531 and introduction of the materials into the chamber 4520. In the case where an In-Ga-Zn oxide, which contains indium, gallium, and zinc, is formed as the metal oxide as described above, it is preferable to use a deposition apparatus provided with at least three source material supply portions 4521a to 4521c and at least one source material supply portion 4531, as illustrated in FIG. 8A.

For example, a precursor containing indium is supplied from the source material supply portion 4521a, a precursor containing gallium is supplied from the source material supply portion 4521b, and a precursor containing zinc is supplied from the source material supply portion 4521c. Any of the above-described precursors can be used as the precursor containing indium, the precursor containing gallium, and the precursor containing zinc. The precursor containing indium, the precursor containing gallium, and the precursor containing zinc preferably have high decomposition temperatures, and inorganic precursors are preferably used, for example. Note that in the case where a halogen-based compound or the like is used as an inorganic precursor, a gas may be highly corrosive. Therefore, a material having high corrosion resistance, such as titanium, is preferably used for members that are in contact with a gas, such as a chamber, a pipe, supply portions of various gases, and the like.

A reactant is supplied from the source material supply portion 4531. An oxidizer containing at least one of ozone, oxygen, and water can be used as the reactant.

A carrier gas is supplied from the gas supply portion 4532. As the carrier gas, an inert gas such as argon (Ar), helium (He), or nitrogen (N₂) can be used. The precursor from the source material supply portion 4521 and the reactant from the source material supply portion 4531 are mixed with the carrier gas and introduced into the chamber 4520.

A pipe heater 4534a is provided to cover the pipe, the valve, and the like between the source material supply portion 4521a, the source material supply portion 4521b, the source material supply portion 4521c, the source material supply portion 4531, and the gas supply portion 4532 and the chamber 4520. A pipe heater 4534b is provided to cover the pipe, the valve, and the like between the evacuation unit 4525 and the chamber 4520. The temperatures of the pipe heater 4534a and the pipe heater 4534b are set as appropriate in a range from room temperature to 300° C., for example. Provision of such pipe heaters can prevent a precursor or the like supplied from the source material supply portion 4521 from being solidified on inner walls of pipes or the like of the gas introduction system and the gas evacuation system. In particular, a precursor having a high decomposition temperature, such as an inorganic precursor, tends to be solidified; thus, in the case of using such a precursor, pipe heaters are preferably provided to cover the pipes of the gas introduction system and the gas evacuation system. The temperatures of the pipe heater 4534a, the pipe heater 4534b, and the heater 4527 are controlled independently. The pipe heater 4534a, the pipe heater 4534b, and the heater 4527 are controlled independently, whereby the temperatures of the heaters can be controlled individually. Note that, without limitation to this, the temperatures of the pipe heater 4534a, the pipe heater 4534b, and the heater 4527 may be controlled in conjunction with each other. In this case, the temperatures can be controlled at a time, so that the cost of an apparatus member or the like can be reduced.

The high-speed valve 4522a to the high-speed valve 4522d can be precisely controlled based on time. Thus, source gases supplied from the source material supply portion 4521a, the source material supply portion 4521b, the source material supply portion 4521c, and the source material supply portion 4531 can be controlled to be introduced into the chamber 4520.

For example, in the case of supplying a precursor included in any of the source material supply portion 4521a, the source material supply portion 4521b, and the source material supply portion 4521c, a corresponding high-speed valve among the high-speed valve 4522a to the high-speed valve 4522c is opened. In the case of supplying a reactant included in the source material supply portion 4531, the high-speed valve 4522d is opened. In the case of purging the chamber 4520, the high-speed valve 4522a to the high-speed valve 4522d are closed and only a carrier gas included in the gas supply portion 4532 is introduced into the chamber 4520.

Although FIG. 8A shows the example in which three source material supply portions 4521 and one source material supply portion 4531 are provided, this embodiment is not limited thereto. One, two, or four or more source material supply portions 4521 may be provided. In addition, two or more source material supply portions 4531 may be provided.

In FIG. 8A, the heater 4527, the source material introduction port 4523, and the source material exhaust port 4524 are provided on the lower portion of the chamber 4520; however, without limitation to this, their arrangement can be set as appropriate. In FIG. 8A, inlets of the source material supply portion 4521a, the source material supply portion 4521b, the source material supply portion 4521c, the source material supply portion 4531, and the gas supply portion 4532 are combined into the source material introduction port 4523; however, without limitation to this, inlets different from each other may be provided.

Next, a structure of a plasma ALD apparatus that can be used as the deposition apparatus 4000 is described with reference to FIG. 8B. The plasma ALD apparatus includes a deposition chamber (a chamber 4020), a source material supply portion 4021 (a source material supply portion 4021a to a source material supply portion 4021c), a source material supply portion 4031, a high-speed valve 4022a to a high-speed valve 4022d that are introduction amount controllers, a gas supply portion 4032, a source material introduction port 4023, a source material introduction port 4033, a source material exhaust port 4024, and an evacuation unit 4025. The source material introduction port 4023 and the source material introduction port 4033 provided in the chamber 4020 are connected to the source material supply portion 4021a, the source material supply portion 4021b, the source material supply portion 4021c, the source material supply portion 4031, and the gas supply portion 4032 through supply tubes and valves, and the source material exhaust port 4024 is connected to the evacuation unit 4025 through an exhaust tube, a valve, and a pressure controller. A substrate holder 4026 is positioned in the chamber 4020, and a substrate 4030 is placed on the substrate holder 4026. A heater 4027 is provided on an outside wall of the chamber, and a pipe heater 4034a and a pipe heater 4034b are provided to cover pipes and the like connected to the chamber.

Here, the chamber 4020, the source material supply portion 4021, the source material supply portion 4031, the high-speed valve 4022a to the high-speed valve 4022d, the gas supply portion 4032, the source material introduction port 4023, the source material exhaust port 4024, the evacuation unit 4025, the substrate holder 4026, the substrate 4030, the heater 4027, the pipe heater 4034a, and the pipe heater 4034b correspond to the chamber 4520, the source material supply portion 4521, the source material supply portion 4531, the high-speed valve 4522a to the high-speed valve 4522d, the gas supply portion 4532, the source material introduction port 4523, the source material exhaust port 4524, the evacuation unit 4525, the substrate holder 4526, the substrate 4530, the heater 4527, the pipe heater 4534a, and the pipe heater 4534b, respectively; and detailed structures can be referred to for the above description.

In the plasma ALD apparatus, a plasma generation apparatus 4028 is connected to the chamber 4020 as illustrated in FIG. 8B, whereby deposition can be performed by a plasma ALD method as well as a thermal ALD method. It is preferable that the plasma generation apparatus 4028 be an ICP-type plasma generation apparatus using a coil 4029 connected to a high-frequency power source. The high-frequency power source is capable of outputting power with a frequency higher than or equal to 10 kHz and lower than or equal to 100 MHz, preferably higher than or equal to 1 MHz and lower than or equal to 60 MHz, further preferably higher than or equal to 2 MHz and lower than or equal to 60 MHz. For example, power with a frequency of 13.56 MHz can be output. A plasma ALD method enables deposition without decreasing the deposition rate even at low temperatures, and thus is preferably used for a single-wafer type deposition apparatus with low deposition efficiency.

A reactant exhausted from the source material supply portion 4031 passes through the plasma generation apparatus 4028 and turns into a plasma state. The reactant in the plasma state is introduced from the source material introduction port 4033 into the chamber 4020. Although not illustrated in FIG. 8B, a reactant exhausted from the source material supply portion 4031 may be mixed with a carrier gas.

The substrate holder 4526 may be provided with a mechanism to which a constant potential or a high-frequency wave is applied. Alternatively, the substrate holder 4526 may be floating or grounded.

In FIG. 8B, the source material introduction port 4033 is provided on the upper portion of the chamber 4520, the heater 4027 and the source material introduction port 4023 are provided on a side surface of the chamber 4520, and the source material exhaust port 4524 is provided on the lower portion of the chamber 4520; however, without limitation to this, their arrangement can be set as appropriate.

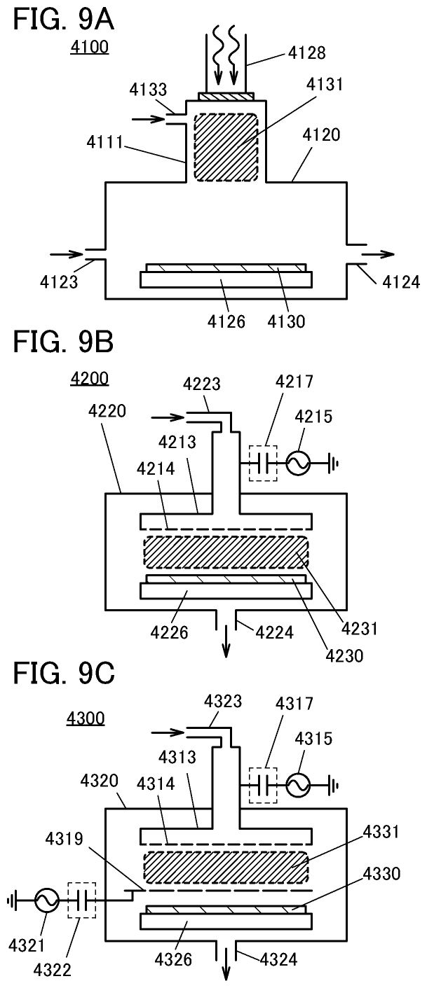

FIG. 9A to FIG. 9C each illustrate a different structure of an ALD apparatus that can be used for the deposition apparatus 4000. Note that detailed description on structures and functions similar to those of the ALD apparatus illustrated in FIG. 8B are omitted in some cases.

FIG. 9A is a schematic view illustrating one embodiment of a plasma ALD apparatus. A plasma ALD apparatus 4100 is provided with a reaction chamber 4120 and a plasma generation chamber 4111 above the reaction chamber 4120. The reaction chamber 4120 can be referred to as a chamber. Alternatively, the reaction chamber 4120 and the plasma generation chamber 4111 can be collectively referred to as a chamber. The reaction chamber 4120 includes a source material introduction port 4123 and a source material exhaust port 4124, and the plasma generation chamber 4111 includes a source material introduction port 4133. Furthermore, a plasma generation apparatus 4128 enables a high-frequency wave such as RF or a microwave to be applied to a gas introduced to the plasma generation chamber 4111, thereby generating plasma 4131 in the plasma generation chamber 4111. In the case where the plasma 4131 is generated using a microwave, a microwave with a frequency of 2.45 GHz is typically used. Such plasma generated by application of the microwave and an electric field is referred to as ECR (Electron Cyclotron Resonance) plasma in some cases.

A substrate holder 4126 is provided in the reaction chamber 4120, and a substrate 4130 is positioned thereover. A source gas introduced from the source material introduction port 4123 is decomposed by heat from a heater provided in the reaction chamber 4120 and is deposited over the substrate 4130. A source gas introduced from the source material introduction port 4133 turns into a plasma state by the plasma generation apparatus 4128. The source gas in the plasma state is recombined with electrons or other molecules to be in a radical state before it reaches the surface of the substrate 4130, and reaches the substrate 4130. An ALD apparatus that performs deposition using a radical in such a manner may also be referred to as a radical ALD (Radical-Enhanced ALD) apparatus. The structure of the plasma ALD apparatus 4100, in which the plasma generation chamber 4111 is provided above the reaction chamber 4120, is illustrated; however, this embodiment is not limited thereto. The plasma generation chamber 4111 may be provided adjacent to a side surface of the reaction chamber 4120.

FIG. 9B is a schematic view illustrating one embodiment of a plasma ALD apparatus. A plasma ALD apparatus 4200 includes a chamber 4220. The chamber 4220 includes an electrode 4213, a source material exhaust port 4224, and a substrate holder 4226, and a substrate 4230 is put over the substrate holder 4226. The electrode 4213 includes a source material introduction port 4223 and a shower head 4214 that supplies the introduced source gas into the chamber 4220. A power source 4215 capable of applying a high-frequency wave through a capacitor 4217 is connected to the electrode 4213. The substrate holder 4226 may be provided with a mechanism to which a constant potential or a high-frequency wave is applied. Alternatively, the substrate holder 4226 may be floating or grounded. The electrode 4213 and the substrate holder 4226 function as an upper electrode and a lower electrode for generating plasma 4231, respectively. A source gas introduced from the source material introduction port 4223 is decomposed by heat from a heater provided in the chamber 4220 and is deposited over the substrate 4230. Alternatively, the source gas introduced from the source material introduction port 4223 turns into a plasma state between the electrode 4213 and the substrate holder 4226. The source gas in the plasma state enters the substrate 4230 owing to a potential difference (also referred to as an ion sheath) generated between the plasma 4231 and the substrate 4230.

FIG. 9C is a schematic view illustrating one embodiment of a plasma ALD apparatus different form that in FIG. 9B. A plasma ALD apparatus 4300 includes a chamber 4320. The chamber 4320 includes an electrode 4313, a source material exhaust port 4324, and a substrate holder 4326, and a substrate 4330 is put over the substrate holder 4326. The electrode 4313 includes a source material introduction port 4323 and a shower head 4314 that supplies the introduced source gas into the chamber 4320. A power source 4315 capable of applying a high-frequency wave through a capacitor 4317 is connected to the electrode 4313. The substrate holder 4326 may be provided with a mechanism to which a constant potential or a high-frequency wave is applied. Alternatively, the substrate holder 4326 may be floating or grounded. The electrode 4313 and the substrate holder 4326 function as an upper electrode and a lower electrode for generating plasma 4331, respectively. The plasma ALD apparatus 4300 is different from the plasma ALD apparatus 4200 in that a mesh 4319 to which a power source 4321 capable of applying a high-frequency wave through a capacitor 4322 is connected is provided between the electrode 4313 and the substrate holder 4326. With the mesh 4319, the plasma 4231 can be away from the substrate 4130. A source gas introduced from the source material introduction port 4323 is decomposed by heat from a heater provided in the chamber 4320 and is deposited over the substrate 4330. Alternatively, the source gas introduced from the source material introduction port 4323 turns into a plasma state between the electrode 4313 and the substrate holder 4326. Charge of the source gas in the plasma state is removed by the mesh 4319 and the source gas reaches the substrate 4130 while being in an electrically neutral state such as a radical. Therefore, it is possible to perform deposition with suppressed damage due to plasma and the entry of ions.

Note that the microwave treatment after the deposition of the metal oxide may be performed with the use of the plasma ALD apparatus illustrated in FIG. 8B and FIG. 9A to FIG. 9C.

### <Deposition Sequence>

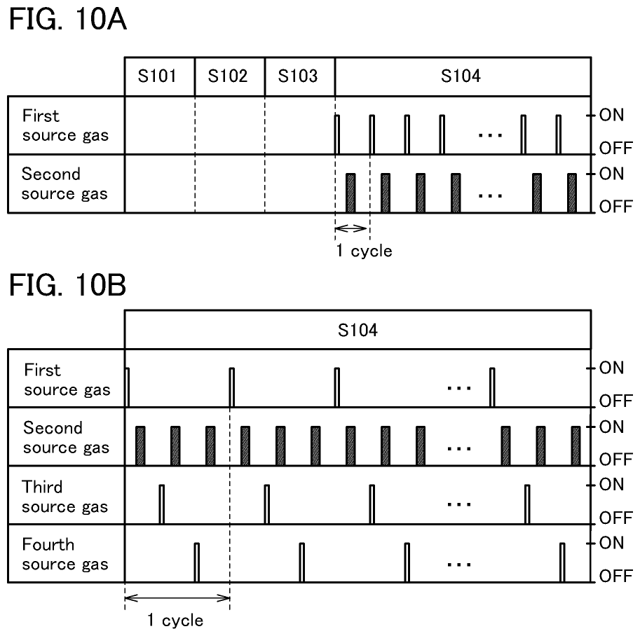

Next, a deposition sequence of a metal oxide using the ALD apparatus illustrated in FIG. 8A is described with reference to FIG. 10A to FIG. 12. In FIG. 10A to FIG. 12, introductions of a first source gas to a fourth source gas are each indicated by ON, and periods during which the source gases are not introduced are each indicated by OFF.

FIG. 10A shows a deposition sequence using the ALD apparatus illustrated in FIG. 8A. First, the substrate 4530 is set on the substrate holder 4526 in the chamber 4520 (Step S101). Next, the temperature of the heater 4527 is adjusted (Step S102). At this time, the temperatures of the pipe heater 4534a and the pipe heater 4534b are also adjusted. Then, the substrate 4530 is held on the substrate holder 4526 so that the temperature of the substrate 4530 becomes uniform in the substrate surface (Step S103). Next, a metal oxide is deposited in accordance with the above first step to fourth step (Step S104). Note that after setting the substrate 4530 (Step S101), Step S102 may be omitted if the temperature of the heater 4527 does not need to be adjusted.

In Step S104, the first source gas (a source gas containing a precursor) and the second source gas (a source gas containing a reactant) are alternately introduced into the chamber 4520, whereby a film is deposited over the substrate 4530. The first source gas and the second source gas are introduced in a pulsed form. In periods during which neither the first source gas nor the second source gas is introduced, the chamber 4520 is purged. In the deposition by an ALD method, introduction of the first source gas (the first step), purge of the first source gas (the second step), introduction of the second source gas (the third step), and purge of the second source gas (the fourth step) are regarded as one cycle, and a film having a desired thickness is formed by repetition of this cycle.

Furthermore, the second source gas containing a reactant may be introduced into the chamber 4020 between Step S103 and Step S104. It is preferable that one or more selected from ozone (O₃), oxygen (O₂), and water (H₂O), which function as oxidizers, be introduced as the second source gas. Introduction of water as the second source gas can form a hydrophilic group on the substrate 4530, so that the precursor can have a much improved adsorption property. Introduction of ozone and oxygen as the second source gas can provide an oxygen atmosphere in the chamber and supply oxygen to the base insulating film or the like formed on the substrate 4530. Accordingly, oxygen can be supplied to the metal oxide film formed over the base insulating film, so that the oxygen concentration in the film can be increased. In that case, the second source gas is preferably introduced in a pulsed form in a manner similar to that in Step S104; however, the present invention is not limited thereto. The second source gas may be successively introduced. In the period during which the second source gas is not introduced, the chamber 4520 is evacuated.

A first oxide layer is formed in one cycle using the above first source gas, a second oxide layer is formed in one cycle using the third source gas different from the first source gas, and a third oxide layer is formed in one cycle using the fourth source gas different from the first source gas, whereby a layered crystalline oxide including different oxide layers can be deposited. Hereinafter, a deposition sequence corresponding to a deposition process of the In-Ga-Zn oxide illustrated in FIG. 5A to FIG. 6C is described as an example with reference to FIG. 10B.

FIG. 10B shows Step S104 of the deposition sequence in an example in which deposition is performed using the first source gas to the third source gas containing precursors. Note that Step S101 to Step S103 are performed in a manner similar to the above. Here, the first source gas contains a precursor containing indium, the third source gas contains a precursor containing gallium, and the fourth source gas contains a precursor containing zinc.

As shown in FIG. 10B, first, the first source gas is introduced, whereby the precursor containing indium is adsorbed onto the substrate 4530 (corresponding to FIG. 5A). Then, introduction of the first source gas is stopped and an excess first source gas in the chamber is purged.

Next, the second source gas is introduced, whereby the adsorbed precursor containing indium reacts with an oxidizer and a layer of indium oxide is formed (corresponding to FIG. 5B). Then, introduction of the second source gas is stopped and an excess second source gas in the chamber is purged.

Next, the third source gas is introduced, whereby the precursor containing gallium is adsorbed onto the layer of indium oxide (corresponding to FIG. 5C). Then, introduction of the third source gas is stopped and an excess third source gas in the chamber is purged.

Next, the second source gas is introduced, whereby the adsorbed precursor containing gallium reacts with an oxidizer and a layer of gallium oxide is formed (corresponding to FIG. 5D). Then, introduction of the second source gas is stopped and an excess second source gas in the chamber is purged.

Next, the fourth source gas is introduced, whereby the precursor containing zinc is adsorbed onto the layer of gallium oxide (corresponding to FIG. 6A). Then, introduction of the fourth source gas is stopped and an excess fourth source gas in the chamber is purged.

Next, the second source gas is introduced, whereby the adsorbed precursor containing zinc reacts with an oxidizer and a layer of zinc oxide is formed (corresponding to FIG. 6B). Then, introduction of the second source gas is stopped and an excess second source gas in the chamber is purged. Furthermore, the precursor containing indium is adsorbed onto the zinc oxide by the above method (corresponding to FIG. 6C).

The above steps of forming indium oxide, gallium oxide, and zinc oxide are regarded as one cycle and the cycle is repeated, whereby an In-Ga-Zn oxide with In:Ga:Zn=1:1:1 [atomic ratio] having a desired thickness can be formed.

The first source gas to the fourth source gas are introduced in a pulsed form. The pulse time of introducing the first source gas, the third source gas, and the fourth source gas into the chamber 4520 is preferably longer than or equal to 0.05 seconds and shorter than or equal to 1 second, further preferably longer than or equal to 0.1 seconds and shorter than or equal to 0.5 seconds. The time for evacuating the first source gas, the third source gas, and the fourth source gas from the chamber 4520 is longer than or equal to 0.1 seconds and shorter than or equal to 15 seconds, preferably longer than or equal to 0.5 seconds and shorter than or equal to 10 seconds. The pulse time of introducing the second source gas into the chamber 4520 is preferably longer than or equal to 0.05 seconds and shorter than or equal to 30 seconds, further preferably longer than or equal to 0.1 seconds and shorter than or equal to 15 seconds. The time for evacuating the second source gas from the chamber 4520 is longer than or equal to 0.1 seconds and shorter than or equal to 15 seconds, preferably longer than or equal to 0.1 seconds and shorter than or equal to 5 seconds.

Note that in the sequence shown in FIG. 10B, the order of introduction of the first source gas, the third source gas, and the fourth source gas is not limited thereto. For example, the fourth gas containing the precursor containing zinc may be introduced first. Since zinc oxide is likely to form a crystal structure as compared to indium oxide and gallium oxide, a stable crystal of zinc oxide can be formed in a bottom layer. Accordingly, layers of indium oxide and gallium oxide can be comparatively easily formed over the zinc oxide.

Deposition of an In-Ga-Zn oxide with In:Ga:Zn=1:1:1 [atomic ratio] is described above; however, the present invention is not limited thereto. An In-Ga-Zn oxide with a different atomic ratio can be formed by a similar method. The number of pulses or the pulse time of a source gas containing a precursor in one cycle is preferably set in accordance with the atomic ratio of a desired In-Ga-Zn oxide.

For example, in the sequence shown in FIG. 10B, in order to deposit an In-Ga-Zn oxide with In:Ga:Zn=1:1:1 [atomic ratio], the numbers of pulses of the first source gas containing indium, the third source gas containing gallium, and the fourth source gas containing zinc were each one in one cycle. Here, the pulse times of the precursors are the same.

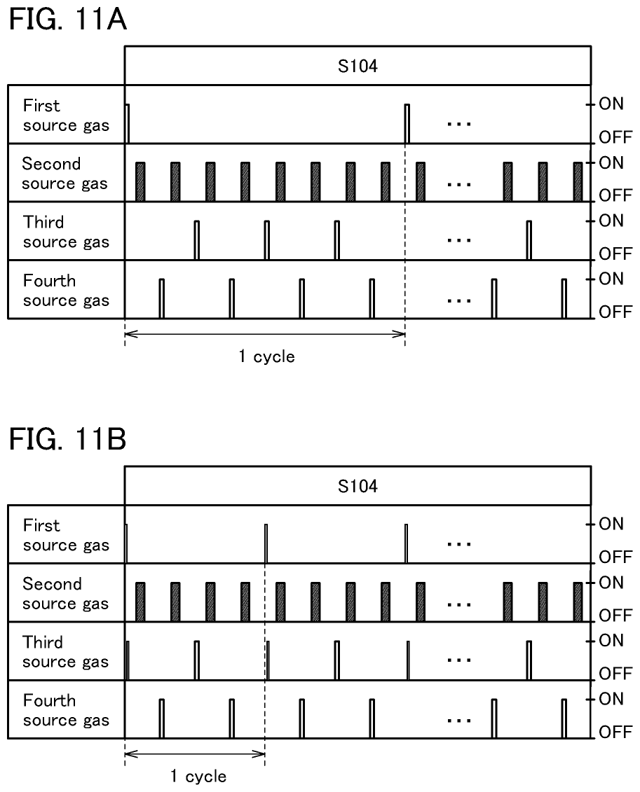

FIG. 11A shows an example of a deposition sequence of an In-Ga-Zn oxide with In:Ga: Zn=1:3:4 [atomic ratio]. In FIG. 11A, in one cycle, the number of pulses of the first source gas containing indium is one, the number of pulses of the third source gas containing gallium is three, and the number of pulses of the fourth source gas containing zinc is four. That is, the numbers of pulses of the source gases containing precursors correspond to In:Ga:Zn=1:3:4 [atomic ratio]. By performing deposition in such a manner, a metal oxide having a layered crystal structure according to FIG. 2D can be formed.

Furthermore, by performing deposition by an ALD method while a substrate is being heated as described above, rearrangement of oxide layers can be promoted. Accordingly, even when deposition is performed in accordance with the sequence shown in FIG. 11A, a layer in which one oxide layer contains two kinds of metal elements (indium and gallium) can be formed like the layer 22 illustrated in FIG. 2D.

Note that in the above, introductions of different kinds of precursors are performed while the source gas containing a reactant is introduced therebetween; however, the present invention is not limited thereto. For example, introductions of source gases containing the same kind of precursor are successively performed while the source gas containing a reactant is introduced therebetween. At this time, the numbers of pulses of the source gases containing the precursors in one cycle is preferably the same as the atomic ratio of a desired In-Ga-Zn oxide.

Moreover, in the above, the structure in which only the source gas containing one kind of precursor is introduced during the interval in which oxidation using the second source gas is performed is shown; however, the present invention is not limited thereto. Two or more kinds of source gases containing precursors may be introduced during the interval in which oxidation using the second source gas is performed. At this time, two or more kinds of source gases containing precursors may be introduced at the same time. Alternatively, the same kind of precursor may be successively introduced twice during the interval in which oxidation using the second source gas is performed.

For example, when an In-Ga-Zn oxide with In:Ga:Zn=1:3:4 [atomic ratio] is deposited, the deposition may be performed in a sequence shown in FIG. 11B. In FIG. 11B, in accordance with the crystal structure illustrated in FIG. 2D in which the layer 22, the layer 41, the layer 31, and the layer 41 are stacked in this order, the first source gas, the third source gas, the fourth source gas, the third source gas, and the fourth source gas are introduced in this order. Note that first introductions of the first source gas and the third source gas are performed without introducing the second source gas therebetween. In other words, the precursor containing indium contained in the first source gas and the precursor containing gallium contained in the third source gas are adsorbed, and then an oxidizer is introduced. Accordingly, like the layer 22 illustrated in FIG. 2D, a layer in which one oxide layer contains two kinds of metal elements (indium and gallium) can be formed. At this time, the pulse time of each of the first source gas and the third source gas is preferably approximately half of the pulse time of the fourth source gas. Accordingly, as shown in FIG. 11B, the ratio of the pulse time of the first source gas containing indium to the pulse time of the third source gas containing gallium and the pulse time of the fourth source gas containing zinc in one cycle can be 1:3:4, which is the same as the atomic ratio.

Deposition of the oxide with a constant atomic ratio is described above; however, the present invention is not limited thereto. Two or more kinds of oxides with different atomic ratios can be successively deposited by a similar method. In this case, for stacked oxides with different atomic ratios, the number of pulses or the pulse time of a source gas containing a precursor in one cycle is preferably set in accordance with the atomic ratios of the oxides. When deposition is performed in such a manner, the stacked oxides with different atomic ratios can be deposited in one chamber. Thus, entry of an impurity such as hydrogen or carbon can be prevented in the interval in which the oxide is deposited.

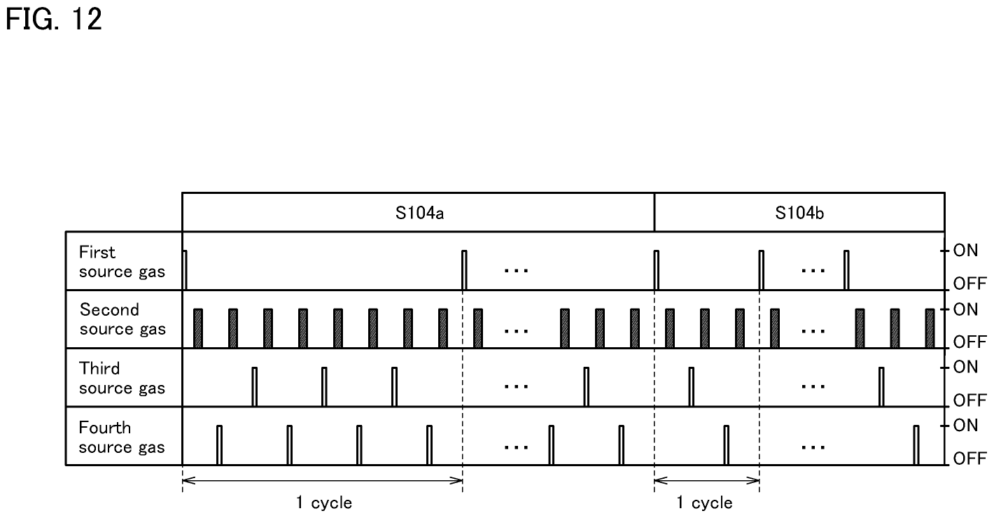

FIG. 12 shows an example of a deposition sequence in the case where an oxide with In: Ga:Zn=1:1:1 [atomic ratio] is stacked over an oxide with In:Ga:Zn=1:3:4 [atomic ratio]. Step 104a corresponds to the oxide with In:Ga:Zn=1:3:4 [atomic ratio] and is similar to the sequence shown in FIG. 11A. Step 104b corresponds to the oxide with In:Ga:Zn=1:1:1 [atomic ratio] and is similar to the sequence shown in FIG. 10B. As described above, the number of pulses in one cycle in the former period is the first source gas: the third source gas: the fourth source gas=1:3:4 and the number of pulses in one cycle in the latter period is the first source gas: the third source gas: the fourth source gas=1:1:1, so that a metal oxide having a stacked-layer structure including the oxide 62 and the oxide 60 illustrated in FIG. 3B can be deposited. In other words, deposition is performed in the former period with the number of pulses corresponding to In:Ga: Zn=1:3:4 [atomic ratio] and deposition is performed in the latter period with the number of pulses corresponding to In:Ga:Zn=1:1:1 [atomic ratio].

In the above, the deposition method is described using an In-Ga-Zn oxide as an example; however, the present invention is not limited thereto. A precursor is set as appropriate in accordance with a metal element contained in a desired metal oxide. In the above, one or three kinds of precursors are used; however, without limitation to this, two or four or more kinds may be used.

In the above, the example in which deposition is performed using a precursor containing one kind of metal element is described; however, the present invention is not limited thereto. A precursor containing two or more kinds of metal elements may be used. For example, a precursor containing indium and gallium or a precursor containing gallium and zinc may be used. In such a case, the number of source material supply portions 4521 illustrated in FIG. 8A and the like can be reduced.

### <Classification of Crystal Structures>

Hereinafter, the classification of the crystal structures of the above metal oxide (oxide semiconductor) is explained.

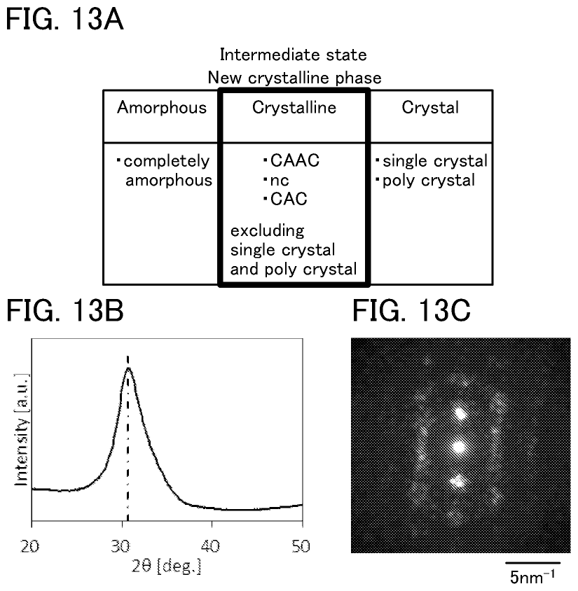

First, the classification of the crystal structures of an oxide semiconductor is described with reference to FIG. 13A. FIG. 13A is a diagram showing the classification of crystal structures of an oxide semiconductor, typically IGZO (a metal oxide containing In, Ga, and Zn).

As shown in FIG. 13A, an oxide semiconductor is roughly classified into “Amorphous”, “Crystalline”, and “Crystal”. The term “Amorphous” includes completely amorphous. The term “Crystalline” includes CAAC (c-axis-aligned crystalline), nc (nanocrystalline), and CAC (cloud-aligned composite) (excluding single crystal and poly crystal). Note that the term “Crystalline” excludes single crystal, poly crystal, and completely amorphous. The term “Crystal” includes single crystal and poly crystal.

Note that the structures in the thick frame in FIG. 13A are in an intermediate state between “Amorphous” and “Crystal”, and belong to a new crystalline phase. That is, these structures are completely different from “Amorphous”, which is energetically unstable, or “Crystal”.

A crystal structure of a film or a substrate can be analyzed with an X-ray diffraction (XRD) spectrum. Here, FIG. 13B shows an XRD spectrum, which is obtained by GIXD (Grazing-Incidence XRD) measurement, of a CAAC-IGZO film classified into “Crystalline”. Note that a GIXD method is also referred to as a thin film method or a Seemann—Bohlin method. The XRD spectrum that is shown in FIG. 13B and obtained by GIXD measurement is hereinafter simply referred to as an XRD spectrum. The CAAC-IGZO film shown in FIG. 13B has a composition in the vicinity of In:Ga:Zn=4:2:3 [atomic ratio]. The CAAC-IGZO film shown in FIG. 13B has a thickness of 500 nm.

As shown in FIG. 13B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. 13B, the peak at 2θ of around 31° is asymmetric with respect to the axis of the angle at which the peak intensity is detected.

A crystal structure of a film or a substrate can also be evaluated with a diffraction pattern obtained by a nanobeam electron diffraction method (NBED) (such a pattern is also referred to as a nanobeam electron diffraction pattern). FIG. 13C shows a diffraction pattern of the CAAC-IGZO film. FIG. 13C shows a diffraction pattern obtained with the NBED method in which an electron beam is incident in the direction parallel to the substrate. The composition of the CAAC-IGZO film shown in FIG. 13C is In:Ga:Zn=4:2:3 [atomic ratio] or the neighborhood thereof. In the nanobeam electron diffraction method, electron diffraction is performed with a probe diameter of 1 nm.

As shown in FIG. 13C, a plurality of spots indicating c-axis alignment are observed in the diffraction pattern of the CAAC-IGZO film.

### <Metal Oxide Having CAAC Structure>

The details of a metal oxide having a CAAC structure are described below.

The CAAC structure includes a plurality of crystals and each of the plurality of crystals has c-axis alignment in a particular direction. Note that the particular direction refers to the thickness direction of a metal oxide having the CAAC structure, the normal direction of the surface where the metal oxide having the CAAC structure is formed, or the normal direction of the surface of the metal oxide having the CAAC structure. In the case where a crystal region is denoted, the crystal region refers to a crystal itself included in the CAAC structure, or a crystal included in the CAAC structure and a region in the vicinity thereof. Thus, a crystal included in the CAAC structure is sometimes referred to as a crystal region included in the CAAC structure.

The crystal region refers to a region having a periodic atomic arrangement. When an atomic arrangement is regarded as a lattice arrangement, the crystal region also refers to a region with a uniform lattice arrangement. The CAAC structure has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, a metal oxide having the CAAC structure is a metal oxide having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the elementM is one kind or two or more kinds selected from aluminum, gallium, yttrium, tin, titanium, and the like), the CAAC structure tends to have a layered crystal structure (also referred to as a layered structure) in which a layer containing indium (In) and oxygen and a layer containing the element M, zinc (Zn), and oxygen are stacked. Note that the layer containing indium and oxygen may contain the element M or zinc. The layer containing the element M, zinc, and oxygen may contain indium. Such a layered structure is observed as a lattice image in a high-resolution TEM image, for example.

When a metal oxide having the CAAC structure is subjected to structural analysis by out-of-plane XRD measurement with an XRD apparatus using 0120 scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the metal oxide.

For example, a plurality of bright spots are observed in the electron diffraction pattern of a metal oxide having the CAAC structure. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in a metal oxide having the CAAC structure. That is, formation of a grain boundary is inhibited by the distortion of lattice arrangement. This is probably because a metal oxide having the CAAC structure can tolerate distortion owing to a low density of arrangement of oxygen atoms in the a-b plane direction, an interatomic bond distance changed by substitution of a metal atom, and the like.

A metal oxide having the CAAC structure is a metal oxide with high crystallinity in which no clear grain boundary is observed. Thus, a reduction in electron mobility due to the grain boundary is less likely to occur in a metal oxide having the CAAC. Thus, a metal oxide having the CAAC structure is physically stable. Therefore, a metal oxide having the CAAC structure is resistant to heat and has high reliability. Thus, a metal oxide having the CAAC structure is one of crystalline oxides having a crystal structure suitable for a semiconductor layer of a transistor.

### <Transistor Including Metal Oxide>

Next, the case where a metal oxide (oxide semiconductor) is used for a transistor will be described.

When a metal oxide (oxide semiconductor) of one embodiment of the present invention is used for a transistor, a transistor with high field-effect mobility can be achieved. In addition, a transistor having high reliability can be achieved. Furthermore, a miniaturized or highly integrated transistor can be achieved. For example, a transistor with a channel length of greater than or equal to 2 nm and less than or equal to 30 nm can be fabricated.

An oxide semiconductor with a low carrier concentration is preferably used for a channel formation region of the transistor. For example, the carrier concentration in an oxide semiconductor in the channel formation region is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity in Metal Oxide>

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the concentration of silicon or carbon in the oxide semiconductor in the channel formation region and the concentration of silicon or carbon in the vicinity of an interface with the oxide semiconductor in the channel formation region (the concentrations obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor in the channel formation region, which is obtained by SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type because of generation of electrons serving as carriers and an increase in carrier concentration. As a result, a transistor using an oxide semiconductor containing nitrogen as a semiconductor is likely to have normally-on characteristics. When the oxide semiconductor contains nitrogen, a trap state is sometimes formed. This might make the electrical characteristics of the transistor unstable. Therefore, the concentration of nitrogen in the oxide semiconductor in the channel formation region, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor in the channel formation region is preferably reduced as much as possible. Specifically, the hydrogen concentration in the oxide semiconductor in the channel formation region, which is obtained by SIMS, is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³.

When an oxide semiconductor with sufficiently reduced impurities is used for the channel formation region of the transistor, stable electrical characteristics can be given.

<Other Materials that can be Used for Semiconductor Layer of Transistor>

One embodiment of the present invention is not limited to the above metal oxide. For example, a layered material may be used. The layered material has high electrical conductivity in a monolayer, that is, high two-dimensional electrical conductivity. When a material that functions as a semiconductor and has high two-dimensional electrical conductivity is used for a channel formation region, a transistor having a high on-state current can be provided.

Examples of the layered material include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

For a semiconductor layer of a transistor, a transition metal chalcogenide functioning as a semiconductor is preferably used, for example. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The structure, method, and the like described in this embodiment can be used in an appropriate combination with other structures, methods, and the like described in this embodiment or the other embodiments.

### Embodiment 2

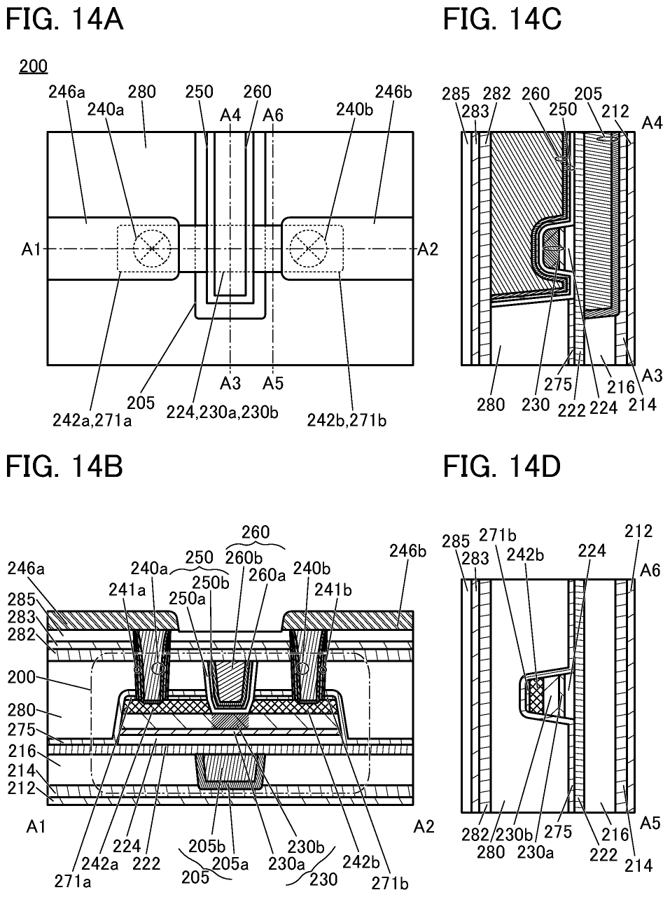

In this embodiment, an example of a semiconductor device including a transistor 200 including the metal oxide described in the above embodiment and a manufacturing method thereof are described using FIG. 14 to FIG. 30.

### <Structure Example of Semiconductor Device>

A structure of a semiconductor device including the transistor 200 is described using FIG. 14. FIG. 14A to FIG. 14D are a top view and cross-sectional views of the semiconductor device including the transistor 200. FIG. 14A is a top view of the semiconductor device. FIG. 14B to FIG. 14D are cross-sectional views of the semiconductor device. Here, FIG. 14B is a cross-sectional view of a portion indicated by dashed-dotted line A1-A2 in FIG. 14A, and is also a cross-sectional view of the transistor 200 in the channel length direction. FIG. 14C is a cross-sectional view of a portion indicated by dashed-dotted line A3-A4 in FIG. 14A, and is also a cross-sectional view of the transistor 200 in the channel width direction. FIG. 14D is a cross-sectional view of a portion indicated by dashed-dotted line A5-A6 in FIG. 14A. Note that for clarity of the drawing, some components are omitted in the top view of FIG. 14A.

The semiconductor device of one embodiment of the present invention includes an insulator 212 over a substrate (not illustrated), an insulator 214 over the insulator 212, the transistor 200 over the insulator 214, an insulator 280 over the transistor 200, an insulator 282 over the insulator 280, an insulator 283 over the insulator 282, and an insulator 285 over the insulator 283. The insulator 212, the insulator 214, the insulator 280, the insulator 282, the insulator 283, and the insulator 285 function as interlayer insulating films. A conductor 240 (a conductor 240a and a conductor 240b) that is electrically connected to the transistor 200 and functions as a plug is also included. Note that an insulator 241 (an insulator 241a and an insulator 241b) is provided in contact with side surfaces of the conductor 240 functioning as a plug. A conductor 246 (a conductor 246a and a conductor 246b) that is electrically connected to the conductor 240 and functions as a wiring is provided over the insulator 285 and the conductor 240.

The insulator 241a is provided in contact with an inner wall of an opening in the insulator 280, the insulator 282, the insulator 283, and the insulator 285, and the conductor 240a is provided in contact with a side surface of the insulator 241a. The insulator 241b is provided in contact with an inner wall of an opening in the insulator 280, the insulator 282, the insulator 283, and the insulator 285, and the conductor 240b is provided in contact with a side surface of the insulator 241b. The insulator 241 has a structure in which a first insulator is provided in contact with the inner wall of the opening and a second insulator is provided on the inner side. The conductor 240 has a structure in which a first conductor is provided in contact with the side surface of the insulator 241 and a second conductor is provided on the inner side.

Note that although the transistor 200 has a structure in which the first insulator of the insulator 241 and the second insulator of the insulator 241 are stacked, the present invention is not limited thereto. For example, the insulator 241 may be provided as a single layer or to have a stacked-layer structure of three or more layers. Although the transistor 200 has a structure in which the first conductor of the conductor 240 and the second conductor of the conductor 240 are stacked, the present invention is not limited thereto. For example, the conductor 240 may have a single-layer structure or a stacked-layer structure of three or more layers. In the case where a stacked-layer structure is employed, the layers may be distinguished by numbers corresponding to the formation order.

### [Transistor 200]

As illustrated in FIG. 14A to FIG. 14D, the transistor 200 includes an insulator 216 over the insulator 214; a conductor 205 (a conductor 205a and a conductor 205b) placed to be embedded in the insulator 216; an insulator 222 over the insulator 216 and the conductor 205; an insulator 224 over the insulator 222; an oxide 230a over the insulator 224; an oxide 230b over the oxide 230a; a conductor 242a over the oxide 230b; an insulator 271a over the conductor 242a; a conductor 242b over the oxide 230b; an insulator 271b over the conductor 242b; an insulator 250 (an insulator 250a and an insulator 250b) over the oxide 230b; a conductor 260 (a conductor 260a and a conductor 260b) positioned over the insulator 250 and overlapping with part of the oxide 230b; and an insulator 275 placed to cover the insulator 222, the insulator 224, the oxide 230a, the oxide 230b, the conductor 242a, the conductor 242b, the insulator 271a, and the insulator 271b.

Hereinafter, the oxide 230a and the oxide 230b are collectively referred to as an oxide 230 in some cases. The conductor 242a and the conductor 242b are collectively referred to as a conductor 242 in some cases. The insulator 271a and the insulator 271b are collectively referred to as an insulator 271 in some cases.

An opening reaching the oxide 230b is provided in the insulator 280 and the insulator 275. The insulator 250 and the conductor 260 are placed in the opening. In addition, in the channel length direction of the transistor 200, the conductor 260 and the insulator 250 are provided between the insulator 271a and the conductor 242a, and the insulator 271b and the conductor 242b. The insulator 250 includes a region in contact with a side surface of the conductor 260 and a region in contact with a bottom surface of the conductor 260.

The oxide 230 preferably includes the oxide 230a placed over the insulator 224 and the oxide 230b placed over the oxide 230a. With the oxide 230a positioned under the oxide 230b, diffusion of impurities from components formed below the oxide 230a into the oxide 230b can be inhibited.

Note that although the transistor 200 is illustrated to have a structure in which two layers, the oxide 230a and the oxide 230b, are stacked, the present invention is not limited thereto. For example, the oxide 230 may be provided as a single layer of the oxide 230b or to have a stacked-layer structure of three or more layers, or the oxide 230a and the oxide 230b may each have a stacked-layer structure.

The conductor 260 functions as a first gate (also referred to as a top gate) electrode, and the conductor 205 functions as a second gate (also referred to as a back gate) electrode. The insulator 250 functions as a first gate insulating film, and the insulator 224 and the insulator 222 function as a second gate insulating film. The conductor 242a functions as one of a source electrode and a drain electrode, and the conductor 242b functions as the other of the source electrode and the drain electrode. A region of the oxide 230 that overlaps with the conductor 260 at least partly functions as a channel formation region.

In the transistor 200, the metal oxide described in the above embodiment (such a metal oxide is hereinafter also referred to as an oxide semiconductor) is preferably used for the oxide 230 (the oxide 230a and the oxide 230b) including the channel formation region.

The metal oxide described in the above embodiment can function as a semiconductor. Here, the metal oxide has a band gap of 2 eV or more, preferably 2.5 eV or more. With the use of a metal oxide having such a wide band gap, the off-state current of the transistor can be reduced.

As the oxide 230, it is preferable to use, for example, a metal oxide such as an In-M-Zn oxide containing indium, an element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like). Alternatively, an In-Ga oxide, an In-Zn oxide, or indium oxide may be used as the oxide 230.

The atomic ratio of In to the element M in the metal oxide used as the oxide 230b is preferably greater than the atomic ratio of In to the element Min the metal oxide used as the oxide 230a. For example, the metal oxide illustrated in FIG. 2D in the above embodiment can be used as the oxide 230a. For example, the metal oxide illustrated in FIG. 2B in the above embodiment can be used as the oxide 230b.

With the oxide 230a placed under the oxide 230b as described above, diffusion of impurities and oxygen from components formed below the oxide 230a into the oxide 230b can be inhibited.

When the oxide 230a and the oxide 230b contain a common element (as the main component) besides oxygen, the density of defect states at an interface between the oxide 230a and the oxide 230b can be made low. Since the density of defect states at the interface between the oxide 230a and the oxide 230b can be made low, the influence of interface scattering on carrier conduction is small, and a high on-state current can be obtained.

The oxide 230b preferably has crystallinity. It is particularly preferable to use a CAAC-OS (c-axis aligned crystalline oxide semiconductor) as the oxide 230b. By employing the deposition method described in the above embodiment, a CAAC-OS having reduced impurities and a favorable crystal can be formed.

The CAAC-OS is a metal oxide having a dense structure with high crystallinity and a small amount of impurities or defects (e.g., oxygen vacancies (Vo)). In particular, after the formation of a metal oxide, heat treatment is performed at a temperature at which the metal oxide does not become a polycrystal (e.g., 400° C. to 600° C.), whereby a CAAC-OS having a dense structure with higher crystallinity can be obtained. When the density of the CAAC-OS is increased in such a manner, diffusion of impurities or oxygen in the CAAC-OS can be further reduced.

On the other hand, a clear grain boundary is difficult to observe in the CAAC-OS; thus, it can be said that a reduction in electron mobility due to the grain boundary is unlikely to occur. Thus, a metal oxide including a CAAC-OS is physically stable. Therefore, the metal oxide including a CAAC-OS is resistant to heat and has high reliability.

An oxide having crystallinity, such as a CAAC-OS, has a dense structure with small amounts of impurities and defects (e.g., oxygen vacancies) and high crystallinity, which can inhibit oxygen extraction from the oxide 230b by the source electrode or the drain electrode. This can reduce oxygen extraction from the oxide 230b even when heat treatment is performed; thus, the transistor 200 is stable with respect to high temperatures in a manufacturing process (what is called thermal budget).

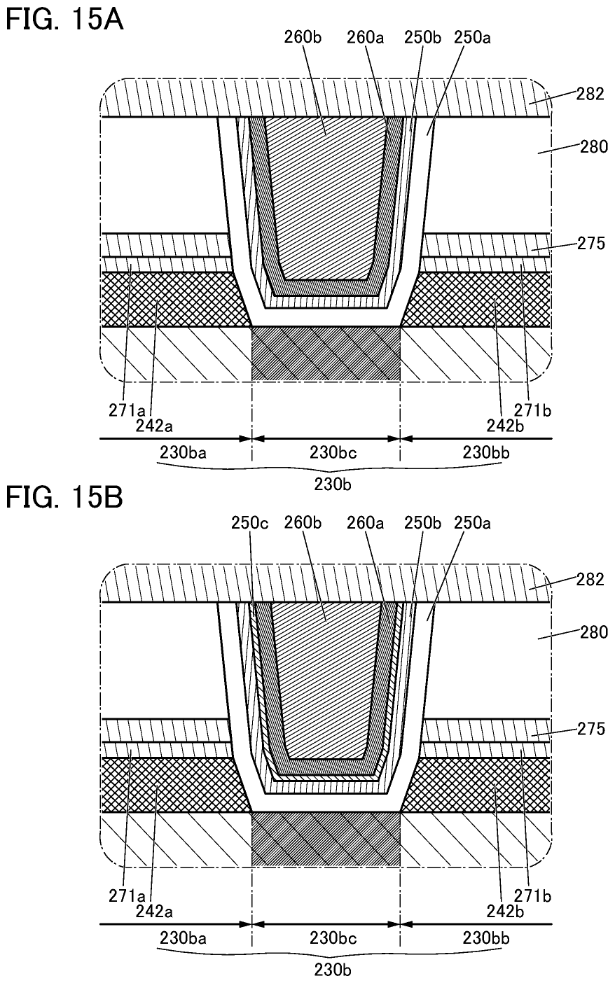

Here, an enlarged view of the vicinity of a channel formation region of the transistor 200 is shown in FIG. 15A. Supply of oxygen to the oxide 230b forms the channel formation region in a region between the conductor 242a and the conductor 242b. Thus, as illustrated in FIG. 15A, the oxide 230b includes a region 230bc functioning as the channel formation region of the transistor 200 and a region 230ba and a region 230bb that are provided to sandwich the region 230bc and function as a source region and a drain region. At least part of the region 230bc overlaps with the conductor 260. In other words, the region 230bc is provided between the conductor 242a and the conductor 242b. The region 230ba is provided to overlap with the conductor 242a, and the region 230bb is provided to overlap with the conductor 242b.

The region 230bc functioning as the channel formation region is a high-resistance region with a low carrier concentration because it includes a smaller amount of oxygen vacancies or has a lower impurity concentration than the region 230ba and the region 230bb. Thus, the region 230bc can be regarded as being i-type (intrinsic) or substantially i-type.

The region 230ba and the region 230bb functioning as the source region and the drain region are each a low-resistance region with an increased carrier concentration because it includes a large amount of oxygen vacancies and has a high concentration of an impurity such as hydrogen, nitrogen, or a metal element. In other words, the region 230ba and the region 230bb are each an n-type region having a higher carrier concentration and a lower resistance than the region 230bc.

Here, the carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet further preferably lower than 1×10¹² cm⁻³. Note that the lower limit of the carrier concentration in the region 230bc functioning as the channel formation region is not particularly limited and can be, for example, 1×10⁻⁹ cm⁻³.

A region having a carrier concentration that is lower than or substantially equal to the carrier concentrations in the region 230ba and the region 230bb and higher than or substantially equal to the carrier concentration in the region 230bc may be formed between the region 230bc and the region 230ba or the region 230bb. That is, the region functions as a junction region between the region 230bc and the region 230ba or the region 230bb. The hydrogen concentration in the junction region is sometimes lower than or substantially equal to the hydrogen concentrations in the region 230ba and the region 230bb and higher than or substantially equal to the hydrogen concentration in the region 230bc. The amount of oxygen vacancies in the junction region is sometimes smaller than or substantially equal to the amounts of oxygen vacancies in the region 230ba and the region 230bb and larger than or substantially equal to the amount of oxygen vacancies in the region 230bc.

Although FIG. 15A illustrates an example in which the region 230ba, the region 230bb, and the region 230bc are formed in the oxide 230b, the present invention is not limited thereto. For example, the above regions may be formed not only in the oxide 230b but also in the oxide 230a.

In the oxide 230, the boundaries between the regions are difficult to detect clearly in some cases. The concentration of a metal element and an impurity element such as hydrogen and nitrogen, which is detected in each region, may be gradually changed not only between the regions but also in each region. That is, the region closer to the channel formation region preferably has a lower concentration of a metal element and an impurity element such as hydrogen and nitrogen.

As illustrated in FIG. 14C, a curved surface may be provided between a side surface of the oxide 230b and a top surface of the oxide 230b in the cross-sectional view in the channel width direction of the transistor 200. That is, an end portion of the side surface and an end portion of the top surface may be curved (such a shape is also referred to as a rounded shape).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 250 and the conductor 260.

The oxide 230 preferably has a stacked-layer structure of a plurality of oxide layers with different chemical compositions. Specifically, the atomic ratio of the element M to the metal element of the main component in the metal oxide used as the oxide 230a is preferably greater than the atomic ratio of the element M to the metal element of the main component in the metal oxide used as the oxide 230b. Moreover, the atomic ratio of the element M to In in the metal oxide used as the oxide 230a is preferably greater than the atomic ratio of the element M to In in the metal oxide used as the oxide 230b. Furthermore, the atomic ratio of In to the element Min the metal oxide used as the oxide 230b is preferably greater than the atomic ratio of In to the element M in the metal oxide used as the oxide 230a. By employing the deposition method described in the above embodiment, the oxide 230a and the oxide 230b that have different atomic ratios can be successively deposited in one chamber. Accordingly, excessive entry of impurities such as hydrogen into an interface between the oxide 230a and the oxide 230b can be prevented, for example.

Here, the conduction band minimum gradually changes at a junction portion of the oxide 230a and the oxide 230b. In other words, the conduction band minimum at the junction portion of the oxide 230a and the oxide 230b continuously changes or is continuously connected. To obtain this, the density of defect states in a mixed layer formed at the interface between the oxide 230a and the oxide 230b is preferably decreased.

Specifically, when the oxide 230a and the oxide 230b contain the same element as a main component in addition to oxygen, a mixed layer with a low density of defect states can be formed. For example, in the case where the oxide 230b is an In-M-Zn oxide, an In-M-Zn oxide, an M-Zn oxide, an oxide of the element M, an In-Zn oxide, indium oxide, or the like may be used as the oxide 230a.

Specifically, as the oxide 230a, a metal oxide with In:M:Zn=1:3:4 [atomic ratio] or a composition in the neighborhood thereof, or In:M:Zn=1:1:0.5 [atomic ratio] or a composition in the neighborhood thereof is used. As the oxide 230b, a metal oxide with In:M:Zn=1:1:1 [atomic ratio] or a composition in the neighborhood thereof, In:M:Zn=4:2:3 [atomic ratio] or a composition in the neighborhood thereof, or In:M:Zn=5:1:3 [atomic ratio] or a composition in the neighborhood thereof is used. Note that a composition in the neighborhood includes the range of ±30% of a desired atomic ratio. Gallium is preferably used as the element M By employing the deposition method described in the above embodiment, metal oxides with a variety of atomic ratios described above can be formed relatively easily.

When the oxide 230a and the oxide 230b have the above structure, the density of defect states at the interface between the oxide 230a and the oxide 230b can be made low. Thus, the influence of interface scattering on carrier conduction is small, and the transistor 200 can have a high on-state current and excellent frequency characteristics.

Note that although the transistor 200 is illustrated to have a structure in which two layers, the oxide 230a and the oxide 230b, are stacked in the oxide 230, the present invention is not limited thereto. For example, a single layer of the oxide 230b or a stacked-layer structure of three or more layers may be provided. The oxide 230a and the oxide 230b may each have a stacked-layer structure. In the case where the oxide 230 has a stacked-layer structure of three or more layers, like the insulator 250, part of the stacked-layer structure of the oxide 230 may be formed in the opening formed in the insulator 280 and the insulator 275.

At least one of the insulator 212, the insulator 214, the insulator 271, the insulator 275, the insulator 282, and the insulator 283 preferably functions as a barrier insulating film, which inhibits diffusion of impurities such as water and hydrogen from the substrate side or above the transistor 200 into the transistor 200. Thus, for at least one of the insulator 212, the insulator 214, the insulator 271, the insulator 275, the insulator 282, and the insulator 283, an insulating material which has a function of inhibiting diffusion of impurities such as hydrogen atoms, hydrogen molecules, water molecules, nitrogen atoms, nitrogen molecules, nitrogen oxide molecules (e.g., N₂O, NO, or NO₂), or copper atoms (through which the impurities are less likely to pass) is preferably used. Alternatively, it is preferable to use an insulating material which has a function of inhibiting diffusion of oxygen (e.g., at least one of an oxygen atom, an oxygen molecule, and the like) (through which the above oxygen is less likely to pass).

Note that in this specification, a barrier insulating film refers to an insulating film having a barrier property. A barrier property in this specification means a function of inhibiting diffusion of a targeted substance (also referred to as having lower permeability). Alternatively, a barrier property in this specification means a function of capturing or fixing (also referred to as gettering) a targeted substance.

Aluminum oxide, magnesium oxide, hafnium oxide, gallium oxide, indium gallium zinc oxide, silicon nitride, or silicon nitride oxide can be used for the insulator 212, the insulator 214, the insulator 271, the insulator 275, the insulator 282, and the insulator 283, for example. For example, silicon nitride, which has a higher hydrogen barrier property, is preferably used for the insulator 212, the insulator 275, and the insulator 283. For example, aluminum oxide or magnesium oxide, which has a function of capturing or fixing more hydrogen, is preferably used for the insulator 214, the insulator 271, and the insulator 282. In this case, impurities such as water and hydrogen can be inhibited from being diffused to the transistor 200 side from the substrate side through the insulator 212 and the insulator 214. Impurities such as water and hydrogen can be inhibited from being diffused to the transistor 200 side from an interlayer insulating film and the like which are provided outside the insulator 283. Alternatively, oxygen contained in the insulator 224 or the like can be inhibited from being diffused to the substrate side through the insulator 212 and the insulator 214. Alternatively, oxygen contained in the insulator 280 and the like can be inhibited from being diffused to above the transistor 200 through the insulator 282 and the like. In this manner, it is preferable that the transistor 200 be surrounded with the insulator 212, the insulator 214, the insulator 271, the insulator 275, the insulator 282, and the insulator 283, which have a function of inhibiting diffusion of oxygen and impurities such as water and hydrogen.

Here, an oxide including an amorphous structure is preferably used for at least one of the insulator 212, the insulator 214, the insulator 271, the insulator 275, the insulator 282, and the insulator 283. For example, a metal oxide such as AlOₓ (x is a given number greater than 0) or MgO_{y} (y is a given number greater than 0) is preferably used. In such a metal oxide including an amorphous structure, an oxygen atom has a dangling bond and sometimes has a property of capturing or fixing hydrogen with the dangling bond. When such a metal oxide including an amorphous structure is used as the component of the transistor 200 or provided in the vicinity of the transistor 200, hydrogen contained in the transistor 200 or hydrogen in the vicinity of the transistor 200 can be captured or fixed. In particular, hydrogen contained in the channel formation region of the transistor 200 is preferably captured or fixed. The metal oxide including an amorphous structure is used as the component of the transistor 200 or provided in the vicinity of the transistor 200, whereby the transistor 200 and a semiconductor device which have favorable characteristics and high reliability can be manufactured.

Although at least one of the insulator 212, the insulator 214, the insulator 271, the insulator 275, the insulator 282, and the insulator 283 preferably has an amorphous structure, they may partly include a region with a polycrystalline structure. Alternatively, at least one of the insulator 212, the insulator 214, the insulator 271, the insulator 275, the insulator 282, and the insulator 283 may have a multilayer structure in which a layer with an amorphous structure and a layer with a polycrystalline structure are stacked. For example, a stacked-layer structure in which a layer with a polycrystalline structure is formed over a layer with an amorphous structure may be employed.

The insulator 212, the insulator 214, the insulator 271, the insulator 275, the insulator 282, and the insulator 283 are deposited by a sputtering method, for example. Since a sputtering method does not need to use hydrogen as a deposition gas, the hydrogen concentrations in the insulator 212, the insulator 214, the insulator 271, the insulator 275, the insulator 282, and the insulator 283 can be reduced. The deposition method is not limited to a sputtering method; a chemical vapor deposition (CVD) method, a molecular beam epitaxy (MBE) method, a pulsed laser deposition (PLD) method, an atomic layer deposition (ALD) method, or the like may be used as appropriate. For example, the insulator 275 may be deposited by an ALD method with relatively favorable coverage. Among ALD methods, a PEALD method in which deposition temperature can be relatively low may be employed.

The resistivities of the insulator 212 and the insulator 283 are preferably low in some cases. For example, by setting the resistivities of the insulator 212 and the insulator 283 to approximately 1×10¹³ Ωcm, the insulator 212 and the insulator 283 can sometimes reduce charge up of the conductor 205, the conductor 242, the conductor 260, or the conductor 246 in treatment using plasma or the like in the manufacturing process of a semiconductor device. The resistivities of the insulator 212 and the insulator 283 are preferably higher than or equal to 1×10¹⁰ Ωcm and lower than or equal to 1×10¹⁵ Ωcm.

The insulator 216 and the insulator 280 preferably have a lower permittivity than the insulator 214. When a material with a low permittivity is used for an interlayer insulating film, parasitic capacitance generated between wirings can be reduced. For the insulator 216 and the insulator 280, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate, for example.

The conductor 205 is placed to overlap with the oxide 230 and the conductor 260. Here, the conductor 205 is preferably provided to be embedded in an opening formed in the insulator 216. Part of the conductor 205 is provided to be embedded in the insulator 214 in some cases.

The conductor 205 includes the conductor 205a and the conductor 205b. The conductor 205a is provided in contact with a bottom surface and a sidewall of the opening. The conductor 205b is provided to be embedded in a recessed portion formed in the conductor 205a. Here, the level of a top surface of the conductor 205b is substantially the same as the level of the uppermost portion of the conductor 205a and the level of the top surface of the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from being diffused into the oxide 230 through the insulator 224 and the like. When the conductor 205a is formed using a conductive material having a function of inhibiting diffusion of oxygen, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, a single layer or a stacked layer of the above conductive material is used as the conductor 205a. For example, titanium nitride is used for the conductor 205a.

Moreover, the conductor 205b is preferably formed using a conductive material containing tungsten, copper, or aluminum as its main component. For example, tungsten is used for the conductor 205b.

The conductor 205 sometimes functions as a second gate electrode. In that case, by changing a potential applied to the conductor 205 not in conjunction with but independently of a potential applied to the conductor 260, the threshold voltage (Vth) of the transistor 200 can be controlled. In particular, Vth of the transistor 200 can be higher in the case where a negative potential is applied to the conductor 205 than in the case where a potential is not applied to the conductor 205, and the off-state current can be reduced. Thus, a drain current at the time when a potential applied to the conductor 260 is 0 V can be lower in the case where a negative potential is applied to the conductor 205 than in the case where the negative potential is not applied to the conductor 205.

As illustrated in FIG. 14A, the conductor 205 is preferably provided to be larger than a region of the oxide 230 that does not overlap with the conductor 242a or the conductor 242b. As illustrated in FIG. 14C, it is particularly preferable that the conductor 205 extend to a region outside end portions of the oxide 230a and the oxide 230b that intersect with the channel width direction. That is, the conductor 205 and the conductor 260 preferably overlap each other with the insulators therebetween on the outer side of a side surface of the oxide 230 in the channel width direction. With this structure, the channel formation region of the oxide 230 can be electrically surrounded by the electric field of the conductor 260 functioning as a first gate electrode and the electric field of the conductor 205 functioning as the second gate electrode. In this specification, a transistor structure in which a channel formation region is electrically surrounded by electric fields of a first gate and a second gate is referred to as a surrounded channel (S-channel) structure.

In this specification and the like, the S-channel structure refers to a transistor structure in which a channel formation region is electrically surrounded by electric fields of a pair of gate electrodes. The S-channel structure disclosed in this specification and the like is different from a Fin-type structure and a planar structure. With the S-channel structure, resistance to a short-channel effect can be enhanced, that is, a transistor in which a short-channel effect is unlikely to occur can be provided.

Furthermore, as illustrated in FIG. 14C, the conductor 205 is extended to function as a wiring as well. However, without limitation to this structure, a structure in which a conductor functioning as a wiring is provided below the conductor 205 may be employed. In addition, the conductor 205 does not necessarily have to be provided in each transistor. For example, the conductor 205 may be shared by a plurality of transistors.

Although the transistor 200 having a structure in which the conductor 205 is a stack of the conductor 205a and the conductor 205b is illustrated, the present invention is not limited thereto. For example, the conductor 205 may be provided to have a single-layer structure or a stacked-layer structure of three or more layers.

The insulator 222 and the insulator 224 function as a gate insulating film.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of further inhibiting diffusion of one or both of hydrogen and oxygen as compared to the insulator 224.

For the insulator 222, an insulator containing an oxide of one or both of aluminum and hafnium, which is an insulating material, is preferably used. It is preferable that aluminum oxide, hafnium oxide, an oxide containing aluminum and hafnium (hafnium aluminate), or the like be used for the insulator. In the case where the insulator 222 is formed using such a material, the insulator 222 functions as a layer that inhibits release of oxygen from the oxide 230 to the substrate side or diffusion of impurities such as hydrogen from the periphery of the transistor 200 into the oxide 230. Thus, providing the insulator 222 can inhibit diffusion of impurities such as hydrogen inside the transistor 200 and inhibit generation of oxygen vacancies in the oxide 230. Moreover, the conductor 205 can be inhibited from reacting with oxygen contained in the insulator 224 or the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of silicon oxide, silicon oxynitride, or silicon nitride over these insulators may be used for the insulator 222.

For example, a single layer or stacked layers of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) may be used for the insulator 222. With miniaturization and high integration of transistors, a problem such as leakage current might arise because of a thinner gate insulator. When a high-k material is used for the insulator functioning as a gate insulator, a gate potential during operation of the transistor can be reduced while the physical thickness of the gate insulator is maintained.

Silicon oxide or silicon oxynitride, for example, can be used as appropriate for the insulator 224 that is in contact with the oxide 230. When the insulator 224 containing oxygen is provided in contact with the oxide 230, oxygen vacancies in the oxide 230 can be reduced, leading to an improvement in the reliability of the transistor 200. The insulator 224 is preferably processed into an island shape so as to overlap with the oxide 230a. In that case, the insulator 275 is in contact with a side surface of the insulator 224 and a top surface of the insulator 222. With such a structure, the volume of the insulator 224 can be reduced greatly and the insulator 224 and the insulator 280 can be isolated from each other by the insulator 275. Thus, oxygen contained in the insulator 280 can be inhibited from being diffused into the insulator 224 and oxygen in the insulator 224 can be inhibited from being in excess.

Note that the insulator 222 and the insulator 224 may each have a stacked-layer structure of two or more layers. In that case, without limitation to a stacked-layer structure formed of the same material, a stacked-layer structure formed of different materials may be employed. Note that FIG. 14B and the like illustrate the structure in which the insulator 224 is formed into an island shape so as to overlap with the oxide 230a; however, the present invention is not limited to thereto. In the case where the amount of oxygen contained in the insulator 224 can be adjusted appropriately, a structure in which the insulator 224 is not pattered, like the insulator 222, may be employed.

In a manufacturing process of the transistor 200, heat treatment is preferably performed with a surface of the oxide 230 exposed. The heat treatment is performed at higher than or equal to 100° C. and lower than or equal to 600° C., preferably higher than or equal to 350° C. and lower than or equal to 550° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. This can supply oxygen to the oxide 230 to reduce oxygen vacancies (V_{O}). The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas or inert gas atmosphere.

Note that oxygen adding treatment performed on the oxide 230 can promote a reaction in which oxygen vacancies in the oxide 230 are repaired with supplied oxygen, i.e., a reaction of “V_{O}+O→null”. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of V_{O}H.

It is preferable that the conductor 242a and the conductor 242b be provided in contact with the top surface of the oxide 230b. Each of the conductor 242a and the conductor 242b functions as a source electrode or a drain electrode of the transistor 200.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are conductive materials that are not easily oxidized or materials that maintain the conductivity even when absorbing oxygen.

Here, a film with large compressive stress is preferably used for the conductor 242; for example, tantalum nitride deposited by a sputtering method is preferably used. When the crystal structures of the region 230ba and the region 230bb are distorted by the stress of the conductor 242, oxygen vacancies (V_{O}) are easily formed in these regions. Thus, the amounts of V_{O}H formed in the region 230ba and the region 230bb are increased, whereby the carrier concentrations in the region 230ba and the region 230bb are increased, making the region 230ba and the region 230bb n-type regions.

Note that hydrogen contained in the oxide 230b or the like is diffused into the conductor 242a or the conductor 242b in some cases. In particular, when a nitride containing tantalum is used for the conductor 242a and the conductor 242b, hydrogen contained in the oxide 230b or the like is likely to be diffused into the conductor 242a or the conductor 242b, and the diffused hydrogen is bonded to nitrogen contained in the conductor 242a or the conductor 242b in some cases. That is, hydrogen contained in the oxide 230b or the like is sometimes absorbed by the conductor 242a or the conductor 242b in some cases.

No curved surface is preferably formed between a side surface of the conductor 242 and a top surface of the conductor 242. When no curved surface is formed in the conductor 242, the conductor 242 can have a large cross-sectional area in the channel width direction as illustrated in FIG. 14D. Accordingly, the conductivity of the conductor 242 is increased, so that the on-state current of the transistor 200 can be increased.

The insulator 271a is provided in contact with the top surface of the conductor 242a, and the insulator 271b is provided in contact with a top surface of the conductor 242b. The insulator 271 preferably has a function of capturing impurities such as hydrogen. In that case, for the insulator 271, a metal oxide including an amorphous structure, for example, an insulator such as aluminum oxide or magnesium oxide may be used. It is particularly preferable to use aluminum oxide including an amorphous structure or aluminum oxide with an amorphous structure for the insulator 271 because hydrogen can be captured or fixed more effectively in some cases. Accordingly, the transistor 200 and a semiconductor device which have favorable characteristics and high reliability can be manufactured.

The insulator 271 preferably functions as a barrier insulating film against oxygen. Thus, the insulator 271 preferably has a function of inhibiting oxygen diffusion. For example, the insulator 271 preferably has a function of inhibiting diffusion of oxygen more than the insulator 280. In this case, a nitride containing silicon such as silicon nitride may be used for the insulator 271, for example.

The insulator 275 is provided in contact with the top surface of the insulator 222, the side surface of the insulator 224, a side surface of the oxide 230a, the side surface of the oxide 230b, the side surface of the conductor 242, and a side surface and a top surface of the insulator 271. The insulator 275 includes the opening formed in a region where the insulator 250 and the conductor 260 are provided.

The insulator 275 preferably functions as a barrier insulating film that inhibits passage of oxygen. In addition, the insulator 275 preferably functions as a barrier insulating film that inhibits the diffusion of impurities such as water and hydrogen and preferably has a function of capturing impurities such as hydrogen. As the insulator 275, a single layer or a stacked layer of an insulator such as aluminum oxide or silicon nitride is used. For example, an aluminum oxide film with an amorphous structure is provided and a silicon nitride film is provided thereover. Such a stacked-layer structure is preferable because of its high barrier property against hydrogen and oxygen compared with a single layer of an aluminum oxide film or a single layer of a silicon nitride film.

When the above insulator 271 and the insulator 275 are provided, the conductor 242 can be surrounded by the insulators having a barrier property against oxygen. That is, oxygen contained in the insulator 224, the insulator 280, and the insulator 250a can be prevented from being diffused into the conductor 242. As a result, the conductor 242 can be inhibited from being directly oxidized by oxygen contained in the insulator 224, the insulator 280, and the insulator 250a, so that an increase in resistivity and a reduction in on-state current can be inhibited.

The insulator 214, the insulator 271, and the insulator 275, which have a function of capturing impurities such as hydrogen, are provided in a region sandwiched between the insulator 212 and the insulator 275, whereby impurities such as hydrogen contained in the insulator 224, the insulator 216, or the like can be captured and the amount of hydrogen in the region can be kept constant. In that case, at least part of the insulator 275 preferably contains aluminum oxide with an amorphous structure.

The insulator 250 includes the insulator 250a and the insulator 250b over the insulator 250a and functions as a gate insulating film. The insulator 250a is preferably placed in contact with the top surface of the oxide 230b and a side surface of the insulator 280. The thickness of the insulator 250 is preferably greater than or equal to 1 nm and less than or equal to 20 nm.

For the insulator 250a, silicon oxide, silicon oxynitride, silicon nitride oxide, silicon nitride, silicon oxide to which fluorine is added, porous silicon oxide, or the like can be used. In particular, silicon oxide and silicon oxynitride are preferable because they are thermally stable. The carbon content in the insulator 250a is preferably as low as possible.

However, one embodiment of the present invention is not limited thereto and the insulator 250a may contain carbon. For example, the carbon concentration in the insulator 250a by SIMS analysis is preferably higher than or equal to 1×10¹⁸ atoms/cm³ and lower than or equal to 5×10²⁰ atoms/cm³, further preferably higher than or equal to 5×10¹⁸ atoms/cm³ and lower than or equal to 1×10²⁰ atoms/cm³. The carbon concentration in the insulator 250a can be measured by SIMS analysis or the like.

As in the insulator 224, for the insulator 250a, the concentration of impurities such as water and hydrogen in the insulator 250a is preferably reduced.

It is preferable that the insulator 250a be formed using an insulator from which oxygen is easily diffused by heating and the insulator 250b be formed using an insulator that has a function of inhibiting the diffusion of oxygen. With such a structure, when oxygen contained in the insulator 250a is diffused, the oxygen can be inhibited from being diffused into the conductor 260. That is, a reduction in the amount of oxygen supplied to the oxide 230 can be inhibited. In addition, oxidation of the conductor 260 due to oxygen contained in the insulator 250a can be inhibited. For example, the insulator 250b can be provided using a material similar to that for the insulator 222.

In the case where silicon oxide, silicon oxynitride, or the like is used for the insulator 250a, the insulator 250b may be formed using an insulating material that is a high-k material having a high relative permittivity. The gate insulator having a stacked-layer structure of the insulator 250a and the insulator 250b can be thermally stable and can have a high relative permittivity. Thus, a gate potential that is applied during operation of the transistor can be reduced while the physical thickness of the gate insulator is maintained. In addition, the equivalent oxide thickness (EOT) of the insulator functioning as the gate insulator can be reduced.

Specifically, for the insulator 250b, a metal oxide containing one kind or two or more kinds selected from hafnium, aluminum, gallium, yttrium, zirconium, tungsten, titanium, tantalum, nickel, germanium, magnesium, and the like or a metal oxide that can be used for the oxide 230 can be used. In particular, an insulator containing an oxide of one or both of aluminum and hafnium is preferably used. For the insulator, aluminum oxide, hafnium oxide, an oxide containing aluminum and hafnium (hafnium aluminate), or the like is preferably used. As the insulator 250b, a stacked film in which a hafnium oxide film and a silicon nitride film over the hafnium oxide film are provided may be used.

Note that although the insulator 250 has a stacked-layer structure of two layers in FIG. 14B and FIG. 14C, the present invention is not limited thereto. The insulator 250 may be a single layer or have a stacked-layer structure of three or more layers. For example, as illustrated in FIG. 15B, an insulator 250c may be provided between the insulator 250b and the conductor 260a. As the insulator 250c, an insulator that can be used as the insulator 283 described above is used. As the insulator 250c, an insulating film having a barrier property against hydrogen is preferably used. This can prevent diffusion of impurities such as hydrogen contained in the conductor 260 into the insulator 250b, the insulator 250a, and the oxide 230b. For example, silicon nitride deposited by a PEALD method may be used as the insulator 250c.

Furthermore, a metal oxide may be provided between the insulator 250 and the conductor 260. The metal oxide preferably inhibits diffusion of oxygen from the insulator 250 into the conductor 260. Providing the metal oxide that inhibits diffusion of oxygen inhibits diffusion of oxygen from the insulator 250 into the conductor 260. That is, a reduction in the amount of oxygen supplied to the oxide 230 can be inhibited. Moreover, oxidation of the conductor 260 due to oxygen in the insulator 250 can be inhibited.

Note that the metal oxide may have a function of part of the first gate electrode. For example, a metal oxide that can be used as the oxide 230 can be used as the metal oxide. In that case, when the conductor 260a is deposited by a sputtering method, the metal oxide can have a reduced electric resistance value to be a conductor. Such a conductor can be referred to as an OC (Oxide Conductor) electrode.

With the metal oxide, the on-state current of the transistor 200 can be increased without a reduction in the influence of the electric field from the conductor 260.

The conductor 260 is provided over the insulator 250b and functions as the first gate electrode of the transistor 200. The conductor 260 preferably includes the conductor 260a and the conductor 260b placed over the conductor 260a. For example, the conductor 260a is preferably placed to cover a bottom surface and a side surface of the conductor 260b. Moreover, as illustrated in FIG. 14B and FIG. 14C, a top surface of the conductor 260 is substantially level with a top surface of the insulator 250. Although the conductor 260 has a two-layer structure of the conductor 260a and the conductor 260b in FIG. 14B and FIG. 14C, the conductor 260 may have a single-layer structure or a stacked-layer structure of three or more layers.

For the conductor 260a, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen contained in the insulator 250. As a conductive material having a function of inhibiting diffusion of oxygen, for example, titanium, titanium nitride, tantalum, tantalum nitride, ruthenium, or ruthenium oxide is preferably used.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening formed in the insulator 280 and the like. The formation of the conductor 260 in this manner allows the conductor 260 to be placed certainly in a region between the conductor 242a and the conductor 242b without alignment. In the case where an upper portion of the opening is larger than a lower portion of the opening as illustrated in FIG. 15A and the like, the conductor 260 similarly has an upper portion larger than a lower portion.

As illustrated in FIG. 14C, in the channel width direction of the transistor 200, with reference to a bottom surface of the insulator 222, the level of the bottom surface of the conductor 260 in a region where the conductor 260 and the oxide 230b do not overlap is preferably lower than the level of a bottom surface of the oxide 230b. When the conductor 260 functioning as the gate electrode covers a side surface and a top surface of the channel formation region of the oxide 230b with the insulator 250 and the like therebetween, the electric field of the conductor 260 is likely to act on the entire channel formation region of the oxide 230b. Thus, the on-state current of the transistor 200 can be increased and the frequency characteristics of the transistor 200 can be improved. When the bottom surface of the insulator 222 is a reference, the difference between the level of the bottom surface of the conductor 260 in a region where the conductor 260 do not overlap the oxide 230a and the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275, and the opening is formed in a region where the insulator 250 and the conductor 260 are to be provided. In addition, a top surface of the insulator 280 may be planarized. In this case, it is preferable that the top surface of the insulator 280 be substantially level with the top surface of the insulator 250 and the top surface of the conductor 260.

The insulator 280 functioning as an interlayer insulating film preferably has a low permittivity. When a material with a low permittivity is used for an interlayer insulating film, parasitic capacitance generated between wirings can be reduced. The insulator 280 is preferably provided using a material similar to that for the insulator 216, for example. In particular, silicon oxide and silicon oxynitride, which have thermal stability, are preferable. Materials such as silicon oxide, silicon oxynitride, and porous silicon oxide are particularly preferable because a region containing oxygen released by heating can be easily formed.

Like the insulator 224, the insulator 280 sometimes contains excess oxygen. The insulator 280 preferably has a reduced concentration of impurities such as water and hydrogen. Oxide containing silicon such as silicon oxide, silicon oxynitride, or the like is used as appropriate for the insulator 280, for example. When the insulator 280 is provided in contact with the insulator 250a, oxygen can be supplied to the oxide 230 through the insulator 250a. The oxygen reduces oxygen vacancies in the oxide 230, whereby the reliability of the transistor 200 can be improved.

The insulator 282 is provided in contact with the top surface of the insulator 280, the top surface of the insulator 250, and the top surface of the conductor 260. For the insulator 282, for example, an insulator such as aluminum oxide can be used. When aluminum oxide is deposited as the insulator 282 by a sputtering method, the insulator 280 can contain excess oxygen. The insulator 282 preferably functions as a barrier insulating film that inhibits impurities such as water and hydrogen from being diffused into the insulator 280 from above and preferably has a function of capturing impurities such as hydrogen. The insulator 282 preferably functions as a barrier insulating film that inhibits passage of oxygen. The insulator 282, which has a function of capturing impurities such as hydrogen, is provided in contact with the insulator 280 in a region sandwiched between the insulator 212 and the insulator 283, whereby impurities such as hydrogen contained in the insulator 280 and the like can be captured and the amount of hydrogen in the region can be kept constant. It is particularly preferable to use aluminum oxide including an amorphous structure or aluminum oxide with an amorphous structure for the insulator 282 because hydrogen can be captured or fixed more effectively in some cases. Accordingly, the transistor 200 and a semiconductor device which have favorable characteristics and high reliability can be manufactured.

The insulator 283 functions as a barrier insulating film that inhibits impurities such as water and hydrogen from being diffused into the insulator 280 from above. The insulator 283 is placed over the insulator 282. The insulator 283 is preferably formed using a nitride containing silicon such as silicon nitride or silicon nitride oxide. For example, silicon nitride deposited by a sputtering method is used for the insulator 283. When the insulator 283 is deposited by a sputtering method, a high-density silicon nitride film where a void or the like is unlikely to be formed can be formed. To obtain the insulator 283, silicon nitride deposited by an ALD method may be stacked over silicon nitride deposited by a sputtering method. Such a structure is preferable because, even when a defect, e.g., a void, is generated in the silicon nitride deposited by a sputtering method, the silicon nitride deposited by an ALD method achieving good coverage can fill the void and a sealing property can be improved.

The insulator 285 is provided over the insulator 283. The insulator 285 is preferably provided using a material similar to that for the insulator 280, for example. In particular, silicon oxide and silicon oxynitride, which have thermal stability, are preferable. Note that although FIG. 14B and FIG. 14C illustrate a structure in which the insulator 285 is provided, the present invention is not limited thereto. A structure may be employed in which the insulator 285 is not provided and the conductor 246 is provided in contact with the insulator 283.

For the conductor 240a and the conductor 240b, a conductive material containing tungsten, copper, or aluminum as its main component is preferably used. The conductor 240a and the conductor 240b may each have a stacked-layer structure.

In the case where the conductor 240 has a stacked-layer structure, a conductive material having a function of inhibiting passage of impurities such as water and hydrogen is preferably used for the first conductor in contact with the insulator 241. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen contained in a layer above the insulator 283 can be inhibited from entering the oxide 230 through the conductor 240a and the conductor 240b.

As the insulator 241a and the insulator 241b, a barrier insulating film that can be used as the insulator 275 or the like is used. As the insulator 241a and the insulator 241b, an insulator such as silicon nitride, aluminum oxide, or silicon nitride oxide is used. Since the insulator 241a and the insulator 241b are provided in contact with the insulator 283, the insulator 282, and the insulator 271, impurities such as water and hydrogen contained in the insulator 280 or the like can be inhibited from entering the oxide 230 through the conductor 240a and the conductor 240b. In particular, silicon nitride is suitable because of having a high barrier property against hydrogen. Furthermore, oxygen contained in the insulator 280 can be prevented from being absorbed by the conductor 240a and the conductor 240b.

In the case where the insulator 241a and the insulator 241b each have a stacked-layer structure as illustrated in FIG. 14A, the first insulator that is in contact with an inner wall of the opening provided in the insulator 280 and the like and the second insulator inside the first insulator are preferably a barrier insulating film against oxygen and a barrier insulating film against hydrogen.

For example, aluminum oxide deposited by an ALD method is used as the first insulator and silicon nitride deposited by a PEALD method is used as the second insulator. With this structure, oxidation of the conductor 240 can be inhibited, and hydrogen can be prevented from entering the conductor 240.

The conductor 246 (the conductor 246a and the conductor 246b) functioning as a wiring may be placed in contact with the top surface of the conductor 240a and the top surface of the conductor 240b. The conductor 246 is preferably formed using a conductive material containing tungsten, copper, or aluminum as its main component. Furthermore, the conductor may have a stacked-layer structure and may be a stack of titanium or titanium nitride and the conductive material, for example. Note that the conductor may be formed to be embedded in an opening provided in an insulator.

### <Constituent Materials of Semiconductor Device>

Constituent materials that can be used for the semiconductor device are described below.

### <<Substrate>>

As a substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (an yttria-stabilized zirconia substrate or the like), and a resin substrate. Examples of the semiconductor substrate include a semiconductor substrate using silicon, germanium, or the like as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### <<Insulator>>

Examples of an insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage during operation of the transistor can be lowered while the physical thickness of the gate insulator is maintained. In contrast, when a material with a low relative permittivity is used for the insulator functioning as an interlayer insulating film, parasitic capacitance generated between wirings can be reduced. Thus, a material is preferably selected depending on the function of an insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor using a metal oxide is surrounded by an insulator having a function of inhibiting passage of oxygen and impurities such as hydrogen, the electrical characteristics of the transistor can be stable. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, for the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide, or a metal nitride such as aluminum nitride, silicon nitride oxide, or silicon nitride can be used.

The insulator functioning as the gate insulator is preferably an insulator including a region containing oxygen released by heating. For example, when a structure is employed in which silicon oxide or silicon oxynitride including a region containing oxygen released by heating is in contact with the oxide 230, oxygen vacancies included in the oxide 230 can be filled.

### <<Conductor>>

For a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. A semiconductor having high electrical conductivity, typified by polycrystalline silicon containing an impurity element such as phosphorus, or silicide such as nickel silicide may be used.

A stack including a plurality of conductive layers formed of the above materials may be used. For example, a stacked-layer structure combining a material containing the above metal element and a conductive material containing oxygen may be employed. A stacked-layer structure combining a material containing the above metal element and a conductive material containing nitrogen may be employed. A stacked-layer structure combining a material containing the above metal element, a conductive material containing oxygen, and a conductive material containing nitrogen may be employed.

Note that when an oxide is used for the channel formation region of the transistor, a stacked-layer structure combining a material containing the above metal element and a conductive material containing oxygen is preferably used for the conductor functioning as the gate electrode. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where the channel is formed. Alternatively, a conductive material containing the above metal element and nitrogen may be used. For example, a conductive material containing nitrogen, such as titanium nitride or tantalum nitride, may be used. Alternatively, indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Furthermore, indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

<<Metal oxide>>

The oxide 230 is preferably formed using a metal oxide functioning as a semiconductor (an oxide semiconductor). A metal oxide that can be used as the oxide 230 of the present invention is described below.

The metal oxide preferably contains at least indium or zinc. In particular, indium and zinc are preferably contained. In addition, aluminum, gallium, yttrium, tin, or the like is preferably contained. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, or tin. Examples of other elements that can be used as the elementMinclude boron, titanium, iron, nickel, germanium, zirconium, molybdenum, lanthanum, cerium, neodymium, hafnium, tantalum, tungsten, magnesium, and cobalt. Note that two or more of the above elements may be used in combination as the element M.

### <Method for Manufacturing Semiconductor Device>

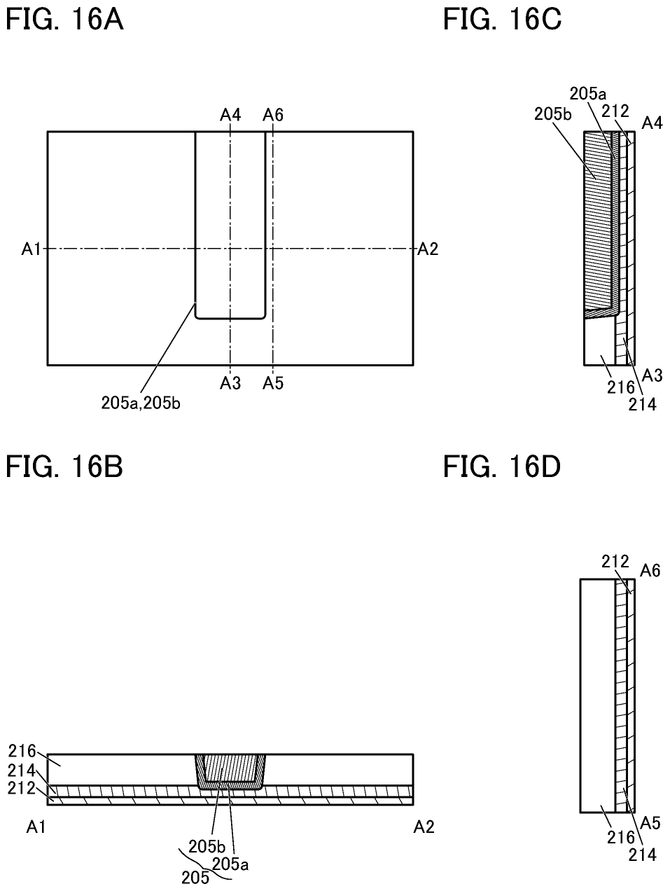

Next, a method for manufacturing the semiconductor device that is one embodiment of the present invention and is illustrated in FIG. 14A to FIG. 14D is described with reference to FIG. 16A to FIG. 25A, FIG. 16B to FIG. 25B, FIG. 16C to FIG. 25C, and FIG. 16D to FIG. 25D.

FIG. 16A to FIG. 25A illustrate top views. FIG. 16B to FIG. 25B are cross-sectional views corresponding to a portion indicated by a dashed-dotted line A1-A2 in FIG. 16A to FIG. 25A, and are also cross-sectional views of the transistor 200 in the channel length direction. FIG. 16C to FIG. 25C are cross-sectional views corresponding to a portion indicated by a dashed-dotted line A3-A4 in FIG. 16A to FIG. 25A, and are also cross-sectional views in the channel width direction of the transistor 200. FIG. 16D to FIG. 25D are cross-sectional views of portions indicated by dashed-dotted line A5-A6 in FIG. 16A to FIG. 25A. Note that for clarity of the drawings, some components are omitted in the top views of FIG. 16A to FIG. 25A.

Hereinafter, an insulating material for forming an insulator, a conductive material for forming a conductor, and a semiconductor material for forming a semiconductor can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which a voltage is applied while being changed in a pulsed manner. An RF sputtering method is mainly used in the case where an insulating film is deposited, and a DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma enhanced CVD (PECVD) method using plasma (sometimes referred to as a plasma enhanced chemical vapor deposition method), a thermal CVD (TCVD) method using heat, a photo CVD method using light, and the like. Moreover, the CVD method can be classified into a metal CVD (MCVD) method and a metal organic CVD (MOCVD) method (sometimes referred to as a metal organic chemical vapor deposition method) depending on a source gas to be used.

A high-quality film can be obtained at a relatively low temperature by a plasma enhanced CVD method. Furthermore, a thermal CVD method is a deposition method that does not use plasma and thus enables less plasma damage to an object to be processed. For example, a wiring, an electrode, an element (a transistor, a capacitor, or the like), or the like included in a semiconductor device might be charged up by receiving electric charge from plasma. In that case, accumulated electric charge might break the wiring, the electrode, the element, or the like included in the semiconductor device. In contrast, such plasma damage does not occur in the case of a thermal CVD method, which does not use plasma, and thus the yield of the semiconductor device can be increased. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

An ALD method, which enables one atomic layer to be deposited at a time using self-regulating characteristics of atoms, has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because deposition at a lower temperature is possible. Note that a precursor used in an ALD method sometimes contains impurities such as carbon. Thus, in some cases, a film provided by an ALD method contains impurities such as carbon in a larger amount than a film provided by another deposition method. Note that impurities can be quantified by X-ray photoelectron spectroscopy (XPS).

Unlike a deposition method in which particles ejected from a target or the like are deposited, a CVD method and an ALD method are deposition methods in which a film is formed by reaction at a surface of an object to be processed. Thus, a CVD method and an ALD method are deposition methods that enable favorable step coverage almost regardless of the shape of an object to be processed. In particular, an ALD method has excellent step coverage and excellent thickness uniformity and thus is suitable for covering a surface of an opening portion with a high aspect ratio, for example. Note that an ALD method has a relatively low deposition rate, and thus is preferably used in combination with another deposition method with a high deposition rate, such as a CVD method, in some cases.

A CVD method and an ALD method enable control of the composition of a film to be obtained with the flow rate ratio of the source gases. For example, by a CVD method and an ALD method, a film with a certain composition can be deposited depending on the flow rate ratio of the source gases. Moreover, for example, by a CVD method and an ALD method, a film whose composition is continuously changed can be deposited by changing the flow rate ratio of the source gases during the deposition. In the case where the film is deposited while the flow rate ratio of the source gases is changed, as compared to the case where the film is deposited using a plurality of deposition chambers, the time taken for the deposition can be shortened because the time taken for transfer and pressure adjustment is omitted. Thus, the productivity of the semiconductor device can be increased in some cases.

First, a substrate (not illustrated) is prepared, and the insulator 212 is deposited over the substrate (see FIG. 16A to FIG. 16D). The insulator 212 is preferably deposited by a sputtering method. Since hydrogen is not used as a deposition gas in the sputtering method, the hydrogen concentration in the insulator 212 can be reduced. Without limitation to a sputtering method, the insulator 212 may be deposited by a CVD method, an MBE method, a PLD method, an ALD method, or the like as appropriate.

In this embodiment, for the insulator 212, silicon nitride is deposited by a pulsed DC sputtering method using a silicon target in an atmosphere containing a nitrogen gas. The use of the pulsed DC sputtering method can inhibit generation of particles due to arcing on the target surface, achieving more uniform film thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator through which impurities such as water and hydrogen are less likely to pass, such as silicon nitride, can inhibit diffusion of impurities such as water and hydrogen contained in a layer below the insulator 212. When an insulator through which copper is less likely to pass, such as silicon nitride, is used for the insulator 212, even in the case where a metal that is likely to be diffused, such as copper, is used for a conductor in a layer (not illustrated) below the insulator 212, diffusion of the metal into a layer above the insulator 212 through the insulator 212 can be inhibited.

Next, the insulator 214 is deposited over the insulator 212 (see FIG. 16A to FIG. 16D). The insulator 214 is preferably deposited by a sputtering method. Since hydrogen is not used as a deposition gas in the sputtering method, the hydrogen concentration in the insulator 214 can be reduced. Without limitation to a sputtering method, the insulator 214 may be deposited by a CVD method, an MBE method, a PLD method, an ALD method, or the like as appropriate.

In this embodiment, for the insulator 214, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. Here, RF (Radio Frequency) power may be applied to the substrate. For example, a structure may be employed in which RF power is not applied when a lower layer of the insulator 214 is deposited, and RF power is applied when an upper layer of the insulator 214 is deposited. The amount of oxygen implanted to a layer below the insulator 214 can be controlled depending on the amount of the RF power applied to the substrate. The RF power is higher than or equal to 0 W/cm² and lower than or equal to 1.86 W/cm². In other words, the implantation amount of oxygen can be changed to be appropriate for the characteristics of the transistor, with the RF power used at the time of forming the insulator 214. Accordingly, an appropriate amount of oxygen for improving the reliability of the transistor can be implanted. The RF frequency is preferably 10 MHz or higher. The typical frequency is 13.56 MHz. The higher the RF frequency is, the less damage the substrate gets.

A metal oxide including an amorphous structure, which has an excellent function of capturing and fixing hydrogen, such as aluminum oxide, is preferably used for the insulator 214. In this case, the insulator 214 captures or fixes hydrogen contained in the insulator 216 and the like and prevents the hydrogen from being diffused into the oxide 230. It is particularly preferable to use aluminum oxide including an amorphous structure or aluminum oxide with an amorphous structure for the insulator 214 because hydrogen can be captured or fixed more effectively in some cases. Accordingly, the transistor 200 and a semiconductor device which have favorable characteristics and high reliability can be manufactured.

Next, the insulator 216 is deposited over the insulator 214. The insulator 216 is preferably deposited by a sputtering method. Since hydrogen is not used as a deposition gas in the sputtering method, the hydrogen concentration in the insulator 216 can be reduced. Without limitation to a sputtering method, the insulator 216 may be deposited by a CVD method, an MBE method, a PLD method, an ALD method, or the like as appropriate.

In this embodiment, for the insulator 216, silicon oxide is deposited by a pulsed DC sputtering method using a silicon target in an atmosphere containing an oxygen gas. The use of the pulsed DC sputtering method can achieve more uniform film thickness and improve the sputtering rate and film quality.

The insulator 212, the insulator 214, and the insulator 216 are preferably successively deposited without exposure to the air. For example, a multi-chamber deposition apparatus is used. As a result, the amounts of hydrogen in the deposited insulator 212, insulator 214, and insulator 216 can be reduced, and furthermore, entry of hydrogen in the films in intervals between deposition steps can be inhibited.

Then, an opening reaching the insulator 214 is formed in the insulator 216. Examples of the opening include a groove and a slit. A region where an opening is formed is referred to as an opening portion in some cases. Wet etching can be used for the formation of the opening; however, dry etching is preferably used for microfabrication. As the insulator 214, it is preferable to select an insulator that functions as an etching stopper film used in forming the groove by etching the insulator 216. For example, in the case where silicon oxide or silicon oxynitride is used for the insulator 216 in which the groove is to be formed, silicon nitride, aluminum oxide, or hafnium oxide is preferably used for the insulator 214. Note that a recessed portion overlapping with the opening in the insulator 216 is sometimes formed in the insulator 214.

As a dry etching apparatus, a capacitively coupled plasma (CCP) etching apparatus including parallel plate electrodes can be used. The capacitively coupled plasma etching apparatus including the parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

After the formation of the opening, a conductive film to be the conductor 205a is deposited. The conductive film to be the conductor 205a desirably includes a conductor having a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used. The conductive film to be the conductor 205a can be deposited by a sputtering method, a CVD method, an MBE method, a PLD method, an ALD method, or the like.

In this embodiment, titanium nitride is deposited for the conductive film to be the conductor 205a. When such a metal nitride is provided in contact with a bottom surface and a side surface of the conductor 205b, oxidation of the conductor 205b by the insulator 216 or the like can be inhibited. Furthermore, even when a metal that is likely to be diffused, such as copper, is used for the conductor 205b, the metal can be prevented from being diffused to the outside through the conductor 205a.

Next, a conductive film to be the conductor 205b is deposited. Tantalum, tungsten, titanium, molybdenum, aluminum, copper, a molybdenum-tungsten alloy, or the like can be used for the conductive film to be the conductor 205b. The conductive film can be deposited by a plating method, a sputtering method, a CVD method, an MBE method, a PLD method, an ALD method, or the like. In this embodiment, tungsten is deposited for the conductive film to be the conductor 205b.

Then, CMP treatment is performed to remove parts of the conductive film to be the conductor 205a and the conductive film to be the conductor 205b, so that the insulator 216 is exposed (see FIG. 16A to FIG. 16D). As a result, the conductor 205a and the conductor 205b remain only in the opening portion. In this way, the conductor 205 with a flat top surface can be formed. Note that the insulator 216 is partly removed by the CMP treatment in some cases.

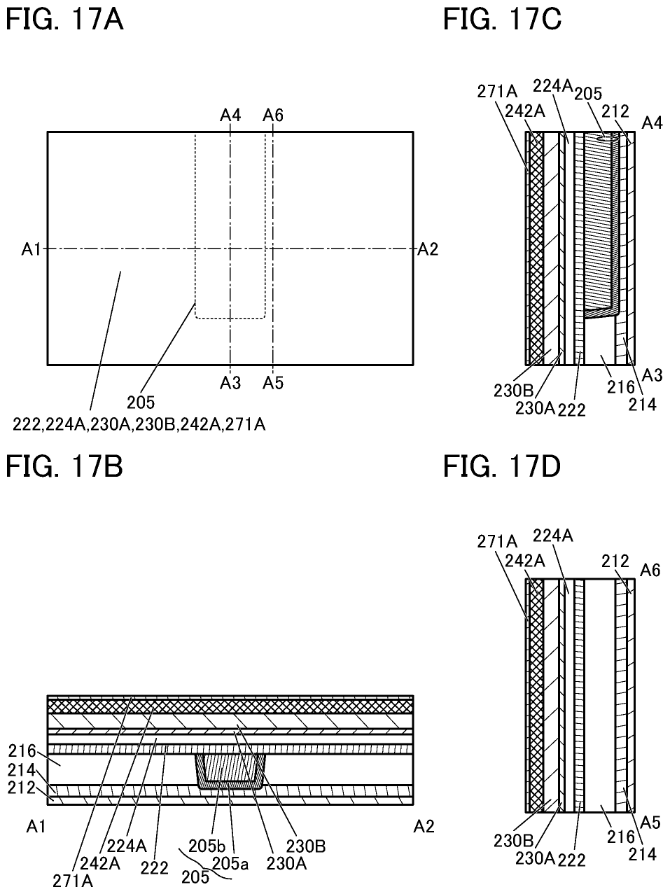

Next, the insulator 222 is deposited over the insulator 216 and the conductor 205 (see FIG. 17A to FIG. 17D). An insulator containing an oxide of one or both of aluminum and hafnium is preferably deposited as the insulator 222. Note that as the insulator containing an oxide of one or both of aluminum and hafnium, aluminum oxide, hafnium oxide, an oxide containing aluminum and hafnium (hafnium aluminate), or the like is preferably used. The insulator containing an oxide of one or both of aluminum and hafnium has a barrier property against oxygen, hydrogen, and water. When the insulator 222 has a barrier property against hydrogen and water, hydrogen and water contained in components provided around the transistor 200 are inhibited from being diffused into the transistor 200 through the insulator 222, and generation of oxygen vacancies in the oxide 230 can be inhibited.

The insulator 222 can be deposited by a sputtering method, a CVD method, an MBE method, a PLD method, an ALD method, or the like. In this embodiment, for the insulator 222, hafnium oxide is deposited by an ALD method.

Sequentially, heat treatment is preferably performed. The heat treatment is performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the insulator 222 and the like as much as possible.

In this embodiment, as the heat treatment, treatment at 400° C. for one hour is performed with a flow rate ratio of a nitrogen gas and an oxygen gas of 4 slm: 1 slm after the deposition of the insulator 222. By the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after the deposition of the insulator 224, for example.

Then, an insulating film 224A is deposited over the insulator 222 (see FIG. 17A to FIG. 17D). The insulating film 224A can be deposited by a sputtering method, a CVD method, an MBE method, a PLD method, an ALD method, or the like. In this embodiment, for the insulating film 224A, silicon oxide is deposited by a sputtering method. Since hydrogen is not used as a deposition gas in the sputtering method, the hydrogen concentration in the insulating film 224A can be reduced. The hydrogen concentration is preferably reduced in such a manner because the insulating film 224A is in contact with the oxide 230a in a later step.

Next, an oxide film 230A and an oxide film 230B are deposited in this order over the insulating film 224A (see FIG. 17A to FIG. 17D). Note that it is preferable to deposit the oxide film 230A and the oxide film 230B successively without exposure to the air. By the deposition without exposure to the air, impurities or moisture from the atmospheric environment can be prevented from being attached onto the oxide film 230A and the oxide film 230B, so that the vicinity of an interface between the oxide film 230A and the oxide film 230B can be kept clean.

The oxide film 230A and the oxide film 230B are preferably deposited by an ALD method as described in the above embodiment. Accordingly, each of the oxide film 230A and the oxide film 230B can be formed as an oxide having a layered crystal structure.

Note that the insulating film 224A, the oxide film 230A, and the oxide film 230B are preferably deposited by an ALD method without exposure to the air. For example, the multi-chamber deposition apparatus described in the above embodiment is used. In this manner, hydrogen can be prevented from entering the insulating film 224A, the oxide film 230A, and the oxide film 230B during each of deposition steps.

Next, heat treatment is preferably performed. The heat treatment is performed in a temperature range where the oxide film 230A and the oxide film 230B do not become polycrystals, i.e., at a temperature higher than or equal to 100° C. and lower than or equal to 1200° C., preferably higher than or equal to 200° C. and lower than or equal to 1000° C., further preferably higher than or equal to 250° C. and lower than or equal to 650° C., still further preferably higher than or equal to 300° C. and lower than or equal to 600° C., still further preferably higher than or equal to 400° C. and lower than or equal to 550° C., still further preferably higher than or equal to 420° C. and lower than or equal to 480° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. In the case where the temperature of the heat treatment is high, the metal oxide may have a polycrystalline structure; thus, the temperature of the heat treatment is set as appropriate within a range where the metal oxide does not have a polycrystalline structure. Note that in one embodiment of the present invention, the metal oxide may have a polycrystalline structure. The heat treatment may be performed in the treatment chamber 4011 illustrated in FIG. 7 in the above embodiment.

The gas used in the above heat treatment is preferably highly purified. For example, the amount of moisture contained in the gas used in the above heat treatment is 1 ppb or less, preferably 0.1 ppb or less, and further preferably 0.05 ppb or less. The heat treatment using a highly purified gas can prevent entry of moisture or the like into the oxide film 230A, the oxide film 230B, and the like as much as possible.

In this embodiment, as the above heat treatment, treatment at 450° C. for one hour is performed with a flow rate ratio of a nitrogen gas to an oxygen gas of 4 slm: 1 slm. By such heat treatment including an oxygen gas, impurities such as carbon, water, and hydrogen in the oxide film 230A and the oxide film 230B can be reduced, for example. Impurities in the film are reduced in the above manner, whereby the crystallinity of the oxide film 230B can be improved and a dense structure can be obtained. Accordingly, the crystal regions in the oxide film 230A and the oxide film 230B can be increased, and in-plane variation in the oxide film 230A and the oxide film 230B can be reduced. Therefore, in-plane variations in electrical characteristics among the transistors 200 can be reduced.

Next, a conductive film 242A is deposited over the oxide film 230B (see FIG. 17A to FIG. 17D). The conductive film 242A can be deposited by a sputtering method, a CVD method, an MBE method, a PLD method, an ALD method, or the like. For example, for the conductive film 242A, tantalum nitride is deposited by a sputtering method. Note that heat treatment may be performed before the deposition of the conductive film 242A. This heat treatment may be performed under reduced pressure, and the conductive film 242A may be successively deposited without exposure to the air. The treatment can remove moisture and hydrogen adsorbed onto the surface of the oxide film 230B and the like, and further can reduce the moisture concentration and the hydrogen concentration in the oxide film 230A, the oxide film 230B, and the oxide film 230B. The heat treatment is preferably performed at a temperature higher than or equal to 100° C. and lower than or equal to 400° C. In this embodiment, the heat treatment is performed at 200° C.

Next, an insulating film 271A is deposited over the conductive film 242A (see FIG. 17A to FIG. 17D). The insulating film 271A can be deposited by a sputtering method, a CVD method, an MBE method, a PLD method, an ALD method, or the like. As the insulating film 271A, an insulating film having a function of inhibiting passage of oxygen is preferably used. For example, for the insulating film 271A, aluminum oxide is deposited by a sputtering method.

Note that the conductive film 242A and the insulating film 271A are preferably deposited by a sputtering method without exposure to the air. For example, a multi-chamber deposition apparatus is used. As a result, the amounts of hydrogen in the deposited conductive film 242A and insulating film 271A can be reduced, and furthermore, entry of hydrogen in the films in intervals between deposition steps can be inhibited. In the case where a hard mask is provided over the insulating film 271A, a film to be the hard mask is preferably successively deposited without exposure to the air.

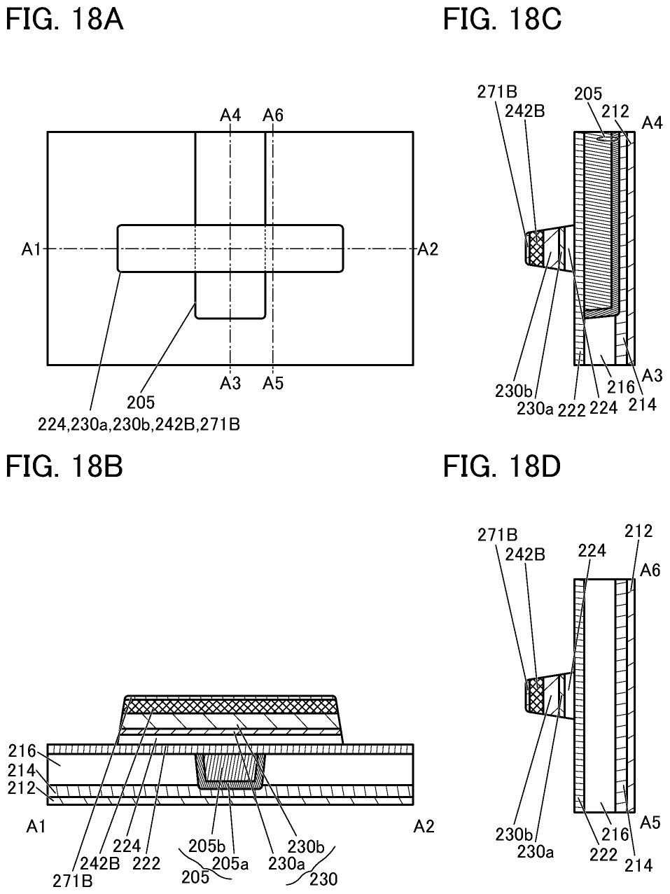

Next, the insulating film 224A, the oxide film 230A, the oxide film 230B, the conductive film 242A, and the insulating film 271A are processed into island shapes by a lithography method to form the insulator 224, the oxide 230a, the oxide 230b, a conductive layer 242B, and an insulating layer 271B (see FIG. 18A to FIG. 18D). Here, the insulator 224, the oxide 230a, the oxide 230b, the conductive layer 242B, and the insulating layer 271B are formed to at least partly overlap the conductor 205. A dry etching method or a wet etching method can be used for the processing. Processing by a dry etching method is suitable for microfabrication. The insulating film 224A, the oxide film 230A, the oxide film 230B, the conductive film 242A, the insulating film 271A, and the insulating layer 271B may be processed under different conditions.

Note that in the lithography method, first, a resist is exposed to light through a mask. Next, a region exposed to light is removed or left using a developing solution, so that a resist mask is formed. Then, etching process through the resist mask is conducted, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. Alternatively, a liquid immersion technique may be employed in which a gap between a substrate and a projection lens is filled with liquid (e.g., water) in light exposure. Alternatively, an electron beam or an ion beam may be used instead of the light. Note that a mask is unnecessary in the case of using an electron beam or an ion beam. Note that the resist mask can be removed by dry etching process such as ashing, wet etching process, wet etching process after dry etching process, or dry etching process after wet etching process.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the conductive film 242A, a resist mask is formed thereover, and then the hard mask material is etched. The etching of the conductive film 242A and the like may be performed after removing the resist mask or with the resist mask remaining. In the latter case, the resist mask sometimes disappears during the etching. The hard mask may be removed by etching after the etching of the conductive film 242A and the like. Meanwhile, the hard mask is not necessarily removed when the hard mask material does not affect later steps or can be utilized in later steps. In this embodiment, the insulating layer 271B is used as a hard mask.

Here, the insulating layer 271B functions as a mask for the conductive layer 242B; thus, as illustrated in FIG. 18B to FIG. 18D, the conductive layer 242B does not have a curved surface between the side surface and the top surface. Thus, end portions at the intersections of the side surfaces and the top surfaces of the conductor 242a and the conductor 242b illustrated in FIG. 14B and FIG. 14D are angular. The cross-sectional area of the conductor 242 is larger in the case where the end portion at the intersection of the side surface and the top surface of the conductor 242 is angular than in the case where the end portion is rounded. Accordingly, the resistance of the conductor 242 is reduced, so that the on-state current of the transistor 200 can be increased.

Furthermore, as illustrated in FIG. 18B to FIG. 18D, cross sections of the insulator 224, the oxide 230a, the oxide 230b, the conductive layer 242B, and the insulating layer 271B may have tapered shapes. In this specification and the like, a tapered shape indicates a shape in which at least part of a side surface of a structure is inclined to a substrate surface. For example, the angle formed between the inclined side surface and the substrate surface (hereinafter, the angle is sometimes referred to as a taper angle) is preferably less than 90°. Each of the insulator 224, the oxide 230a, the oxide 230b, the conductive layer 242B, and the insulating layer 271B may be processed to have a taper angle greater than or equal to 60° and less than 90°. Such a cross section having a tapered shape can improve the coverage with the insulator 275 and the like in the subsequent steps, so that defects such as voids can be reduced.

Not being limited to the above, the insulator 224, the oxide 230a, the oxide 230b, the conductive layer 242B, and the insulating layer 271B may have side surfaces that are substantially perpendicular to the top surface of the insulator 222. With such a structure, a plurality of transistors 200 can be provided with high density in a small area.

A by-product generated in the etching process is sometimes formed in a layered manner on the side surfaces of the insulator 224, the oxide 230a, the oxide 230b, the conductive layer 242B, and the insulating layer 271B. In that case, the layered by-product is formed between the insulator 275 and the insulator 224, the oxide 230a, the oxide 230b, the conductive layer 242B, and the insulating layer 271B. Hence, the layered by-product is preferably removed.

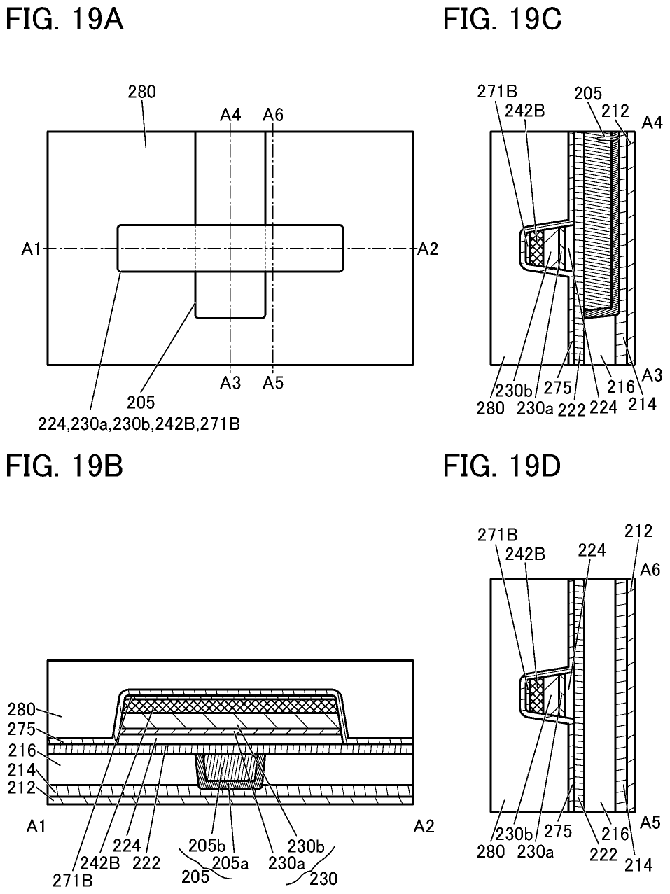

Next, the insulator 275 is deposited to cover the insulator 224, the insulating layer 271B, and the like (see FIG. 19A to FIG. 19D). Here, it is preferable that the insulator 275 be in close contact with the top surface of the insulator 222 and the side surface of the insulator 224. The insulator 275 can be deposited by a sputtering method, a CVD method, an MBE method, a PLD method, an ALD method, or the like. For the insulator 275, an insulating film having a function of inhibiting passage of oxygen is preferably used. For example, for the insulator 275, aluminum oxide is deposited by a sputtering method, and silicon nitride is deposited thereover by a PEALD method. When the insulator 275 has such a stacked-layer structure, the function of inhibiting diffusion of impurities such as water and hydrogen and oxygen is improved in some cases.

In this manner, the insulator 224, the oxide 230a, the oxide 230b, and the conductive layer 242B can be covered with the insulator 275 and the insulating layer 271B, which have a function of inhibiting diffusion of oxygen. This can inhibit direct diffusion of oxygen from the insulator 280 or the like into the insulator 224, the oxide 230a, the oxide 230b, and the conductive layer 242B in a later step.

Next, an insulating film to be the insulator 280 is deposited over the insulator 275. The insulating film can be deposited by a sputtering method, a CVD method, an MBE method, a PLD method, an ALD method, or the like. A silicon oxide film is deposited by a sputtering method as the insulating film, for example. When the insulating film to be the insulator 280 is deposited by a sputtering method in an atmosphere containing oxygen, the insulator 280 containing excess oxygen can be formed. Since hydrogen is not used as a deposition gas in the sputtering method, the concentration of hydrogen in the insulator 280 can be reduced. Note that heat treatment may be performed before the insulating film is deposited. The heat treatment may be performed under reduced pressure, and the insulating film may be successively deposited without exposure to the air. The treatment can remove moisture and hydrogen adsorbed onto the surface of the insulator 275 and the like, and further can reduce the moisture concentration and the hydrogen concentration in the oxide 230a, the oxide 230b, and the insulator 224. For the heat treatment, the above heat treatment conditions can be used.

Next, the insulating film to be the insulator 280 is subjected to CMP treatment, so that the insulator 280 with a flat top surface is formed (see FIG. 19A to FIG. 19D). Note that, for example, silicon nitride may be deposited over the insulator 280 by a sputtering method and CMP treatment may be performed on the silicon nitride until the insulator 280 is reached.

Then, part of the insulator 280, part of the insulator 275, part of the insulating layer 271B, and part of the conductive layer 242B are processed to form an opening reaching the oxide 230b.

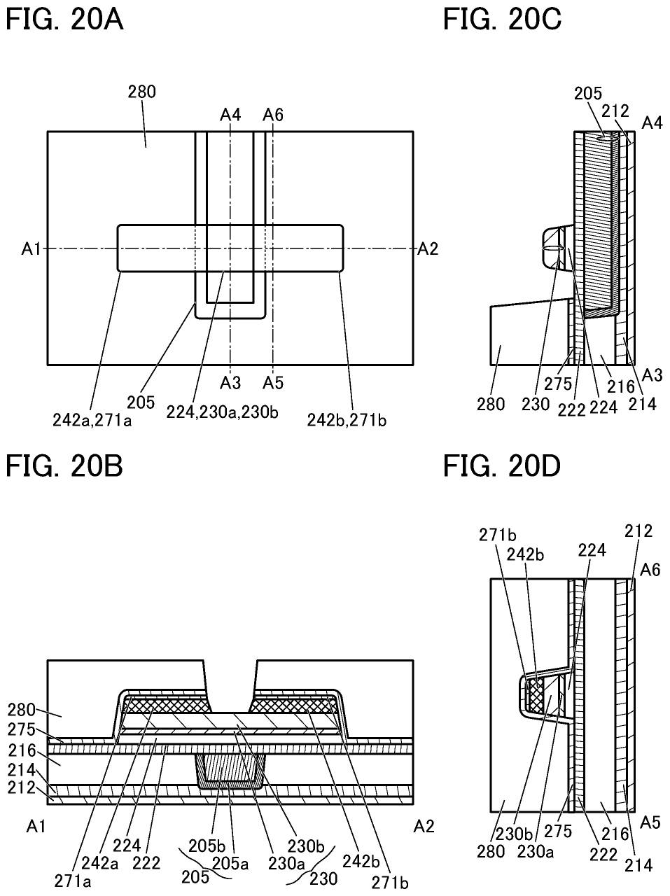

The opening is preferably formed to overlap the conductor 205. The insulator 271a, the insulator 271b, the conductor 242a, and the conductor 242b are formed through the formation of the opening (see FIG. 20A to FIG. 20D).

Here, as illustrated in FIG. 20B and FIG. 20C, the side surfaces of the insulator 280, the insulator 275, the insulator 271, and the conductor 242 may be tapered. The taper angle of the insulator 280 is larger than the taper angle of the conductor 242 in some cases. Although not illustrated in FIG. 20A to FIG. 20C, an upper portion of the oxide 230b is removed in some cases when the opening is formed.

The part of the insulator 280, the part of the insulator 275, the part of the insulating layer 271B, and the part of the conductive layer 242B can be processed by a dry etching method or a wet etching method. Processing by a dry etching method is suitable for microfabrication. The processing may be performed under different conditions. For example, the part of the insulator 280 may be processed by a dry etching method, the part of the insulator 275 and the part of the insulating layer 271B may be processed by a wet etching method, and the part of the conductive layer 242B may be processed by a dry etching method.

Here, in some cases, impurities are attached to the side surface of the oxide 230a and the top surface and the side surface of the oxide 230b, the side surface of the conductor 242, and the side surface of the insulator 280 and diffused therein. A step of removing the impurities may be performed. A damaged region is formed on a surface of the oxide 230b by the dry etching in some cases. Such a damaged region may be removed. The impurities come from components contained in the insulator 280, the insulator 275, part of the insulating layer 271B, and the conductive layer 242B; components contained in a member of an apparatus used to form the opening; and components contained in a gas or a liquid used for etching, for instance. Examples of the impurities include hafnium, aluminum, silicon, tantalum, fluorine, and chlorine.

In particular, impurities such as aluminum and silicon block the oxide 230b from becoming a CAAC-OS. It is thus preferable to reduce or remove impurity elements such as aluminum and silicon, which block the oxide from becoming a CAAC-OS. For example, the concentration of aluminum atoms in the oxide 230b and in the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet further preferably lower than 0.3 atomic %.

Note that in a metal oxide, a region that is hindered from becoming a CAAC-OS by impurities such as aluminum and silicon and becomes an amorphous-like oxide semiconductor (a-like OS) is referred to as a non-CAAC region in some cases. In the non-CAAC region, the density of the crystal structure is reduced to increase V_{O}H; thus, the transistor is likely to be normally on. Hence, the non-CAAC region in the oxide 230b is preferably reduced or removed.

In contrast, the oxide 230b preferably has a layered CAAC structure. In particular, the CAAC structure preferably reaches a lower edge portion of a drain in the oxide 230b. Here, in the transistor 200, the conductor 242a or the conductor 242b, and its vicinity function as a drain. In other words, the oxide 230b in the vicinity of the lower edge portion of the conductor 242a (conductor 242b) preferably has a CAAC structure. In this manner, the damaged region of the oxide 230b is removed and the CAAC structure is formed in the edge portion of the drain, which significantly affects the drain withstand voltage, so that variation of the electrical characteristics of the transistor 200 can be further suppressed. The reliability of the transistor 200 can be improved.

In order to remove the impurities and the like attached to the surface of the oxide 230b in the etching step, cleaning treatment is performed. Examples of the cleaning method include wet cleaning (also referred to as wet etching treatment) using a cleaning solution, plasma treatment using plasma, and cleaning by heat treatment, and any of these cleanings may be performed in appropriate combination. The cleaning treatment sometimes makes the groove portion deeper.

As the wet cleaning, cleaning treatment may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Further alternatively, such cleaning methods may be performed in combination as appropriate.

Note that in this specification and the like, in some cases, an aqueous solution in which commercial hydrofluoric acid is diluted with pure water is referred to as diluted hydrofluoric acid, and an aqueous solution in which commercial ammonia water is diluted with pure water is referred to as diluted ammonia water. The concentration, temperature, and the like of the aqueous solution may be adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

A frequency greater than or equal to 200 kHz, preferably greater than or equal to 900 kHz is preferably used for the ultrasonic cleaning. Damage to the oxide 230b and the like can be reduced with this frequency.

The cleaning treatment may be performed a plurality of times, and the cleaning solution may be changed in every cleaning treatment. For example, the first cleaning treatment may use diluted hydrofluoric acid or diluted ammonia water and the second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like.

After the etching or the cleaning treatment, heat treatment may be performed. The heat treatment is performed at a temperature higher than or equal to 100° C. and lower than or equal to 500° C., preferably higher than or equal to 300° C. and lower than or equal to 500° C., further preferably higher than or equal to 350° C. and lower than or equal to 400° C. Note that the heat treatment is performed in an atmosphere of a nitrogen gas, an inert gas, or an oxidizing gas. Alternatively, the heat treatment is performed in an atmosphere in which an oxidizing gas is added to a nitrogen gas or an inert gas at 10 ppm or more, 1% or more, or 10% or more. For example, the heat treatment is preferably performed in a mixed atmosphere of an oxygen gas and a nitrogen gas. Accordingly, oxygen can be supplied to the oxide 230a and the oxide 230b to reduce the amount of oxygen vacancies (V_{O}). This heat treatment can improve the crystallinity of the oxide 230b. The heat treatment may be performed under reduced pressure. Alternatively, the heat treatment may be performed in a nitrogen atmosphere without exposure to the air successively after heat treatment is performed in an oxygen atmosphere. In the case where the heat treatment is performed in a nitrogen atmosphere without exposure to the air successively after heat treatment is performed in an oxygen atmosphere, the heat treatment in an oxygen atmosphere may be performed for a longer time than the heat treatment in a nitrogen atmosphere.

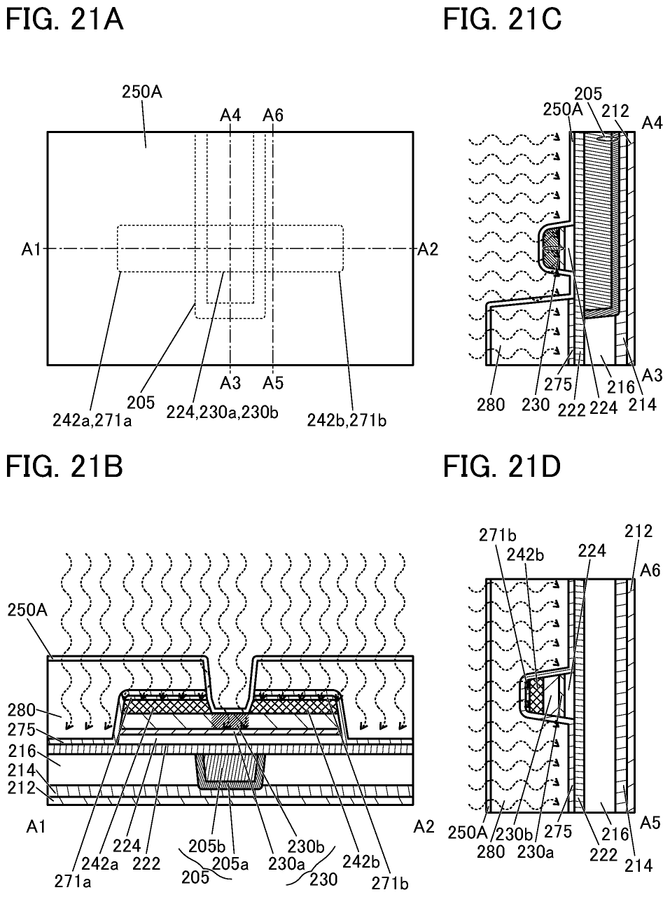

Next, an insulating film 250A is deposited (see FIG. 21A to FIG. 21D). Heat treatment may be performed before the deposition of the insulating film 250A; the heat treatment may be performed under reduced pressure, and the insulating film 250A may be successively deposited without exposure to the air. The heat treatment is preferably performed in an atmosphere containing oxygen. Such treatment can remove moisture and hydrogen adsorbed onto the surface of the oxide 230b and the like, and further can reduce the moisture concentration and the hydrogen concentration in the oxide 230a and the oxide 230b. The heat treatment is preferably performed at a temperature higher than or equal to 100° C. and lower than or equal to 400° C.

The insulating film 250A can be deposited by a sputtering method, a CVD method, a PECVD method, an MBE method, a PLD method, an ALD method, or the like. The insulating film 250A is preferably deposited by a deposition method using a gas in which hydrogen atoms are reduced or removed. This can reduce the hydrogen concentration in the insulating film 250A. The hydrogen concentration in the insulating film 250A is preferably reduced because the insulating film 250A becomes the insulator 250a that is in contact with the oxide 230b in a later step.

The insulating film 250A is preferably deposited by an ALD method. The thickness of the insulator 250, which functions as a gate insulating film of the miniaturized transistor 200, needs to be extremely small (e.g., approximately 5 nm to 30 nm) and have a small variation. In contrast, an ALD method is a deposition method in which a precursor and a reactant (e.g., oxidizer) are alternately introduced, and the film thickness can be adjusted with the number of repetition times of the cycle; thus, accurate control of the film thickness is possible. Thus, the accuracy of the thickness of the gate insulating film required by the miniaturized transistor 200 can be achieved. Furthermore, as illustrated in FIG. 21B and FIG. 21C, the insulating film 250A needs to be deposited on the bottom surface and the side surface of the opening formed in the insulator 280 and the like so as to have good coverage. One atomic layer can be deposited at a time on the bottom surface and the side surface of the opening, whereby the insulating film 250A can be formed in the opening with good coverage.

For example, in the case where the insulating film 250A is deposited by a PECVD method using a deposition gas containing hydrogen, such as SiH₄ (or Si₂H₆), the deposition gas containing hydrogen is decomposed in plasma to generate a large amount of hydrogen radicals. Oxygen in the oxide 230b is extracted by reduction reaction of hydrogen radicals to form V_{O}H, so that the hydrogen concentration in the oxide 230b increases. In contrast, when the insulating film 250A is deposited by an ALD method, the generation of hydrogen radicals can be inhibited at the introduction of a precursor and the introduction of a reactant. Thus, the use of the ALD method for depositing the insulating film 250A can prevent an increase in the hydrogen concentration in the oxide 230b.

In this embodiment, silicon oxide is deposited for the insulating film 250A by a PEALD method.

When the impurities described above are not removed before the deposition of the insulating film 250A, the impurities sometimes remain between the insulator 250a and the oxide 230a, the oxide 230b, the conductor 242, the insulator 280, and the like.

Next, microwave treatment is preferably performed in an atmosphere containing oxygen (see FIG. 21A to FIG. 21D). Here, the microwave treatment refers to, for example, treatment using an apparatus including a power source that generates high-density plasma with the use of a microwave. In this specification and the like, a microwave refers to an electromagnetic wave having a frequency of 300 MHz to 300 GHz.

Here, dotted lines in FIG. 21B to FIG. 21D indicate high-frequency waves such as microwaves or RF, oxygen plasma, oxygen radicals, or the like. For the microwave treatment, a microwave treatment apparatus including a power source for generating high-density plasma using a microwave is preferably used, for example. Here, the frequency of the microwave treatment apparatus is set to greater than or equal to 300 MHz and less than or equal to 300 GHz, preferably greater than or equal to 2.4 GHz and less than or equal to 2.5 GHz, for example, 2.45 GHz. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may include a power source for applying RF to the substrate side. The use of high-density plasma enables high-density oxygen radicals to be generated. Furthermore, application of RF to the substrate side allows oxygen ions generated by the high-density plasma to be efficiently introduced into the oxide 230b.

The microwave treatment is preferably performed under reduced pressure, and the pressure is set to 60 Pa or higher, preferably 133 Pa or higher, further preferably 200 Pa or higher, still further preferably 400 Pa or higher. For example, the pressure is set to higher than or equal to 10 Pa and lower than or equal to 1000 Pa, preferably higher than or equal to 300 Pa and lower than or equal to 700 Pa. The treatment temperature is lower than or equal to 750° C., preferably lower than or equal to 500° C., and is approximately 400° C., for example. Heat treatment may be successively performed without exposure to the air after the oxygen plasma treatment. For example, the heat treatment is performed at higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) is greater than 0% and less than or equal to 100%. The oxygen flow rate ratio (O₂/(O₂+Ar)) is preferably greater than 0% and less than or equal to 50%. The oxygen flow rate ratio (O₂/(O₂+Ar)) is further preferably greater than or equal to 10% and less than or equal to 40%. The oxygen flow rate ratio (O₂/(O₂+Ar)) is still further preferably greater than or equal to 10% and less than or equal to 30%. The carrier concentration in the region 230bc can be reduced by thus performing the microwave treatment in an atmosphere containing oxygen. In addition, the carrier concentrations in the region 230ba and the region 230bb can be prevented from being excessively reduced by preventing an excess amount of oxygen from being introduced into the chamber in the microwave treatment.

As illustrated in FIG. 21B to FIG. 21D, the microwave treatment in an atmosphere containing oxygen can convert an oxygen gas into plasma using a high-frequency wave such as a microwave or RF, and apply the oxygen plasma to a region of the oxide 230b that is between the conductor 242a and the conductor 242b. At this time, the region 230bc can also be irradiated with the high-frequency wave such as a microwave or RF. In other words, the high-frequency wave such as a microwave or RF, the oxygen plasma, or the like can be applied to the region 230bc illustrated in FIG. 15A. The effect of the plasma, the microwave, or the like enables V_{O}H in the region 230bc to be cut, and hydrogen H to be removed from the region 230bc. That is, the reaction “V_{O}H→H+V_{O}” occurs in the region 230bc, so that V_{O}H contained in the region 230bc can be reduced. As a result, oxygen vacancies and V_{O}H in the region 230bc can be reduced to lower the carrier concentration. In addition, oxygen radicals generated by the oxygen plasma or oxygen contained in the insulator 250 can be supplied to oxygen vacancies formed in the region 230bc, thereby further reducing oxygen vacancies and lowering the carrier concentration in the region 230bc.

Meanwhile, the conductor 242a and the conductor 242b are provided over the region 230ba and the region 230bb illustrated in FIG. 15A. Here, the conductor 242 preferably functions as a film blocking the effect caused by the high-frequency wave such as a microwave or RF, the oxygen plasma, or the like in the microwave treatment in an atmosphere containing oxygen. Therefore, the conductor 242 preferably has a function of blocking an electromagnetic wave of greater than or equal to 300 MHz and less than or equal to 300 GHz, for example, greater than or equal to 2.4 GHz and less than or equal to 2.5 GHz.

As illustrated in FIG. 21B to FIG. 21D, the effect of the high-frequency wave such as a microwave or RF, the oxygen plasma, or the like is blocked by the conductor 242a and the conductor 242b, and thus the effect does not reach the region 230ba and the region 230bb. Hence, a reduction in V_{O}H and supply of an excess amount of oxygen due to the microwave treatment do not occur in the region 230ba and the region 230bb, preventing a decrease in carrier concentration.

In the above manner, oxygen vacancies and V_{O}H can be selectively removed from the region 230bc in the oxide semiconductor, whereby the region 230bc can be an i-type or substantially i-type region. Furthermore, supply of an excess amount of oxygen to the region 230ba and the region 230bb functioning as the source region and the drain region can be inhibited and the n-type regions can be maintained. As a result, change in the electrical characteristics of the transistor 200 can be inhibited, and thus variation in the electrical characteristics of the transistors 200 in the substrate plane can be inhibited.

During the microwave treatment, thermal energy might be directly transmitted to the oxide 230b owing to electromagnetic interaction between the microwave and the molecules in the oxide 230b. The oxide 230b might be heated by this thermal energy. Such heat treatment is sometimes referred to as microwave annealing. When microwave treatment is performed in an atmosphere containing oxygen, an effect equivalent to that of oxygen annealing might be obtained. In the case where hydrogen is contained in the oxide 230b, it is probable that the thermal energy is transmitted to the hydrogen in the oxide 230b and the hydrogen activated by the energy is released from the oxide 230b.

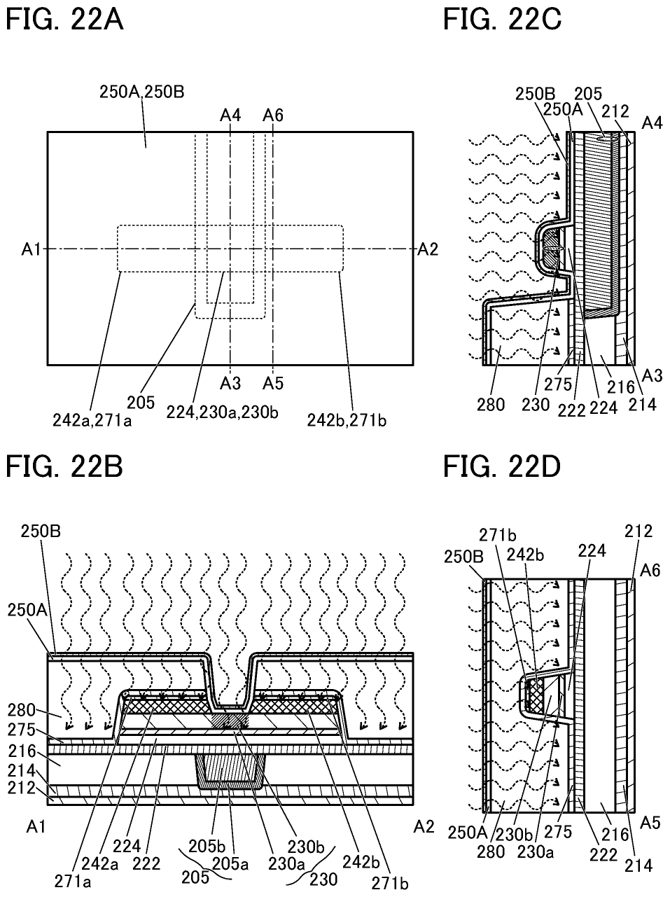

Next, an insulating film 250B is deposited (see FIG. 22A to FIG. 22D). The insulating film 250B can be deposited by a sputtering method, a CVD method, an MBE method, a PLD method, an ALD method, or the like. The insulating film 250B is preferably formed using an insulator having a function of inhibiting diffusion of oxygen. With such a structure, oxygen contained in the insulator 250a can be inhibited from being diffused into the conductor 260. That is, a reduction in the amount of oxygen supplied to the oxide 230 can be inhibited. In addition, oxidation of the conductor 260 due to oxygen contained in the insulator 250a can be inhibited. For example, the insulating film 250A can be formed using the above-described material that can be used for the insulator 250a, and the insulating film 250B can be provided using a material similar to that for the insulator 222.

Specifically, for the insulating film 250B, a metal oxide containing one kind or two or more kinds selected from hafnium, aluminum, gallium, yttrium, zirconium, tungsten, titanium, tantalum, nickel, germanium, magnesium, and the like or a metal oxide that can be used for the oxide 230 can be used. In particular, an insulator containing an oxide of one or both of aluminum and hafnium is preferably used.

In this embodiment, hafnium oxide is deposited for the insulating film 250B by a thermal ALD method.

After the insulating film 250B is deposited, microwave treatment may be performed (see FIG. 22A to FIG. 22D). For the microwave treatment, the conditions for the microwave treatment performed after the deposition of the insulating film 250A may be used. Alternatively, microwave treatment may be performed after the deposition of the insulating film 250B, with no microwave treatment performed after the deposition of the insulating film 250A.

After each of microwave treatment after the deposition of the insulating film 250A and microwave treatment after the deposition of the insulating film 250B, heat treatment may be performed with the reduced pressure being maintained. Such treatment enables hydrogen in the insulating film 250A, the insulating film 250B, the oxide 230b, and the oxide 230a to be removed efficiently. Part of hydrogen is gettered by the conductor 242 (the conductor 242a and the conductor 242b) in some cases. Alternatively, the step of performing microwave treatment and then performing heat treatment with the reduced pressure being maintained may be repeated a plurality of cycles. The repetition of the heat treatment enables hydrogen in the insulating film 250A, the oxide 230b, and the oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are sufficiently heated by the microwave annealing.

Furthermore, the microwave treatment improves the film quality of the insulating film 250A and the insulating film 250B, thereby inhibiting diffusion of hydrogen, water, impurities, and the like. Accordingly, hydrogen, water, impurities, and the like can be inhibited from being diffused into the oxide 230b, the oxide 230a, and the like through the insulator 250 in a later step such as deposition of a conductive film to be the conductor 260 or later treatment such as heat treatment.

Next, a conductive film to be the conductor 260a and a conductive film to be the conductor 260b are deposited in this order. The conductive film to be the conductor 260a and the conductive film to be the conductor 260b can be deposited by a sputtering method, a CVD method, an MBE method, a PLD method, an ALD method, or the like. In this embodiment, the conductive film to be the conductor 260a is deposited by an ALD method, and the conductive film to be the conductor 260b is deposited by a CVD method.

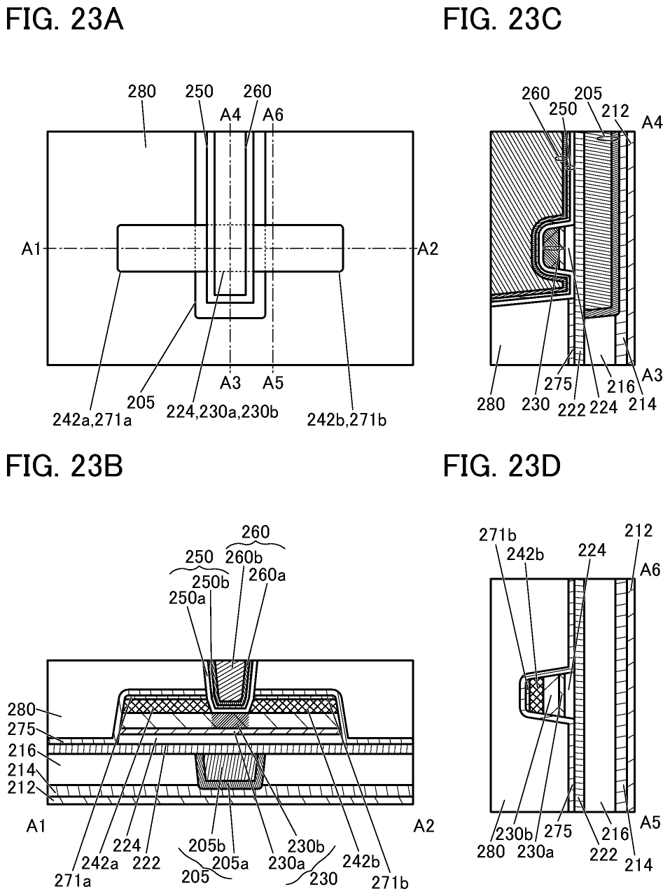

Then, the insulating film 250A, the insulating film 250B, the conductive film to be the conductor 260a, and the conductive film to be the conductor 260b are polished by CMP treatment until the insulator 280 is exposed, whereby the insulator 250a, the insulator 250b, the conductor 260a, and the conductor 260b are formed (see FIG. 23A to FIG. 23D). Accordingly, the insulator 250 is placed to cover the inner wall (the sidewall and the bottom surface) of the opening reaching the oxide 230b and the groove portion of the oxide 230b. The conductor 260 is placed to fill the opening and the groove portion with the insulator 250 therebetween.

Then, heat treatment may be performed under conditions similar to those for the above heat treatment. In this embodiment, treatment is performed at 400° C. in a nitrogen atmosphere for one hour. The heat treatment can reduce the moisture concentration and the hydrogen concentration in the insulator 250 and the insulator 280. After the heat treatment, the insulator 282 may be successively deposited without exposure to the air.

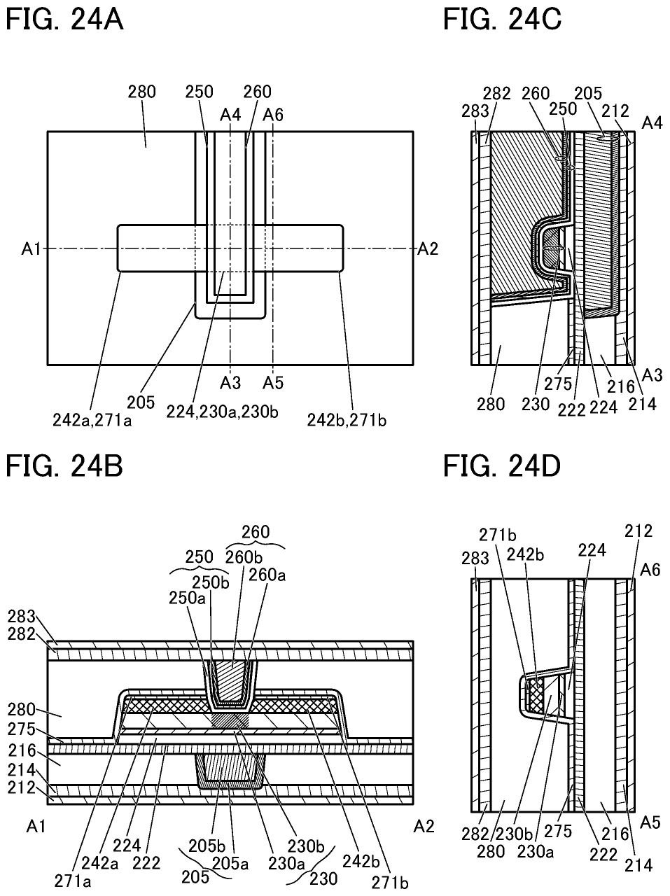

Next, the insulator 282 is formed over the insulator 250, the conductor 260, and the insulator 280 (see FIG. 24A to FIG. 24D). The insulator 282 can be deposited by a sputtering method, a CVD method, an MBE method, a PLD method, an ALD method, or the like. The insulator 282 is preferably deposited by a sputtering method. Since hydrogen is not used as a deposition gas in the sputtering method, the hydrogen concentration in the insulator 282 can be reduced. The insulator 282 is deposited by a sputtering method in an oxygen-containing atmosphere, whereby oxygen can be added to the insulator 280 during the deposition. Thus, excess oxygen can be contained in the insulator 280. At this time, the insulator 282 is preferably deposited while the substrate is being heated.

In this embodiment, for the insulator 282, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality.

Next, heat treatment is preferably performed. The heat treatment can be performed under a condition similar to that of the above heat treatment. In this embodiment, treatment is performed at 400° C. in a nitrogen atmosphere for one hour. By the heat treatment, oxygen added at the time of the deposition of the insulator 282 can be diffused into the insulator 280 and the insulator 250a and then can be supplied selectively to the channel formation region of the oxide 230. Accordingly, a semiconductor device having favorable electrical characteristics can be provided. A semiconductor device having favorable reliability can also be provided.

Note that the heat treatment is not necessarily performed after the formation of the insulator 282 and may be performed after the deposition of the insulator 283, for example.

Next, the insulator 283 is formed over the insulator 282 (see FIG. 24A to FIG. 24D). The insulator 283 can be deposited by a sputtering method, a CVD method, an MBE method, a PLD method, an ALD method, or the like. The insulator 283 is preferably deposited by a sputtering method. Since hydrogen is not used as a deposition gas in the sputtering method, the hydrogen concentration in the insulator 283 can be reduced. The insulator 283 may be a multilayer. For example, silicon nitride may be deposited by a sputtering method and silicon nitride may be deposited by a CVD method over the silicon nitride.

Next, the insulator 285 is deposited over the insulator 283. The insulating film can be deposited by a sputtering method, a CVD method, an MBE method, a PLD method, an ALD method, or the like. A silicon oxide film is deposited by a CVD method as the insulating film, for example.

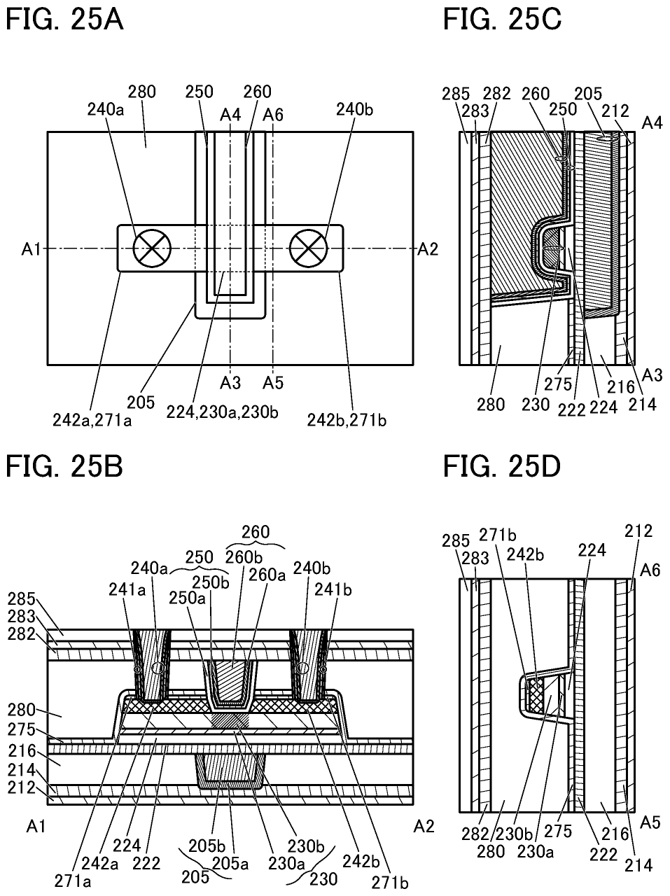

Subsequently, openings reaching the conductor 242 are formed in the insulator 271, the insulator 275, the insulator 280, the insulator 282, the insulator 283, and the insulator 285 (see FIG. 25A to FIG. 25D). The openings are formed by a lithography method. Note that the openings in the top view in FIG. 25A each have a circular shape; however, the shapes of the openings are not limited thereto. For example, the openings in the top view may each have an almost circular shape such as an elliptical shape, a polygonal shape such as a quadrangular shape, or a polygonal shape such as a quadrangular shape with rounded corners.

Subsequently, an insulating film to be the insulator 241 is deposited and the insulating film is subjected to anisotropic etching, so that the insulator 241 is formed (see FIG. 25A to FIG. 25D). The insulating film to be the insulator 241 can be deposited by a sputtering method, a CVD method, an MBE method, a PLD method, an ALD method, or the like. As the insulating film to be the insulator 241, an insulating film having a function of inhibiting passage of oxygen is preferably used. For example, it is preferable that aluminum oxide be deposited by an ALD method and silicon nitride be deposited thereover by a PEALD method. Silicon nitride is preferable because it has a high barrier property against hydrogen.

As an anisotropic etching for the insulating film to be the insulator 241, a dry etching method may be performed, for example. When the insulator 241 is provided on the side wall portions of the openings, passage of oxygen from the outside can be inhibited and oxidation of the conductor 240a and the conductor 240b to be formed next can be prevented. Furthermore, impurities such as water and hydrogen contained in the insulator 280 or the like can be prevented from being diffused into the conductor 240a and the conductor 240b.

Next, a conductive film to be the conductor 240a and the conductor 240b is deposited. The conductive film to be the conductor 240a and the conductor 240b desirably has a stacked-layer structure which includes a conductor having a function of inhibiting passage of impurities such as water and hydrogen. For example, a stacked layer of tantalum nitride, titanium nitride, or the like and tungsten, molybdenum, copper, or the like can be employed. The conductive film to be the conductor 240 can be deposited by a sputtering method, a CVD method, an MBE method, a PLD method, an ALD method, or the like.

Then, part of the conductive film to be the conductor 240a and the conductor 240b is removed by CMP treatment to expose the top surface of the insulator 285. As a result, the conductive film remains only in the openings, so that the conductor 240a and the conductor 240b having flat top surfaces can be formed (see FIG. 25A to FIG. 25D). Note that the top surface of the insulator 285 is partly removed by the CMP treatment in some cases.

Next, a conductive film to be the conductor 246 is deposited. The conductive film to be the conductor 246 can be deposited by a sputtering method, a CVD method, an MBE method, a PLD method, an ALD method, or the like.

Then, the conductive film to be the conductor 246 is processed by a lithography method, thereby forming the conductor 246a in contact with the top surface of the conductor 240a and the conductor 246b in contact with the top surface of the conductor 240b. At this time, part of the insulator 285 in a region where the conductor 246a and the conductor 246b do not overlap with the insulator 285 is sometimes removed.

Through the above process, the semiconductor device including the transistor 200 illustrated in FIG. 14A to FIG. 14D can be manufactured. As illustrated in FIG. 16A to FIG. 25A, FIG. 16B to FIG. 25B, FIG. 16C to FIG. 25C, and FIG. 16D to FIG. 25D, the transistor 200 can be manufactured with the use of the method for manufacturing the semiconductor device described in this embodiment.

### <Microwave Treatment Apparatus>

A microwave treatment apparatus that can be used for the above method for manufacturing the semiconductor device is described below.

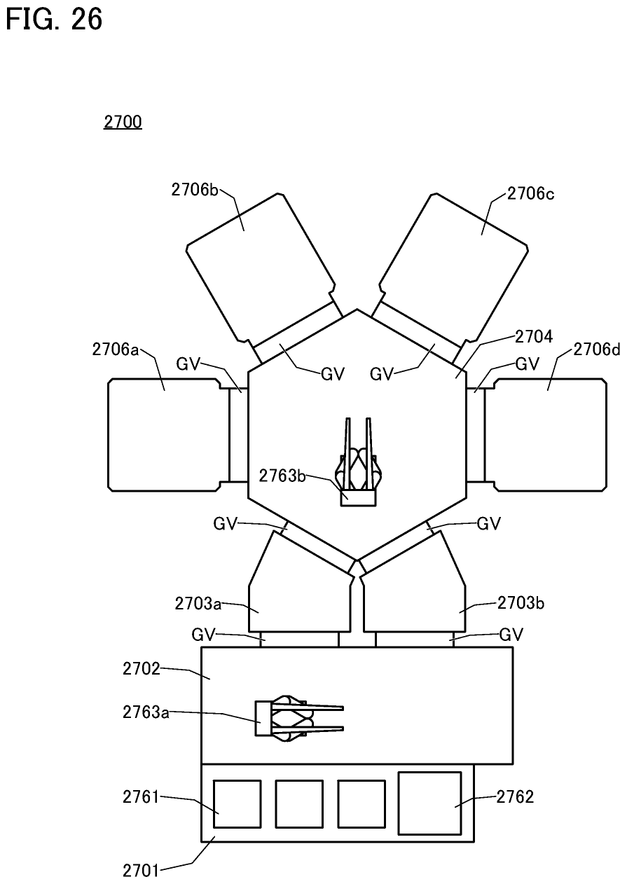

First, a structure of a manufacturing apparatus that can reduce entry of impurities in manufacturing a semiconductor device or the like is described with reference to FIG. 26 to FIG. 29.

FIG. 26 schematically illustrates a top view of a single wafer multi-chamber manufacturing apparatus 2700. The manufacturing apparatus 2700 includes an atmosphere-side substrate supply chamber 2701 including a cassette port 2761 for storing substrates and an alignment port 2762 for performing alignment of substrates; an atmosphere-side substrate transfer chamber 2702 through which a substrate is transferred from the atmosphere-side substrate supply chamber 2701; a load lock chamber 2703a where a substrate is carried in and the pressure inside the chamber is switched from atmospheric pressure to reduced pressure or from reduced pressure to atmospheric pressure; an unload lock chamber 2703b where a substrate is carried out and the pressure inside the chamber is switched from reduced pressure to atmospheric pressure or from atmospheric pressure to reduced pressure; a transfer chamber 2704 through which a substrate is transferred in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that each chamber excluding the atmosphere-side substrate supply chamber 2701 and the atmosphere-side substrate transfer chamber 2702 can be independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in the transfer chamber 2704 and each of the chambers can be measured using a mass analyzer. For example, Qulee CGM-051, a quadrupole mass analyzer (also referred to as Q-mass) produced by ULVAC, Inc. can be used.

Furthermore, the transfer chamber 2704 and the chambers each desirably have a structure in which the amount of external leakage or internal leakage is small. For example, the leakage rate in the transfer chamber 2704 and each of the chambers is less than or equal to 3×10⁻⁶ Pa·m³/s, preferably less than or equal to 1×10⁻⁶ Pa·m³/s. Furthermore, for example, the leakage rate of a gas molecule (atom) having m/z of 18 is less than or equal to 1×10⁻⁷ Pa·m³/s, preferably less than or equal to 3×10⁻⁸ Pa·m³/s. Furthermore, for example, the leakage rate of a gas molecule (atom) having m/z of 28 is less than or equal to 1×10⁻⁵ Pa·m³/s, preferably less than or equal to 1×10⁻⁶ Pa·m³/s. Furthermore, for example, the leakage rate of a gas molecule (atom) having m/z of 44 is less than or equal to 3×10⁻⁶ Pa·m³/s, preferably less than or equal to 1×10⁻⁶ Pa·m³/s.

Note that a leakage rate can be derived from the total pressure and partial pressure measured using the above-described mass analyzer. The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, metal covered with iron fluoride, aluminum oxide, or chromium oxide is preferably used. The metal gasket achieves higher adhesion than an O-ring and can reduce the external leakage. Furthermore, with the use of the metal covered with iron fluoride, aluminum oxide, chromium oxide, or the like, which is in the passive state, the release of gas containing impurities released from the metal gasket is inhibited, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing iron, chromium, nickel, and the like covered with the above-described metal, which releases a small amount of gas containing impurities, may be used. The alloy containing iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only metal when possible, and in the case where a viewing window formed of quartz or the like is provided, for example, the surface is preferably thinly covered with iron fluoride, aluminum oxide, chromium oxide, or the like to inhibit release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with the use of a pump with high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a rare gas is preferably used as the inert gas.

Alternatively, treatment for evacuating the transfer chamber 2704 and each of the chambers is preferably performed a certain period of time after a heated inert gas such as a rare gas, heated oxygen, or the like is introduced to increase the pressure in the transfer chamber 2704 and each of the chambers. The introduction of the heated gas can desorb the adsorbed substance in the transfer chamber 2704 and each of the chambers, and impurities present in the transfer chamber 2704 and each of the chambers can be reduced. Note that this treatment is effective when repeated more than or equal to 2 times and less than or equal to 30 times, preferably more than or equal to 5 times and less than or equal to 15 times. Specifically, an inert gas, oxygen, or the like at a temperature higher than or equal to 40° C. and lower than or equal to 400° C., preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, further preferably higher than or equal to 5 Pa and lower than or equal to 100 Pa in the time range from 1 minute to 300 minutes, preferably from 5 minutes to 120 minutes. After that, the transfer chamber 2704 and each of the chambers are evacuated in the time range from 5 minutes to 300 minutes, preferably from 10 minutes to 120 minutes.

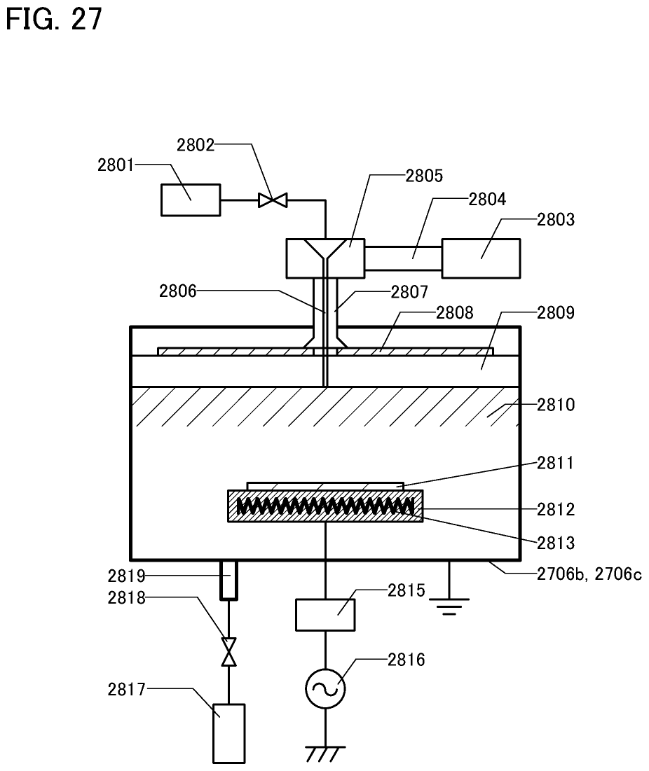

Next, the chamber 2706b and the chamber 2706c are described with reference to a schematic cross-sectional view illustrated in FIG. 27.

The chamber 2706b and the chamber 2706c are chambers in which microwave treatment can be performed on an object, for example. Note that the chamber 2706b is different from the chamber 2706c only in the atmosphere in performing the microwave treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is placed in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 2818 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function as an electrostatic chuck or a mechanical chuck for holding the substrate 2811. Furthermore, the substrate holder 2812 has a function as an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2817, a cryotrap may be used. The use of the cryopump and the cryotrap is particularly preferable because water can be efficiently exhausted.

Furthermore, for example, the heating mechanism 2813 is a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is −80° C. or lower, preferably −100° C. or lower is preferably used. For example, an oxygen gas, a nitrogen gas, or a rare gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high density region of high-density plasma 2810 described later; thus, provision of the protective layer can reduce the damage. Consequently, an increase in the number of particles or the like during the treatment can be inhibited.

The high-frequency generator 2803 has a function of generating a microwave of, for example, more than or equal to 0.3 GHz and less than or equal to 3.0 GHz, more than or equal to 0.7 GHz and less than or equal to 1.1 GHz, or more than or equal to 2.2 GHz and less than or equal to 2.8 GHz. The microwave generated by the high-frequency generator 2803 is propagated to the mode converter 2805 through the waveguide 2804. The mode converter 2805 converts the microwave propagated in the TE mode into a microwave in the TEM mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF power source with a frequency of 13.56 MHz, 27.12 MHz, or the like is used, for example. The application of a bias to the substrate side allows ions in the high-density plasma 2810 to efficiently reach a deep portion of an opening portion of the film or the like over the substrate 2811.

For example, in the chamber 2706b or the chamber 2706c, oxygen radical treatment using the high-density plasma 2810 can be performed by introducing oxygen from the gas supply source 2801.

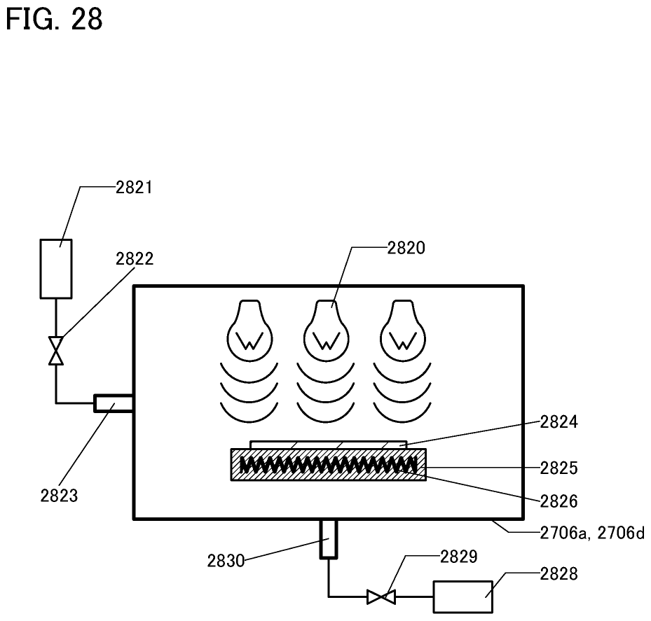

Next, the chamber 2706a and the chamber 2706d are described with reference to a schematic cross-sectional view illustrated in FIG. 28.

The chamber 2706a and the chamber 2706d are chambers in which an object can be irradiated with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or a plurality of lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is provided to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light is used, for example. For example, a light source having a function of emitting an electromagnetic wave which has a peak in a wavelength region of longer than or equal to 10 nm and shorter than or equal to 2500 nm, longer than or equal to 500 nm and shorter than or equal to 2000 nm, or longer than or equal to 40 nm and shorter than or equal to 340 nm is used.

As the lamp 2820, a light source such as a halogen lamp, a metal halide lamp, a xenon arc lamp, a carbon arc lamp, a high-pressure sodium lamp, or a high-pressure mercury lamp is used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may generate heat in the substrate holder 2825 to heat the substrate 2824. In this case, the substrate holder 2825 does not need to include the heating mechanism 2826 therein.

For the vacuum pump 2828, refer to the description of the vacuum pump 2817. Furthermore, for the heating mechanism 2826, refer to the description of the heating mechanism 2813. Furthermore, for the gas supply source 2821, refer to the description of the gas supply source 2801.

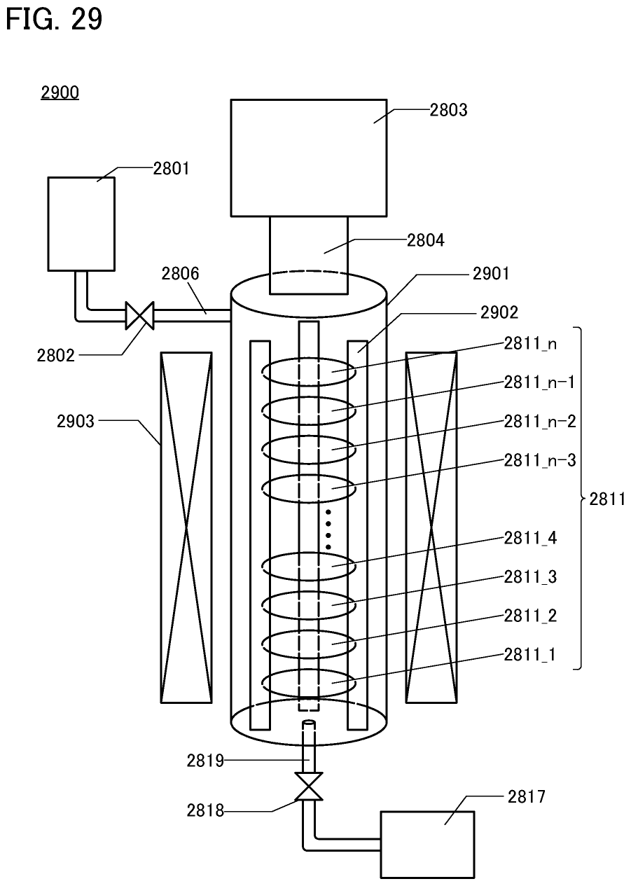

A microwave treatment apparatus that can be used in this embodiment is not limited to the above. A microwave treatment apparatus 2900 illustrated in FIG. 29 can be used. The microwave treatment apparatus 2900 includes a quartz tube 2901, the gas supply source 2801, the valve 2802, the high-frequency generator 2803, the waveguide 2804, the gas pipe 2806, the vacuum pump 2817, the valve 2818, and the exhaust port 2819. Furthermore, the microwave treatment apparatus 2900 includes a substrate holder 2902 that holds a plurality of substrates 2811 (2811_1 to 2811_n, n is an integer greater than or equal to 2) in the quartz tube 2901. The microwave treatment apparatus 2900 may further include a heating means 2903 outside the quartz tube 2901.

The substrate placed in the quartz tube 2901 is irradiated with the microwaves generated by the high-frequency generator 2803 and passing through the waveguide 2804. The vacuum pump 2817 is connected to the exhaust port 2819 through the valve 2818 and can adjust the pressure inside the quartz tube 2901. The gas supply source 2801 is connected to the gas pipe 2806 through the valve 2802 and can introduce a desired gas into the quartz tube 2901. The heating means 2903 can heat the substrate 2811 in the quartz tube 2901 to a desired temperature. Alternatively, the heating means 2903 may heat the gas which is supplied from the gas supply source 2801. With the use of the microwave treatment apparatus 2900, the substrate 2811 can be subjected to heat treatment and microwave treatment at the same time. Alternatively, the substrate 2811 can be heated and then subjected to microwave treatment. Alternatively, the substrate 2811 can be subjected to microwave treatment and then heat treatment.

All of the substrate 2811_1 to the substrate 2811 _n may be substrates to be treated where a semiconductor device or a memory device is to be formed, or some of the substrates may be dummy substrates. For example, the substrate 2811_1 and the substrate 2811_n may be dummy substrates and the substrate 2811_2 to the substrate 2811_n−1 may be substrates to be treated. Alternatively, the substrate 2811_1, the substrate 2811_2, the substrate 2811_n−1, and the substrate 2811_n may be dummy substrates and the substrate 2811_3 to the substrate 2811_n−2 may be substrates to be treated. A dummy substrate is preferably used, in which case a plurality of substrates to be treated can be uniformly treated at the time of microwave treatment or heat treatment and a variation between the substrates to be treated can be reduced. For example, a dummy substrate is preferably placed over the substrate to be treated which is the closest to the high-frequency generator 2803 and the waveguide 2804, in which case the substrate to be treated is inhibited from being directly exposed to microwaves.

With the use of the above-described manufacturing apparatus, the quality of a film or the like can be modified while the entry of impurities into an object is inhibited.

The microwave treatment apparatuses illustrated in FIG. 27 to FIG. 29 can be used in the treatment chamber 4011 illustrated in FIG. 7 in the above embodiment.

### <Modification Example of Semiconductor Device>

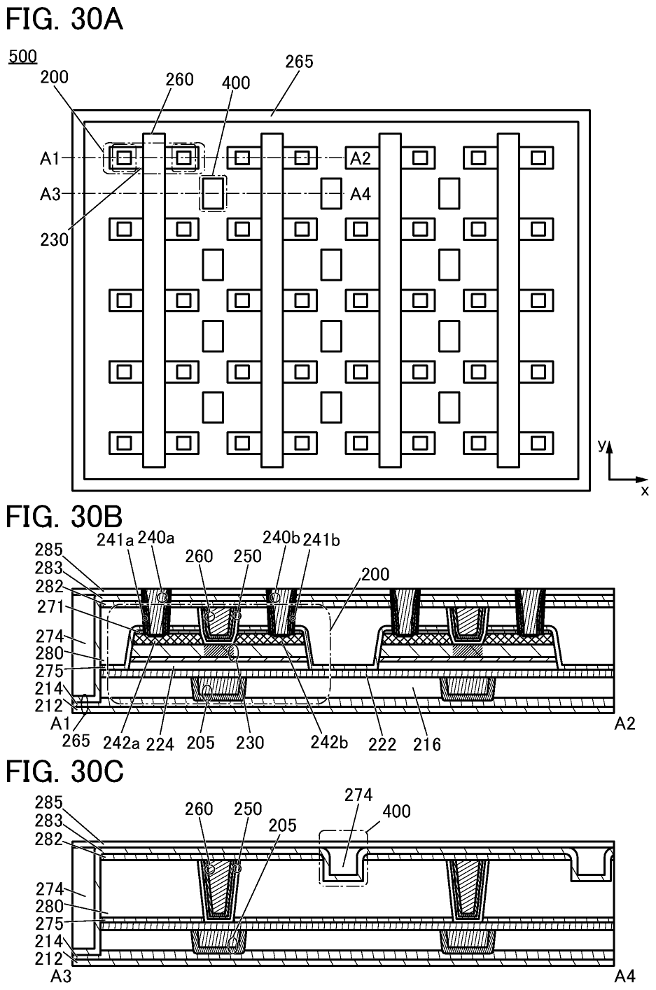

An example of the semiconductor device of one embodiment of the present invention is described below with reference to FIG. 30.

FIG. 30A is a top view of a semiconductor device 500. In FIG. 30A, the x-axis is parallel to the channel length direction of the transistor 200, and the y-axis is perpendicular to the x-axis. Moreover, FIG. 30B is a cross-sectional view corresponding to a portion indicated by dashed-dotted line A1-A2 in FIG. 30A, and is also a cross-sectional view in the channel length direction of the transistor 200. FIG. 30C is a cross-sectional view corresponding to a portion indicated by dashed-dotted line A3-A4 in FIG. 30A, and is also a cross-sectional view of an opening region 400 and the vicinity thereof. Note that for clarity of the drawing, some components are not illustrated in the top view of FIG. 30A.

Note that in the semiconductor device illustrated in FIG. 30A to FIG. 30C, components having the same functions as the components included in the semiconductor device described in <Structure example of semiconductor device>are denoted by the same reference numerals. Note that the materials described in detail in <Structure example of semiconductor device>can also be used as constituent materials of the semiconductor devices in this section.

The semiconductor device 500 illustrated in FIG. 30A to FIG. 30C is a modification example of the semiconductor device illustrated in FIG. 14A to FIG. 14D. The semiconductor device 500 illustrated in FIG. 30A to FIG. 30C is different from the semiconductor device illustrated in FIG. 14A to FIG. 14D in that the opening region 400 is formed in the insulator 282 and the insulator 280. Moreover, a sealing portion 265 is formed to surround a plurality of transistors 200, which is a different point from the semiconductor device illustrated in FIG. 14A to FIG. 14D.

The semiconductor device 500 includes a plurality of transistors 200 and a plurality of opening regions 400. In addition, a plurality of conductors 260 functioning as gate electrodes of the transistors 200 are provided to extend in the y-axis direction. The opening regions 400 are formed in regions not overlapping with the oxide 230 nor the conductor 260. The sealing portion 265 is formed to surround the plurality of transistors 200 and the plurality of opening regions 400. Note that the numbers, the positions, and the sizes of the transistors 200, the conductors 260, and the opening regions 400 are not limited to those illustrated in FIG. 30 and may be set as appropriate in accordance with the design of the semiconductor device 500.

As illustrated in FIG. 30B and FIG. 30C, the sealing portion 265 is provided to surround the plurality of transistors 200 and the insulator 216, the insulator 222, the insulator 275, the insulator 280, and the insulator 282. In other words, the insulator 283 is provided to cover the insulator 216, the insulator 222, the insulator 275, the insulator 280, and the insulator 282. In the sealing portion 265, the insulator 283 is in contact with a top surface of the insulator 214. In the sealing portion 265, an insulator 274 is provided between the insulator 283 and the insulator 285. A top surface of the insulator 274 is substantially level with the uppermost surface of the insulator 283. As the insulator 274, an insulator similar to the insulator 280 can be used.

With such a structure, the plurality of transistors 200 can be surrounded by the insulator 283, the insulator 214, and the insulator 212. Here, one or more of the insulator 283, the insulator 214, and the insulator 212 preferably function as an insulating film having a barrier property against hydrogen. Accordingly, entry of hydrogen contained in the region outside the sealing portion 265 into a region in the sealing portion 265 can be inhibited.

As illustrated in FIG. 30C, the insulator 282 has an opening portion in the opening region 400. In the opening region 400, the insulator 280 may have a groove portion to overlap with the opening portion in the insulator 282. The depth of the groove portion of the insulator 280 is less than or equal to the depth at which a top surface of the insulator 275 is exposed and is, for example, approximately greater than or equal to 1/4 and less than or equal to 1/2 of the maximum thickness of the insulator 280.

As illustrated in FIG. 30C, the insulator 283 is in contact with a side surface of the insulator 282, the side surface of the insulator 280, and the top surface of the insulator 280 inside the opening region 400. Part of the insulator 274 is sometimes formed so as to be embedded in a depression portion formed in the insulator 283 in the opening region 400. At this time, the top surface of the insulator 274 formed in the opening region 400 is substantially aligned with the uppermost surface of the insulator 283, in some cases.

When heat treatment is performed in such a state that the opening region 400 is formed and the insulator 280 is exposed in the opening portion of the insulator 282, part of oxygen contained in the insulator 280 can be made to be diffused to the outside from the opening region 400 while oxygen is supplied to the oxide 230. This enables oxygen to be sufficiently supplied to the region serving as the channel formation region and its vicinity in the oxide semiconductor layer from the insulator 280 containing oxygen released by heating, and also prevents an excess amount of oxygen from being supplied thereto.

At this time, hydrogen contained in the insulator 280 can be bonded to oxygen and released to the outside through the opening region 400. The hydrogen bonded to oxygen is released as water. Thus, the amount of hydrogen contained in the insulator 280 can be reduced, and the hydrogen contained in the insulator 280 can be prevented from entering the oxide 230.

In FIG. 30A, the shape of the opening region 400 in the top view is substantially rectangular; however, the present invention is not limited thereto. For example, the shape of the opening region 400 in the top view may be a rectangular shape, an elliptical shape, a circular shape, a rhombus shape, or a shape obtained by combining these. The area and arrangement interval of the opening regions 400 can be set as appropriate in accordance with the design of the semiconductor device including the transistor 200. For example, in the region where the density of the transistors 200 is low, the area of the opening region 400 may be increased or the arrangement interval of the opening regions 400 may be narrowed. For example, in the region where the density of the transistors 200 is high, the area of the opening region 400 may be decreased, or the arrangement interval of the opening regions may be increased.

One embodiment of the present invention can provide a novel transistor. Another embodiment of the present invention can provide a semiconductor device with a high on-state current. Another embodiment of the present invention can provide a semiconductor device with excellent frequency characteristics. Another embodiment of the present invention can provide a semiconductor device having favorable reliability. Another embodiment of the present invention can provide a semiconductor device having favorable electrical characteristics.

The structure, method, and the like described in this embodiment can be used in an appropriate combination with other structures, methods, and the like described in this embodiment or the other embodiments.

### Embodiment 3

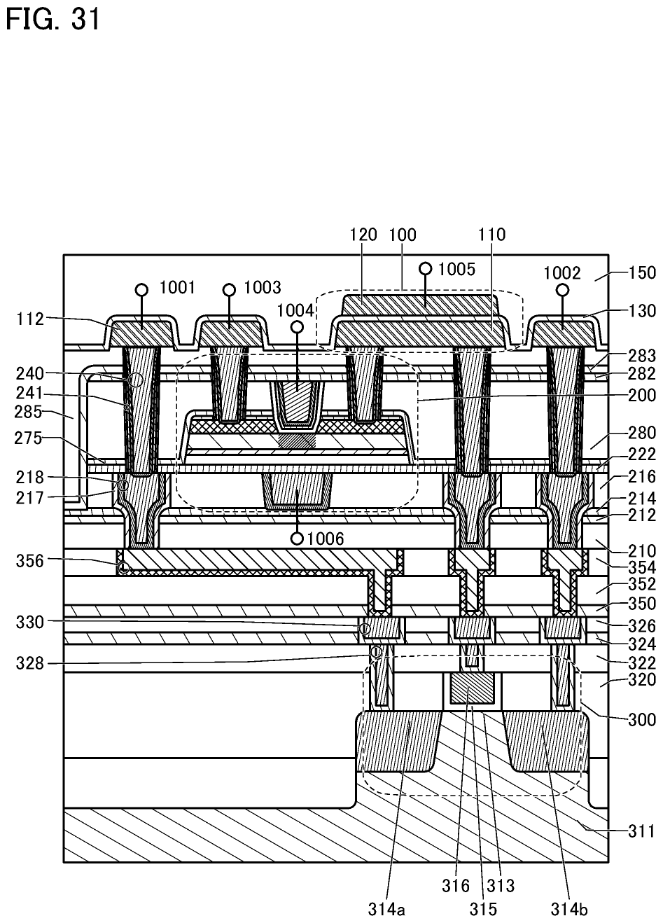

In this embodiment, one embodiment of a semiconductor device is described with reference to FIG. 31 to FIG. 35.

### [Storage Device 1]

FIG. 31 illustrates an example of a semiconductor device (a storage device) of one embodiment of the present invention. In the semiconductor device of one embodiment of the present invention, the transistor 200 is provided above a transistor 300, and a capacitor 100 is provided above the transistor 300 and the transistor 200. The transistor 200 described in the above embodiment can be used as the transistor 200.

The transistor 200 is a transistor in which a channel is formed in a semiconductor layer containing an oxide semiconductor. The off-state current of the transistor 200 is low; thus, by using the transistor 200 in a storage device, stored data can be retained for a long time. In other words, such a storage device does not require refresh operation or has extremely low frequency of the refresh operation, which leads to a sufficient reduction in power consumption of the storage device.

In the semiconductor device illustrated in FIG. 31, a wiring 1001 is electrically connected to a source of the transistor 300, and a wiring 1002 is electrically connected to a drain of the transistor 300. In addition, a wiring 1003 is electrically connected to one of the source and the drain of the transistor 200, a wiring 1004 is electrically connected to the first gate of the transistor 200, and a wiring 1006 is electrically connected to the second gate of the transistor 200. A gate of the transistor 300 and the other of the source and the drain of the transistor 200 are electrically connected to one electrode of the capacitor 100, and a wiring 1005 is electrically connected to the other electrode of the capacitor 100.

The storage devices illustrated in FIG. 31 can form a memory cell array when arranged in a matrix.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 31, the semiconductor region 313 (part of the substrate 311) in which a channel is formed has a protruding shape. In addition, the conductor 316 is provided to cover a side surface and a top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 31 is an example and the structure is not limited thereto; an appropriate transistor is used in accordance with a circuit structure or a driving method.

### <Capacitor 100>

The capacitor 100 is provided above the transistor 200. The capacitor 100 includes a conductor 110 functioning as a first electrode, a conductor 120 functioning as a second electrode, and an insulator 130 functioning as a dielectric. Here, for the insulator 130, the insulator that can be used for the insulator 275 described in the above embodiment is preferably used.

For example, a conductor 112 and the conductor 110 over the conductor 240 can be formed at the same time. Note that the conductor 112 functions as a plug or a wiring that is electrically connected to the capacitor 100, the transistor 200, or the transistor 300. The conductor 112 and the conductor 110 correspond to the conductor 246 described in the above embodiment.

Although the conductor 112 and the conductor 110 having a single-layer structure are illustrated in FIG. 31, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

For the insulator 130, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like is used, and a stacked layer or a single layer can be provided.

For example, for the insulator 130, a stacked-layer structure using a material with high dielectric strength such as silicon oxynitride and a high permittivity (high-k) material is preferably used. In the capacitor 100 having such a structure, a sufficient capacitance can be ensured owing to the high permittivity (high-k) insulator, and the dielectric strength can be increased owing to the insulator with high dielectric strength, so that the electrostatic breakdown of the capacitor 100 can be inhibited.

As the insulator of a high permittivity (high-k) material (a material having a high relative permittivity), gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like can be given.

Examples of a material with high dielectric strength (a material having a low relative permittivity) include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

### <Wiring Layer>

Wiring layers provided with an interlayer film, a wiring, a plug, and the like may be provided between the components. In addition, a plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and another part of the conductor functions as a plug.

For example, an insulator 320, an insulator 322, an insulator 324, and an insulator 326 are sequentially stacked over the transistor 300 as interlayer films. A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as a plug or a wiring.

The insulators functioning as interlayer films may also function as planarization films that cover uneven shapes therebelow. For example, a top surface of the insulator 322 may be planarized by planarization treatment using a chemical mechanical polishing (CMP) method or the like to increase planarity.

A wiring layer may be provided over the insulator 326 and the conductor 330. For example, in FIG. 31, an insulator 350, an insulator 352, and an insulator 354 are stacked sequentially. Furthermore, a conductor 356 is formed in the insulator 350, the insulator 352, and the insulator 354. The conductor 356 functions as a plug or a wiring.

Similarly, a conductor 218, a conductor (the conductor 205) included in the transistor 200, and the like are embedded in an insulator 210, the insulator 212, the insulator 214, and the insulator 216. Note that the conductor 218 functions as a plug or a wiring that is electrically connected to the capacitor 100 or the transistor 300. In addition, an insulator 150 is provided over the conductor 120 and the insulator 130.

Here, like the insulator 241 described in the above embodiment, an insulator 217 is provided in contact with a side surface of the conductor 218 functioning as a plug. The insulator 217 is provided in contact with the inner wall of an opening formed in the insulator 210, the insulator 212, the insulator 214, and the insulator 216. That is, the insulator 217 is provided between the conductor 218 and the insulator 210, the insulator 212, the insulator 214, and the insulator 216. Note that the conductor 205 and the conductor 218 can be formed in parallel; thus, the insulator 217 is sometimes formed in contact with the side surface of the conductor 205.

For the insulator 217, an insulator such as silicon nitride, aluminum oxide, or silicon nitride oxide may be used. Since the insulator 217 is provided in contact with the insulator 210, the insulator 212, the insulator 214, and the insulator 222, the entry of impurities such as water and hydrogen into the oxide 230 through the conductor 218 from the insulator 210, the insulator 216, or the like can be inhibited. In particular, silicon nitride is suitable because of having a high barrier property against hydrogen. Moreover, oxygen contained in the insulator 210 or the insulator 216 can be prevented from being absorbed by the conductor 218.

The insulator 217 can be formed in a manner similar to that of the insulator 241. For example, silicon nitride is deposited by a PEALD method and an opening reaching the conductor 356 is formed by anisotropic etching.

As an insulator that can be used for an interlayer film, an insulating oxide, an insulating nitride, an insulating oxynitride, an insulating nitride oxide, an insulating metal oxide, an insulating metal oxynitride, an insulating metal nitride oxide, or the like is given.

For example, when a material having a low relative permittivity is used for the insulator functioning as an interlayer film, parasitic capacitance generated between wirings can be reduced. Thus, a material is preferably selected depending on the function of an insulator.

For example, the insulator 150, the insulator 210, the insulator 352, the insulator 354, and the like preferably include an insulator having a low relative permittivity. For example, the insulator preferably includes silicon nitride oxide, silicon nitride, silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

When a transistor using an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen can be used for the insulator 214, the insulator 212, the insulator 350, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. A semiconductor having a high electrical conductivity, typified by polycrystalline silicon containing an impurity element such as phosphorus, or silicide such as nickel silicide may be used.

For example, for the conductor 328, the conductor 330, the conductor 356, the conductor 218, the conductor 112, and the like, a single-layer structure or a stacked-layer structure using a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

<Wiring or Plug In Layer Provided with Oxide Semiconductor>

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, the insulator 241 is preferably provided between the conductor 240 and the insulator 285 and the insulator 280 that contain excess oxygen or an impurity in FIG. 31. Since the insulator 241 is provided in contact with the insulator 222, the insulator 275, the insulator 282, and the insulator 283, the insulator 224 and the transistor 200 can be sealed with the insulators having a barrier property.

That is, the insulator 241 can inhibit excess oxygen contained in the insulator 280 from being absorbed by the conductor 240. In addition, diffusion of hydrogen, which is an impurity, into the transistor 200 through the conductor 240 can be inhibited when the insulator 241 is provided.

The insulator 241 is preferably formed using an insulating material having a function of inhibiting diffusion of impurities such as water and hydrogen and oxygen. For example, silicon nitride, silicon nitride oxide, aluminum oxide, hafnium oxide, or the like is preferably used. In particular, silicon nitride is preferably used because silicon nitride has a high barrier property against hydrogen. Other than that, a metal oxide such as magnesium oxide, gallium oxide, germanium oxide, yttrium oxide, zirconium oxide, lanthanum oxide, neodymium oxide, or tantalum oxide can be used, for example.

As described in the above embodiment, the transistor 200 may be sealed with the insulator 212, the insulator 214, the insulator 282, and the insulator 283. Such a structure can inhibit entry of hydrogen contained in the insulator 285, the insulator 150, or the like into the insulator 280 or the like.

Here, the conductor 240 penetrates the insulator 283 and the insulator 282, and the conductor 218 penetrates the insulator 214 and the insulator 212; however, as described above, the insulator 241 is provided in contact with the conductor 240, and the insulator 217 is provided in contact with the conductor 218. This can reduce the amount of hydrogen entering the inside of the insulator 212, the insulator 214, the insulator 282, and the insulator 283 through the conductor 240 and the conductor 218. In this manner, the transistor 200 is sealed with the insulator 212, the insulator 214, the insulator 282, the insulator 283, the insulator 241, and the insulator 217, so that impurities such as hydrogen contained in the insulator 285 or the like can be inhibited from entering from the outside.

### <Dicing Line>

A dicing line (sometimes referred to as a scribe line, a dividing line, or a cutting line) which is provided when a large-sized substrate is divided into semiconductor elements so that a plurality of semiconductor devices are each formed in a chip form is described below. Examples of a dividing method include the case where a groove (a dicing line) for dividing the semiconductor elements is formed on the substrate, and then the substrate is cut along the dicing line to divide (split) it into a plurality of semiconductor devices.

Here, for example, as illustrated in FIG. 31, a region in which the insulator 283 and the insulator 214 are in contact with each other is preferably designed to overlap with the dicing line. That is, an opening is provided in the insulator 282, the insulator 280, the insulator 275, the insulator 222, and the insulator 216 in the vicinity of a region to be the dicing line that is provided on an outer edge of the memory cell including the plurality of transistors 200.

That is, in the opening provided in the insulator 282, the insulator 280, the insulator 275, the insulator 222, and the insulator 216, the insulator 214 is in contact with the insulator 283. For example, the insulator 214 and the insulator 283 may be formed using the same material and the same method. When the insulator 214 and the insulator 283 are formed using the same material and the same method, the adhesion therebetween can be increased.

With such a structure, the transistors 200 can be surrounded by the insulator 212, the insulator 214, the insulator 282, and the insulator 283. Since at least one of the insulator 212, the insulator 214, the insulator 282, and the insulator 283 has a function of inhibiting diffusion of oxygen, hydrogen, and water, even when the substrate is divided into circuit regions each of which is provided with the semiconductor elements described in this embodiment to be processed into a plurality of chips, entry and diffusion of impurities such as hydrogen and water from the direction of the side surface of the divided substrate into the transistor 200 can be prevented.

With the structure, excess oxygen in the insulator 280 can be prevented from being diffused to the outside. Accordingly, excess oxygen in the insulator 280 is efficiently supplied to the oxide where the channel is formed in the transistor 200. The oxygen can reduce oxygen vacancies in the oxide where the channel is formed in the transistor 200. Thus, the oxide where the channel is formed in the transistor 200 can be an oxide semiconductor with a low density of defect states and stable characteristics. That is, the transistor 200 can have a small variation in the electrical characteristics and higher reliability.

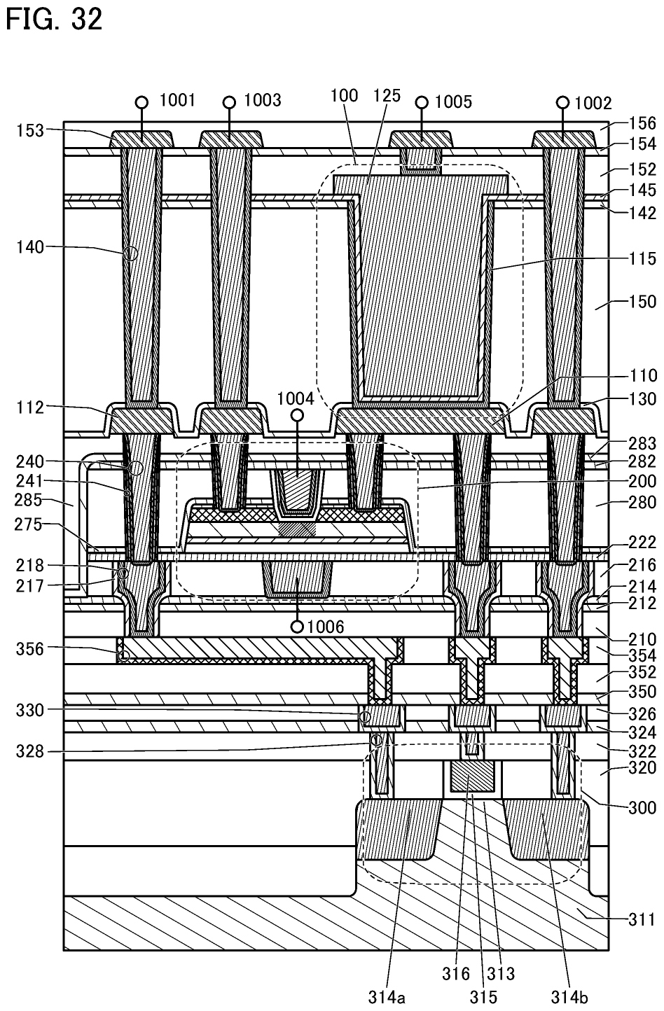

Note that although the capacitor 100 of the storage device illustrated in FIG. 31 has a planar shape, the storage device described in this embodiment is not limited thereto. For example, the capacitor 100 may have a cylindrical shape as illustrated in FIG. 32. Note that the structure below and including the insulator 150 of a storage device illustrated in FIG. 32 is similar to that of the semiconductor device illustrated in FIG. 31.

The capacitor 100 illustrated in FIG. 32 includes the insulator 150 over the insulator 130, an insulator 142 over the insulator 150, a conductor 115 placed in an opening formed in the insulator 150 and the insulator 142, an insulator 145 over the conductor 115 and the insulator 142, a conductor 125 over the insulator 145, and an insulator 152 over the conductor 125 and the insulator 145. Here, at least parts of the conductor 115, the insulator 145, and the conductor 125 are placed in the opening formed in the insulator 150 and the insulator 142. An insulator 154 is placed over the insulator 152, and a conductor 153 and an insulator 156 are placed over the insulator 154. Here, a conductor 140 is provided in an opening formed in the insulator 130, the insulator 150, the insulator 142, the insulator 145, the insulator 152, and the insulator 154.

The conductor 115 functions as a lower electrode of the capacitor 100, the conductor 125 functions as an upper electrode of the capacitor 100, and the insulator 145 functions as a dielectric of the capacitor 100. The capacitor 100 has a structure in which the upper electrode and the lower electrode face each other with the dielectric sandwiched therebetween on a side surface as well as a bottom surface of the opening in the insulator 150 and the insulator 142; thus, the capacitance per unit area can be increased. Thus, the deeper the opening is, the larger the capacitance of the capacitor 100 can be. Increasing the capacitance per unit area of the capacitor 100 in this manner can promote miniaturization or higher integration of the semiconductor device.

An insulator that can be used for the insulator 280 can be used for the insulator 152. The insulator 142 preferably functions as an etching stopper at the time of forming the opening in the insulator 150 and is formed using an insulator that can be used for the insulator 214.

The shape of the opening formed in the insulator 150 and the insulator 142 when seen from above may be a quadrangular shape, a polygonal shape other than a quadrangular shape, a polygonal shape with rounded corners, or a circular shape including an elliptical shape. Here, the area where the opening and the transistor 200 overlap with each other is preferably large in the top view. Such a structure can reduce the area occupied by the semiconductor device including the capacitor 100 and the transistor 200.

The conductor 115 is placed in contact with the opening formed in the insulator 142 and the insulator 150. A top surface of the conductor 115 is preferably substantially level with a top surface of the insulator 142. Furthermore, a bottom surface of the conductor 115 is in contact with the conductor 110 through an opening in the insulator 130. The conductor 115 is preferably deposited by an ALD method, a CVD method, or the like; for example, a conductor that can be used for the conductor 205 is used.

The insulator 145 is placed to cover the conductor 115 and the insulator 142. The insulator 145 is preferably deposited by an ALD method or a CVD method, for example. The insulator 145 can be provided to have stacked layers or a single layer using, for example, silicon oxide, silicon oxynitride, silicon nitride oxide, silicon nitride, zirconium oxide, aluminum oxide, aluminum oxynitride, aluminum nitride oxide, aluminum nitride, hafnium oxide, hafnium oxynitride, hafnium nitride oxide, or hafnium nitride. As the insulator 145, an insulating film in which zirconium oxide, aluminum oxide, and zirconium oxide are stacked in this order can be used, for example.

For the insulator 145, a material with high dielectric strength, such as silicon oxynitride, or a high permittivity (high-k) material is preferably used. Alternatively, a stacked-layer structure using a material with high dielectric strength and a high permittivity (high-k) material may be employed.

As an insulator of a high permittivity (high-k) material (a material having a high relative permittivity), gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, and the like can be given. The use of such a high-k material can ensure sufficient capacitance of the capacitor 100 even when the insulator 145 has a large thickness. When the insulator 145 has a large thickness, leakage current generated between the conductor 115 and the conductor 125 can be inhibited.

Examples of a material with high dielectric strength include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin. For example, it is possible to use an insulating film in which silicon nitride (SiNₓ) deposited by an ALD method, silicon oxide (SiOₓ) deposited by a PEALD method, and silicon nitride (SiNx) deposited by an ALD method are stacked in this order. The use of such an insulator with high dielectric strength can increase the dielectric strength and inhibit electrostatic breakdown of the capacitor 100.

The conductor 125 is placed to fill the opening formed in the insulator 142 and the insulator 150. The conductor 125 is electrically connected to the wiring 1005 through the conductor 140 and the conductor 153. The conductor 125 is preferably deposited by an ALD method, a CVD method, or the like and is formed using a conductor that can be used for the conductor 205, for example.

The conductor 153 is provided over the insulator 154 and is covered with the insulator 156. The conductor 153 is formed using a conductor that can be used as the conductor 112, and the insulator 156 is formed using an insulator that can be used as the insulator 152. Here, the conductor 153 is in contact with a top surface of the conductor 140 and functions as a terminal of the capacitor 100, the transistor 200, or the transistor 300.

### [Storage Device 2]

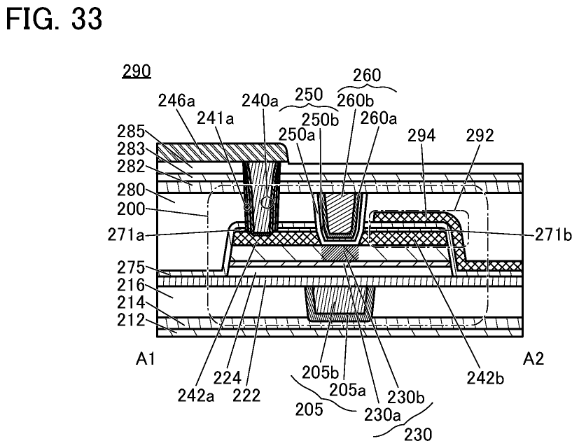

FIG. 33 illustrates an example of a semiconductor device (a storage device) of one embodiment of the present invention.

### <Structure Example of Memory Device>

FIG. 33 is a cross-sectional view of a semiconductor device including a memory device 290. The memory device 290 in FIG. 33 includes a capacitor device 292 besides the transistor 200 illustrated in FIG. 14A to FIG. 14D. FIG. 33 corresponds to a cross-sectional view of the transistor 200 in the channel length direction.

The capacitor device 292 includes the conductor 242b, the insulator 271b provided over the conductor 242b, the insulator 275 provided to cover the conductor 242b and the insulator 271b, and a conductor 294 over the insulator 275. In other words, the capacitor device 292 forms a MIM (Metal-Insulator-Metal) capacitor. Note that one of a pair of electrodes included in the capacitor device 292, i.e., the conductor 242b, can also serve as the source electrode of the transistor. The dielectric layer included in the capacitor device 292 can also serve as a protective layer provided in the transistor, i.e., the insulator 271 and the insulator 275. Thus, the manufacturing process of the capacitor device 292 can also serve as part of the manufacturing process of the transistor; therefore, the productivity of the semiconductor device can be improved. Furthermore, one of a pair of electrodes included in the capacitor device 292, that is, the conductor 242b, also serves as the source electrode of the transistor; therefore, the area in which the transistor and the capacitor device are placed can be reduced.

Note that the conductor 294 can be formed using, for example, a material that can be used for the conductor 242.

### Modification Example of Memory Device

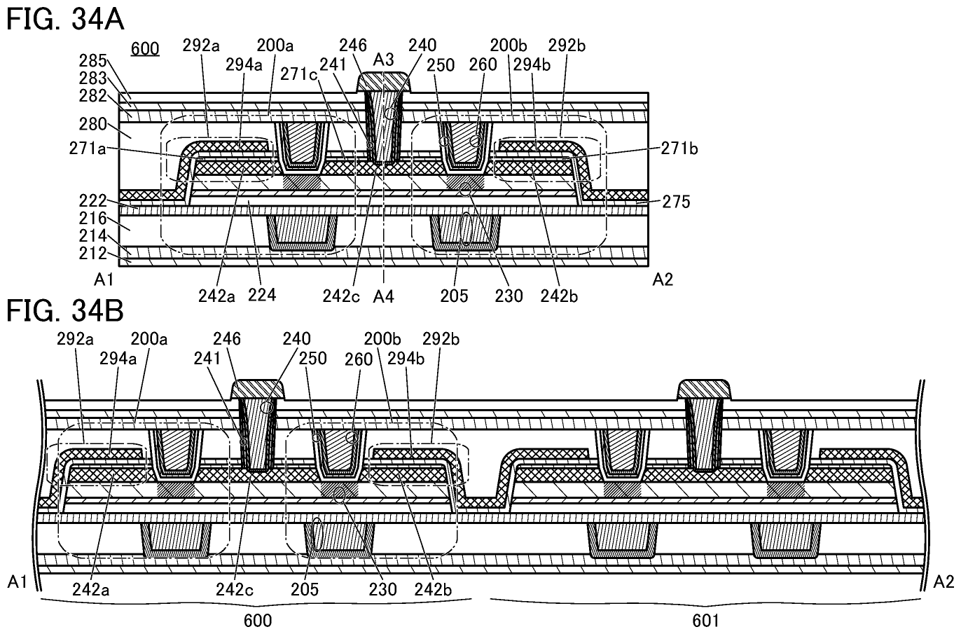

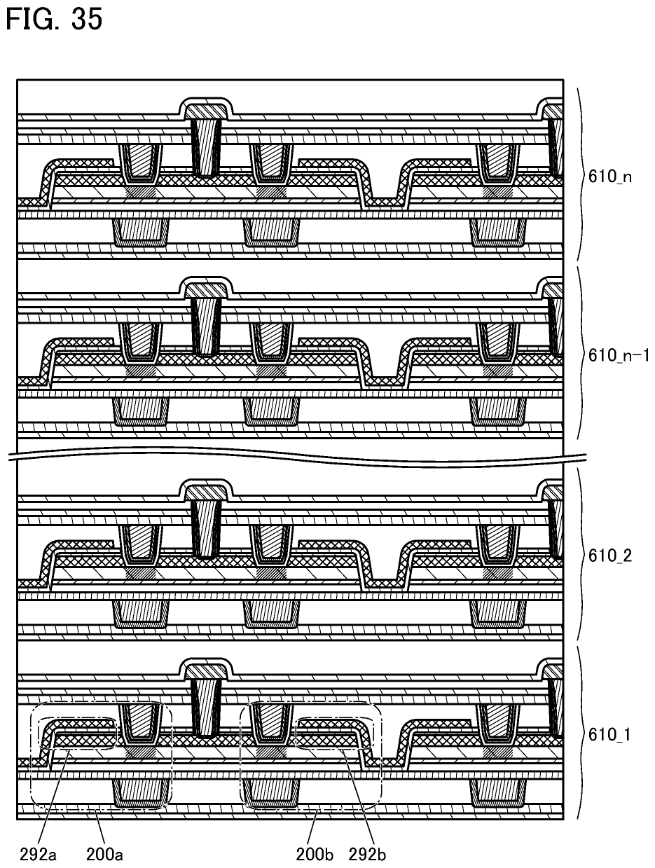

Examples of a semiconductor device of one embodiment of the present invention including the transistor 200 and the capacitor device 292, which are different from the one described above in <Structure example of memory device>, are described below with reference to FIG. 34A, FIG. 34B, and FIG. 35. Note that in the semiconductor devices illustrated in FIG. 34A, FIG. 34B, and FIG. 35, structures having the same function as those included in the semiconductor devices described in the above embodiment and <Structure example of memory device>(see FIG. 33) are denoted by the same reference numerals. Note that the materials described in detail in the above embodiment and <Structure example of memory device>can be used as constituent materials of the transistor 200 and the capacitor device 292 in this section.

### Modification Example 1 of Memory Device

An example of a semiconductor device 600 of one embodiment of the present invention including a transistor 200a, a transistor 200b, a capacitor device 292a, and a capacitor device 292b is described below with reference to FIG. 34A.

FIG. 34A is a cross-sectional view of the semiconductor device 600 including the transistor 200a, the transistor 200b, the capacitor device 292a, and the capacitor device 292b in the channel length direction. Here, the capacitor device 292a includes the conductor 242a, the insulator 271a provided over the conductor 242a, the insulator 275 provided to cover the conductor 242a and the insulator 271a, and a conductor 294a provided over the insulator 275. The capacitor device 292b includes the conductor 242b, the insulator 271b provided over the conductor 242b, the insulator 275 provided to cover the conductor 242b and the insulator 271b, and a conductor 294b provided over the insulator 275.

The semiconductor device 600 has a line-symmetric structure with respect to dashed-dotted line A3-A4 as illustrated in FIG. 34A. A conductor 242c serves as one of a source electrode and a drain electrode of the transistor 200a and one of a source electrode and a drain electrode of the transistor 200b. An insulator 271c is provided over the conductor 242c. The conductor 240 functioning as a plug connects the conductor 246 functioning as a wiring to the transistor 200a and the transistor 200b. Accordingly, when the connection of the two transistors, the two capacitor devices, the wiring, and the plug has the above-described structure, a semiconductor device that can be miniaturized or highly integrated can be provided.

The structure examples of the semiconductor device in FIG. 14A to FIG. 14D and FIG. 33 can be referred to for the structures and the effects of the transistor 200a, the transistor 200b, the capacitor device 292a, and the capacitor device 292b.

### Modification Example 2 of Memory Device

In the above description, the semiconductor device including the transistor 200a, the transistor 200b, the capacitor device 292a, and the capacitor device 292b is given as a structure example; however, the semiconductor device of this embodiment is not limited thereto. For example, as illustrated in FIG. 34B, a structure in which the semiconductor device 600 and a semiconductor device having a structure similar to that of the semiconductor device 600 are connected through a capacitor portion may be employed. In this specification, the semiconductor device including the transistor 200a, the transistor 200b, the capacitor device 292a, and the capacitor device 292b is referred to as a cell. For the structures of the transistor 200a, the transistor 200b, the capacitor device 292a, and the capacitor device 292b, the above description of the transistor 200a, the transistor 200b, the capacitor device 292a, and the capacitor device 292b can be referred to.

FIG. 34B is a cross-sectional view in which the semiconductor device 600 including the transistor 200a, the transistor 200b, the capacitor device 292a, and the capacitor device 292b, and a cell having a structure similar to that of the semiconductor device 600 are connected through a capacitor portion.

As illustrated in FIG. 34B, the conductor 294b functioning as one electrode of the capacitor device 292b included in the semiconductor device 600 also serves as one electrode of a capacitor device included in a semiconductor device 601 having a structure similar to that of the semiconductor device 600. Although not illustrated, the conductor 294a functioning as one electrode of the capacitor device 292a included in the semiconductor device 600 also serves as one electrode of a capacitor device included in a semiconductor device on the left side of the semiconductor device 600, that is, a semiconductor device adjacent to the semiconductor device 600 in the Al direction in FIG. 34B. The cell on the right side of the semiconductor device 601, that is, the cell in the A2 direction in FIG. 34B, has a similar structure. That is, a cell array (also referred to as a memory device layer) can be formed. With this structure of the cell array, the space between the adjacent cells can be reduced; thus, the projected area of the cell array can be reduced and high integration can be achieved. When the cells illustrated in FIG. 34B are arranged in a matrix, a matrix-shape cell array can be formed.

When the transistor 200a, the transistor 200b, the capacitor device 292a, and the capacitor device 292b are formed to have the structures described in this embodiment as described above, the area of the cell can be reduced and the semiconductor device including a cell array can be miniaturized or highly integrated.

Furthermore, the cell array may have a stacked-layer structure instead of a single-layer structure. FIG. 35 illustrates a cross-sectional view of n layers of cell arrays 610 that are stacked. When a plurality of cell arrays (a cell array 610_1 to a cell array 610_n) are stacked as illustrated in FIG. 35, cells can be integrally placed without increasing the area occupied by the cell arrays. In other words, a 3D cell array can be formed.

The structure, method, and the like described in this embodiment can be used in an appropriate combination with other structures, configurations, methods, and the like described in the other embodiments.

### Embodiment 4

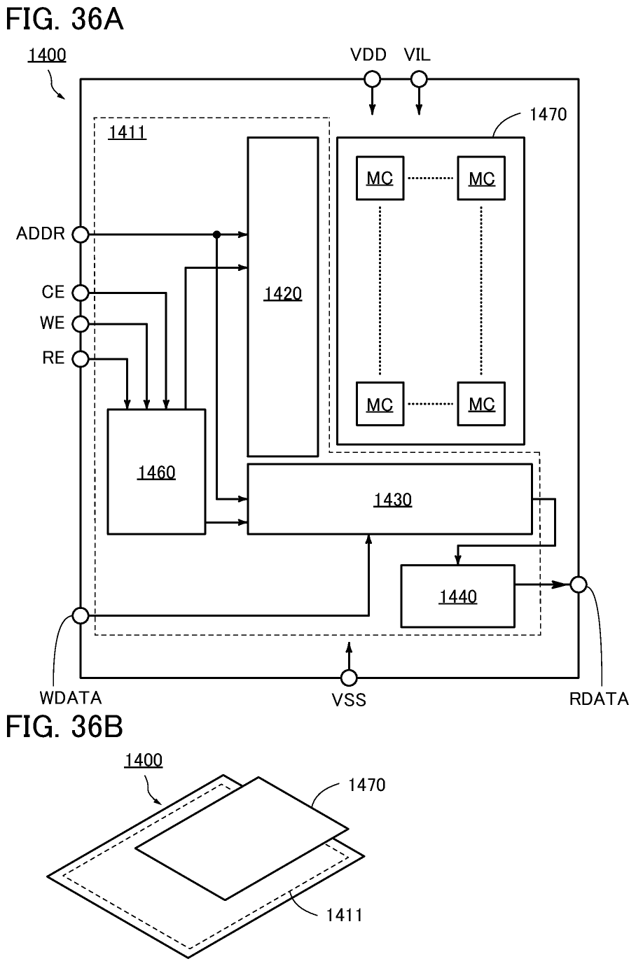

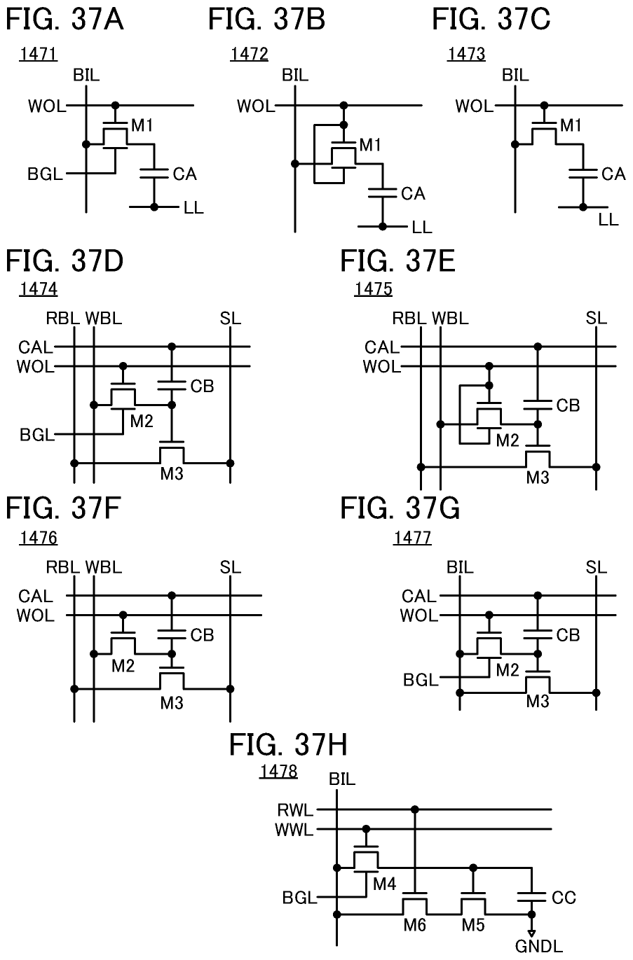

In this embodiment, a storage device of one embodiment of the present invention including a transistor in which an oxide is used as a semiconductor (hereinafter referred to as an OS transistor in some cases) and a capacitor (hereinafter referred to as an OS memory device in some cases), is described with reference to FIG. 36A, FIG. 36B, and FIG. 37A to FIG. 37H. The OS memory device is a storage device including at least a capacitor and the OS transistor that controls the charging and discharging of the capacitor. Since the OS transistor has an extremely low off-state current, the OS memory device has excellent retention characteristics and thus can function as a nonvolatile memory.

### <Structure Example of Storage Device>

FIG. 36A illustrates a structure example of the OS memory device. A storage device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RE), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RE) input from the outside, and generates control signals for the row decoder and the column decoder. The control signal CE is a chip enable signal, the control signal WE is a write enable signal, and the control signal RE is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of the wirings that connect the memory cell array 1470 to the row circuit 1420 depends on the structure of the memory cell MC, the number of the memory cells MC in a column, and the like. The number of the wirings that connect the memory cell array 1470 to the column circuit 1430 depends on the structure of the memory cell MC, the number of the memory cells MC in a row, and the like.

Note that FIG. 36A illustrates an example in which the peripheral circuit 1411 and the memory cell array 1470 are formed on the same plane; however, this embodiment is not limited thereto. For example, as illustrated in FIG. 36B, the memory cell array 1470 may be provided to overlap with part of the peripheral circuit 1411. For example, the sense amplifier may be provided below the memory cell array 1470 so that they overlap with each other.

FIG. 37A to FIG. 37H illustrate structure examples of a memory cell that can be applied to the memory cell MC.

### [DOSRAM]

FIG. 37A to FIG. 37C illustrate circuit structure examples of a memory cell of a DRAM. In this specification and the like, a DRAM using a memory cell including one OS transistor and one capacitor is referred to as a DOSRAM (registered trademark, Dynamic Oxide Semiconductor Random Access Memory) in some cases. A memory cell 1471 illustrated in FIG. 37A includes a transistor M1 and a capacitor CA. Note that the transistor M1 includes a gate (also referred to as a top gate in some cases) and a back gate.

A first terminal of the transistor M1 is connected to a first terminal of the capacitor CA, a second terminal of the transistor M1 is connected to a wiring BIL, the gate of the transistor M1 is connected to a wiring WOL, and the back gate of the transistor M1 is connected to a wiring BGL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and data reading, the wiring LL may be at a ground potential or a low-level potential. The wiring BGL functions as a wiring for applying a potential to the back gate of the transistor M1. By applying a given potential to the wiring BGL, the threshold voltage of the transistor M1 can be increased or decreased.

Here, the memory cell 1471 illustrated in FIG. 37A corresponds to the storage device illustrated in FIG. 33. That is, the transistor M1 and the capacitor CA correspond to the transistor 200 and the capacitor device 292, respectively.

The memory cell MC is not limited to the memory cell 1471, and the circuit structure can be changed. For example, as in a memory cell 1472 illustrated in FIG. 37B, the back gate of the transistor M1 may be connected not to the wiring BGL but to the wiring WOL in the memory cell MC. Alternatively, for example, the transistor M1 may be a single-gate transistor, that is, a transistor without a back gate in the memory cell MC as in a memory cell 1473 illustrated in FIG. 37C.

In the case where the semiconductor device described in the above embodiment is used in the memory cell 1471 or the like, the transistor 200 can be used as the transistor M1, and the capacitor 100 can be used as the capacitor CA. When an OS transistor is used as the transistor M1, the leakage current of the transistor M1 can be extremely low. That is, with the use of the transistor M1, written data can be retained for a long period of time, and thus the frequency of the refresh operation for the memory cell can be decreased. In addition, refresh operation for the memory cell can be omitted. In addition, since the transistor M1 has an extremely low leakage current, multi-level data or analog data can be retained in the memory cell 1471, the memory cell 1472, and the memory cell 1473.

In addition, in the DOSRAM, when the sense amplifier is provided below the memory cell array 1470 to overlap with the memory cell array 1470 as described above, the bit line can be shortened. This reduces bit line capacity, which reduces the storage capacity of the memory cell.

### [NOSRAM]

FIG. 37D to FIG. 37G each illustrate a circuit structure example of a gain-cell memory cell including two transistors and one capacitor. A memory cell 1474 illustrated in FIG. 37D includes a transistor M2, a transistor M3, and a capacitor CB. Note that the transistor M2 includes a top gate (simply referred to as a gate in some cases) and a back gate. In this specification and the like, a storage device including a gain-cell memory cell using an OS transistor as the transistor M2 is referred to as a NOSRAM (Nonvolatile Oxide Semiconductor RAM) in some cases.

A first terminal of the transistor M2 is connected to a first terminal of the capacitor CB, a second terminal of the transistor M2 is connected to a wiring WBL, the gate of the transistor M2 is connected to the wiring WOL, and the back gate of the transistor M2 is connected to the wiring BGL. A second terminal of the capacitor CB is connected to the wiring CAL. A first terminal of the transistor M3 is connected to a wiring RBL, a second terminal of the transistor M3 is connected to a wiring SL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In data writing and data reading, a high-level potential is preferably applied to the wiring CAL. In the time of data retaining, a low-level potential is preferably applied to the wiring CAL. The wiring BGL functions as a wiring for applying a potential to the back gate of the transistor M2. By applying a given potential to the wiring BGL, the threshold voltage of the transistor M2 can be increased or decreased.

Here, the memory cell 1474 illustrated in FIG. 37D corresponds to the storage device illustrated in FIG. 31. That is, the transistor M2, the capacitor CB, the transistor M3, the wiring WBL, the wiring WOL, the wiring BGL, the wiring CAL, the wiring RBL, and the wiring SL correspond to the transistor 200, the capacitor 100, the transistor 300, the wiring 1003, the wiring 1004, the wiring 1006, the wiring 1005, the wiring 1002, and the wiring 1001, respectively.

In addition, the memory cell MC is not limited to the memory cell 1474, and the circuit structure can be changed as appropriate. For example, as in a memory cell 1475 illustrated in FIG. 37E, the back gate of the transistor M2 may be connected not to the wiring BGL but to the wiring WOL in the memory cell MC. Alternatively, for example, the transistor M2 may be a single-gate transistor, that is, a transistor without a back gate in the memory cell MC as in a memory cell 1476 illustrated in FIG. 37F. For example, the memory cell MC may have a structure in which the wiring WBL and the wiring RBL are combined into one wiring BIL as in a memory cell 1477 illustrated in FIG. 37G.

In the case where the semiconductor device described in the above embodiment is used in the memory cell 1474 or the like, the transistor 200 can be used as the transistor M2, the transistor 300 can be used as the transistor M3, and the capacitor 100 can be used as the capacitor CB. When an OS transistor is used as the transistor M2, the leakage current of the transistor M2 can be extremely low. Consequently, with the use of the transistor M2, written data can be retained for a long period of time, and thus the frequency of the refresh operation for the memory cell can be decreased. In addition, refresh operation for the memory cell can be omitted. In addition, since the transistor M2 has an extremely low leakage current, multi-level data or analog data can be retained in the memory cell 1474. The same applies to the memory cell 1475 to the memory cell 1477.

Note that the transistor M3 may be a transistor containing silicon in a channel formation region (hereinafter referred to as a Si transistor in some cases). The conductivity type of the Si transistor may be either an n-channel type or a p-channel type. A Si transistor has higher field-effect mobility than an OS transistor in some cases. Therefore, a Si transistor may be used as the transistor M3 functioning as a read transistor. Furthermore, the use of a Si transistor as the transistor M3 enables the transistor M2 to be stacked over the transistor M3, in which case the area occupied by the memory cell can be reduced and high integration of the storage device can be achieved.

Alternatively, the transistor M3 may be an OS transistor. When OS transistors are used as the transistor M2 and the transistor M3, the circuit of the memory cell array 1470 can be formed using only n-channel transistors.

FIG. 37H illustrates an example of a gain-cell memory cell including three transistors and one capacitor. A memory cell 1478 illustrated in FIG. 37H includes a transistor M4 to a transistor M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor including a back gate, and the back gate is electrically connected to the wiring BGL. Note that the back gate and a gate of the transistor M4 may be electrically connected to each other. Alternatively, the transistor M4 does not necessarily include the back gate.

Note that each of the transistor M5 and the transistor M6 may be an n-channel Si transistor or a p-channel Si transistor. Alternatively, the transistor M4 to the transistor M6 may be OS transistors, in which case the circuit of the memory cell array 1470 can be formed using only n-channel transistors.

In the case where the semiconductor device described in the above embodiment is used in the memory cell 1478, the transistor 200 can be used as the transistor M4, the transistor 300 can be used as the transistor M5 and the transistor M6, and the capacitor 100 can be used as the capacitor CC. When an OS transistor is used as the transistor M4, the leakage current of the transistor M4 can be extremely low.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed.

In general, a variety of storage devices (memories) are used in semiconductor devices such as a computer in accordance with the intended use. The semiconductor device of one embodiment of the present invention can be suitably used for a memory included as a register in an arithmetic processing device such as a CPU, an SRAM (Static Random Access Memory), a DRAM (Dynamic Random Access Memory), and a 3D NAND memory, for example.

A memory included as a register in an arithmetic processing device such as a CPU is used for temporary storage of arithmetic operation results, for example, and thus is very frequently accessed by the arithmetic processing device. Accordingly, a high operating speed is required rather than storage capacity. The register also has a function of retaining setting information of the arithmetic processing device, for example.

An SRAM is used for a cache, for example. The cache has a function of retaining a copy of part of data retained in a main memory. By copying data which is frequently used and holding the copy of the data in the cache, the access speed to the data can be increased.

A DRAM is used for the main memory, for example. The main memory has a function of retaining a program and data which are read from a storage. The record density of a DRAM is approximately 0.1 to 0.3 Gbit/mm².

A 3D NAND memory is used for a storage, for example. The storage has a function of retaining data that needs to be retained for a long time and programs used in an arithmetic processing device, for example. Therefore, the storage needs to have a high storage capacity and a high record density rather than operating speed. The record density of a storage device used for a storage is approximately 0.6 to 6.0 Gbit/mm².

The storage device of one embodiment of the present invention operates fast and can retain data for a long time. The storage device of one embodiment of the present invention can be favorably used as a storage device in a boundary region including both the level in which a cache is placed and the level in which a main memory is placed. Alternatively, the storage device of one embodiment of the present invention can be favorably used as a storage device in a boundary region including both the level in which a main memory is placed and the level in which a storage is placed.

The structure described in this embodiment can be used in an appropriate combination with the structures described in the other embodiments and the like.

### Embodiment 5

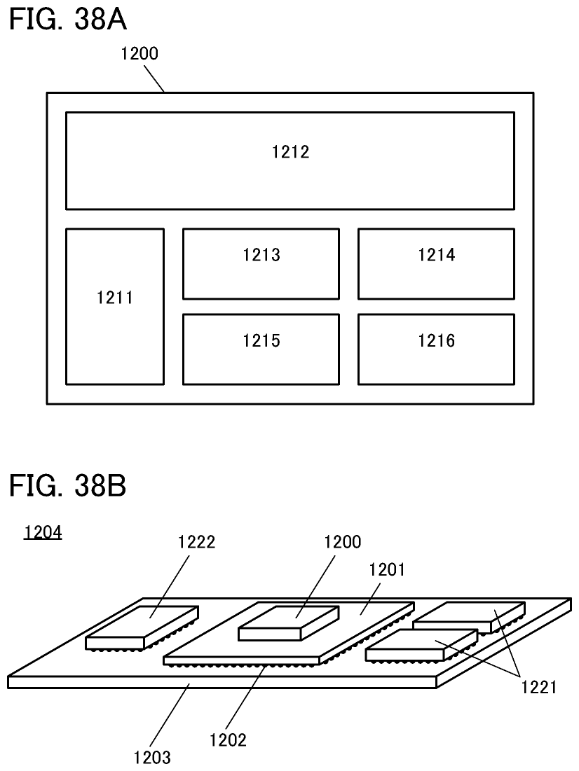

In this embodiment, an example of a chip 1200 on which the semiconductor device of the present invention is mounted is described with reference to FIG. 38A and FIG. 38B. A plurality of circuits (systems) are mounted on the chip 1200. A technique for integrating a plurality of circuits (systems) into one chip is referred to as system on chip (SoC) in some cases.

As illustrated in FIG. 38A, the chip 1200 includes a CPU 1211, a GPU 1212, one or a plurality of analog arithmetic units 1213, one or a plurality of memory controllers 1214, one or a plurality of interfaces 1215, one or a plurality of network circuits 1216, and the like.

A bump (not illustrated) is provided on the chip 1200, and as illustrated in FIG. 38B, the chip 1200 is connected to a first surface of a printed circuit board (PCB) 1201. In addition, a plurality of bumps 1202 are provided on the rear side of the first surface of the PCB 1201, and the PCB 1201 is connected to a motherboard 1203.

Storage devices such as DRAMs 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit or a product-sum operation circuit using an oxide semiconductor of the present invention is provided in the GPU 1212, image processing or product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between the memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 has a function of controlling connection to a LAN (Local Area Network) or the like. The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the PCB 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

The structure described in this embodiment can be used in an appropriate combination with the structures described in the other embodiments and the like.

### Embodiment 6

In this embodiment, examples of electronic components and electronic devices in which the storage device or the like described in the above embodiment is incorporated are described.

### Electronic Component

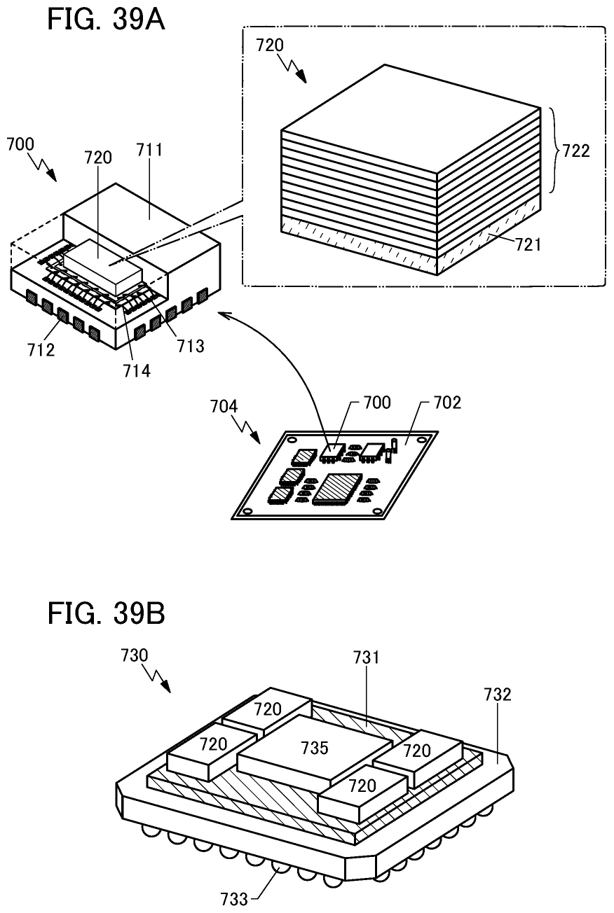

First, FIG. 39A and FIG. 39B show examples of an electronic component including a storage device 720.

FIG. 39A is a perspective view of an electronic component 700 and a substrate (circuit board 704) on which the electronic component 700 is mounted. The electronic component 700 in FIG. 39A includes the storage device 720 in a mold 711. FIG. 39A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the circuit board 704.

The storage device 720 includes a driver circuit layer 721 and a storage circuit layer 722.

FIG. 39B is a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In an SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5D mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably equal to each other. In the electronic component 730 of this embodiment, the heights of the storage device 720 and the semiconductor device 735 are preferably equal to each other, for example.

An electrode 733 may be provided on the bottom portion of the package substrate 732 to mount the electronic component 730 on another substrate. FIG. 39B illustrates an example in which the electrode 733 is formed of a solder ball. Solder balls are provided in a matrix on the bottom portion of the package substrate 732, whereby a BGA (Ball Grid Array) can be achieved. Alternatively, the electrode 733 may be formed of a conductive pin. When conductive pins are provided in a matrix on the bottom portion of the package substrate 732, a PGA (Pin Grid Array) can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

This embodiment can be implemented in an appropriate combination with the structures described in the other embodiments and the like.

### Embodiment 7

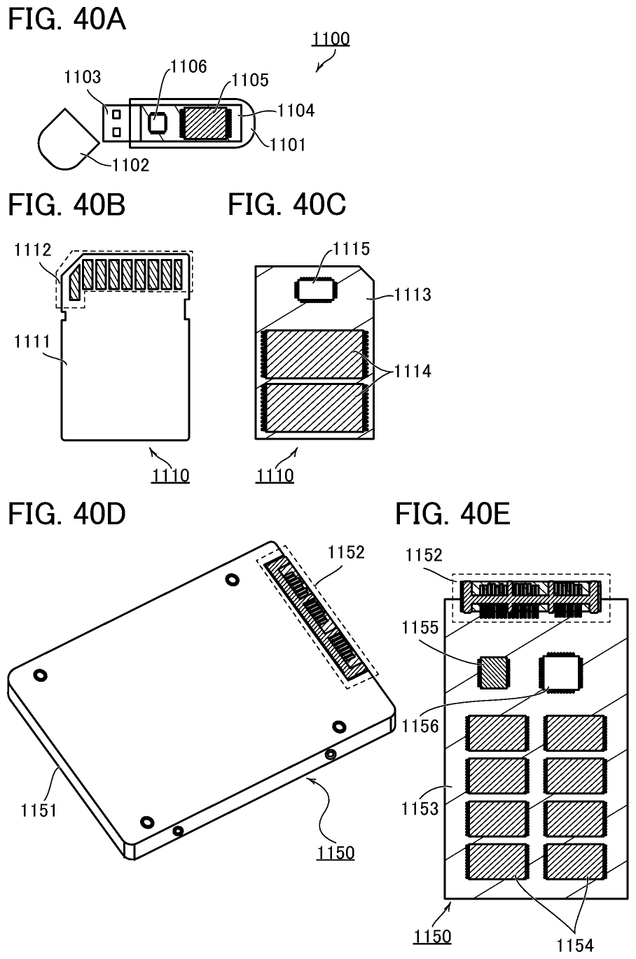

In this embodiment, application examples of the storage device using the semiconductor device described in the above embodiment are described. The semiconductor device described in the above embodiment can be applied to, for example, storage devices of a variety of electronic devices (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to a variety of removable storage devices such as memory cards (e.g., SD cards), USB memories, and SSDs (solid state drives). FIG. 40A to FIG. 40E schematically illustrate some structure examples of removable storage devices. The semiconductor device described in the above embodiment is processed into a packaged memory chip and used in a variety of storage devices and removable memories, for example.

FIG. 40A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105 or the like.

FIG. 40B is a schematic external view of an SD card, and FIG. 40C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the rear surface side of the substrate 1113, the capacity of the SD card 1110 can be increased. In addition, a wireless chip with a radio communication function may be provided on the substrate 1113. With this, data can be read from and written in the memory chip 1114 by radio communication between a host device and the SD card 1110. The semiconductor device described in the above embodiment can be incorporated in the memory chip 1114 or the like.

FIG. 40D is a schematic external view of an SSD, and FIG. 40E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the rear surface side of the substrate 1153, the capacity of the SSD 1150 can be increased. The semiconductor device described in the above embodiment can be incorporated in the memory chip 1154 or the like.

This embodiment can be implemented in combination with any of the structures described in the other embodiments and the like, as appropriate.

### Embodiment 8

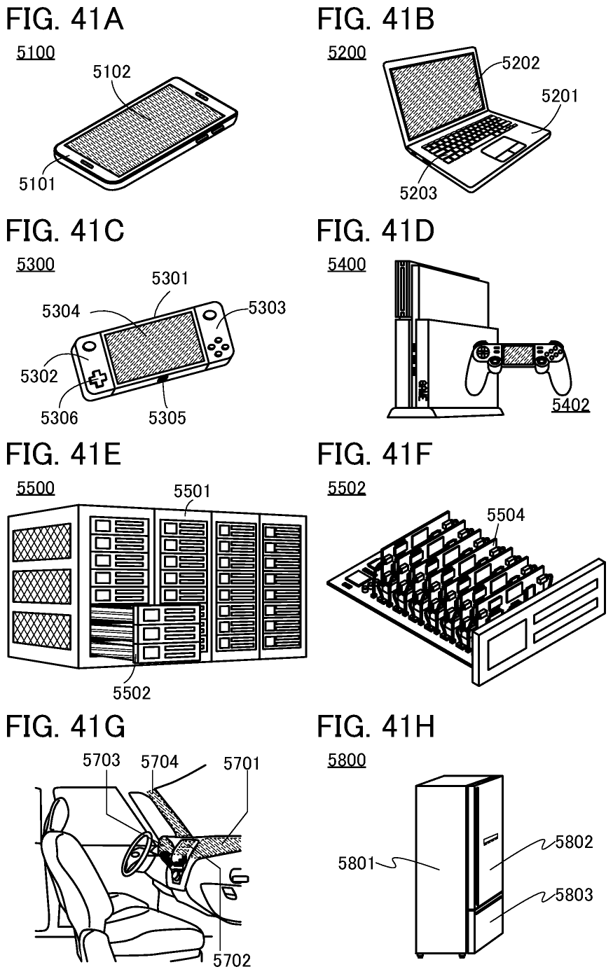

The semiconductor device of one embodiment of the present invention can be used as a processor such as a CPU or a GPU or a chip. FIG. 41A to FIG. 41H illustrate specific examples of electronic devices including a chip or a processor such as a CPU or a GPU of one embodiment of the present invention.

### <Electronic Device and System>

The GPU or the chip of one embodiment of the present invention can be mounted on a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. When the GPU or the chip of one embodiment of the present invention is provided in the electronic device, the electronic device can include artificial intelligence.

The electronic device of one embodiment of the present invention may include an antenna. When a signal is received by the antenna, the electronic device can display a video, data, and the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 41A to FIG. 41H illustrate examples of electronic devices.

### [Information Terminal]

FIG. 41A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the content of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 41B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with the use of the notebook information terminal 5200, novel artificial intelligence can be developed.

Note that although FIG. 41A and FIG. 41B illustrate a smartphone and a notebook information terminal, respectively, as examples of the electronic device in the above description, an information terminal other than a smartphone and a notebook information terminal can be used.

Examples of information terminals other than a smartphone and a notebook information terminal include a PDA (Personal Digital Assistant), a desktop information terminal, and a workstation.

### [Game Machines]

FIG. 41C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In that case, the housing 5302 and the housing 5303 can each function as an operating unit. Thus, a plurality of players can play a game at the same time. The chip described in the above embodiment can be incorporated into a chip provided on a substrate in the housing 5301, the housing 5302, and the housing 5303, for example.

FIG. 41D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated as examples of game machines in FIG. 41C and FIG. 41D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 41E illustrates a supercomputer 5500 as an example of a large computer. FIG. 41F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip described in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is illustrated as an example of a large computer in FIG. 41E and FIG. 41F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 41G illustrates an area around a windshield inside an automobile, which is an example of a moving vehicle. FIG. 41G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, and the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an imaging device (not illustrated) provided for the automobile.

That is, displaying an image taken by the imaging device provided outside the automobile leads to compensation for the blind spot and an increase in safety. In addition, displaying an image to compensate for a portion that cannot be seen makes it possible for the driver to confirm the safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 41H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, or the like.

Although the electric refrigerator-freezer is described as an example of a household appliance, other examples of household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic devices, the functions of the electronic devices, the application examples of artificial intelligence, their effects, and the like described in this embodiment can be combined as appropriate with the description of another electronic device.

This embodiment can be implemented in an appropriate combination with the structures described in the other embodiments and the like.

### REFERENCE NUMERALS

BGL: wiring, BIL: wiring, CA: capacitor, CB: capacitor, CC: capacitor, CAL: wiring, GNDL: wiring, MC: memory cell, M1: transistor, M2: transistor, M3: transistor, M4: transistor, M5: transistor, M6: transistor, RBL: wiring, RWL: wiring, SL: wiring, WBL: wiring, WOL: wiring, WWL: wiring, 10: substrate, 11a: precursor, 11b: precursor, 12a: reactant, 12b: reactant, 13a: oxide, 13b: oxide, 13c: oxide, 21: layer, 22: layer, 31: layer, 41: layer, 50: structure body, 53:

region, 54: region, 56: region, 58: region, 60: oxide, 62: oxide, 64: oxide, 100: capacitor, 110: conductor, 112: conductor, 115: conductor, 120: conductor, 125: conductor, 130: insulator, 140: conductor, 142: insulator, 145: insulator, 150: insulator, 152: insulator, 153: conductor, 154: insulator, 156: insulator, 200: transistor, 200a: transistor, 200b: transistor, 205: conductor, 205a: conductor, 205b: conductor, 210: insulator, 212: insulator, 214: insulator, 216: insulator, 217: insulator, 218: conductor, 222: insulator, 224: insulator, 224A: insulating film, 230: oxide, 230a: oxide, 230A: oxide film, 230b: oxide, 230B: oxide film, 230ba: region, 230bb: region, 230bc: region, 240: conductor, 240a: conductor, 240b: conductor, 241: insulator, 241a: insulator, 241b: insulator, 242: conductor, 242a: conductor, 242A: conductive film, 242b: conductor, 242B: conductive layer, 242c: conductor, 246: conductor, 246a: conductor, 246b: conductor, 250: insulator, 250a: insulator, 250A: insulating film, 250b: insulator, 250B: insulating film, 250c: insulator, 260: conductor, 260a: conductor, 260b: conductor, 265: sealing portion, 271: insulator, 271a: insulator, 271A: insulating film, 271b: insulator, 271B: insulating layer, 271c: insulator, 274: insulator, 275: insulator, 280: insulator, 282: insulator, 283: insulator, 285: insulator, 290: memory device, 292: capacitor device, 292a: capacitor device, 292b: capacitor device, 294: conductor, 294a: conductor, 294b: conductor, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 400: opening region, 500: semiconductor device, 600: semiconductor device, 601: semiconductor device, 610: cell array, 610_n: cell array, 610_1: cell array, 700: electronic component, 702: printed circuit board, 704: circuit board, 711: mold, 712: land, 713: electrode pad, 714: wire, 720: storage device, 721: driver circuit layer, 722: storage circuit layer, 730: electronic component, 731: interposer, 732: package substrate, 733: electrode, 735: semiconductor device, 1001: wiring, 1002: wiring, 1003: wiring, 1004: wiring, 1005: wiring, 1006: wiring, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: PCB, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: storage device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell, 2700: manufacturing apparatus, 2701: atmosphere-side substrate supply chamber, 2702: atmosphere-side substrate supply chamber, 2703a: load lock chamber, 2703b: unload lock chamber, 2704: transfer chamber, 2706a: chamber, 2706b: chamber, 2706c: chamber, 2706d: chamber, 2761: cassette port, 2762: alignment port, 2763a: transfer robot, 2763b: transfer robot, 2801: gas supply source, 2802: valve, 2803: high-frequency generator, 2804: waveguide, 2805: mode converter, 2806: gas pipe, 2807: waveguide, 2808: slot antenna plate, 2809: dielectric plate, 2810: high-density plasma, 2811: substrate, 2811_n: substrate, 2811_n−1: substrate, 2811_n−2: substrate, 2811_1: substrate, 2811_2: substrate, 2811_3: substrate, 2812: substrate holder, 2813: heating mechanism, 2815: matching box, 2816: high-frequency power source, 2817: vacuum pump, 2818: valve, 2819: exhaust port, 2820: lamp, 2821: gas supply source, 2822: valve, 2823: gas inlet, 2824: substrate, 2825: substrate holder, 2826: heating mechanism, 2828: vacuum pump, 2829: valve, 2830: exhaust port, 2900: microwave treatment apparatus, 2901: quartz tube, 2902: substrate holder, 2903: heating means, 4000: deposition apparatus, 4002: carrying-in/out chamber, 4004: carrying-in/out chamber, 4006: transfer chamber, 4008: deposition chamber, 4009: deposition chamber, 4011: treatment chamber, 4014: transfer arm, 4020: chamber, 4021: source material supply portion, 4021a: source material supply portion, 4021b: source material supply portion, 4021c: source material supply portion, 4022a: high-speed valve, 4022d: high-speed valve, 4023: source material introduction port, 4024: source material exhaust port, 4025: evacuation unit, 4026: substrate holder, 4027: heater, 4028: plasma generation apparatus, 4029: coil, 4030: substrate, 4031: source material supply portion, 4032: gas supply portion, 4033: source material introduction port, 4034a: pipe heater, 4034b: pipe heater, 4100: plasma ALD apparatus, 4111: plasma generation chamber, 4120: reaction chamber, 4123: source material introduction port, 4124: source material exhaust port, 4126: substrate holder, 4128: plasma generation apparatus, 4130: substrate, 4131: plasma, 4133: source material introduction port, 4200: plasma ALD apparatus, 4213: electrode, 4214: shower head, 4215: power source, 4217: capacitor, 4220: chamber, 4223: source material introduction port, 4224: source material exhaust port, 4226: substrate holder, 4230: substrate, 4231: plasma, 4300: plasma ALD apparatus, 4313: electrode, 4314: shower head, 4315: power source, 4317: capacitor, 4319: mesh, 4320: chamber, 4321: power source, 4322: capacitor, 4323: source material introduction port, 4324: source material exhaust port, 4326: substrate holder, 4330: substrate, 4331: plasma, 4520: chamber, 4521: source material supply portion, 4521a: source material supply portion, 4521b: source material supply portion, 4521c: source material supply portion, 4522a: high-speed valve, 4522c: high-speed valve, 4522d: high-speed valve, 4523: source material introduction port, 4524: source material exhaust port, 4525: evacuation unit, 4526: substrate holder, 4527: heater, 4530: substrate, 4531: source material supply portion, 4532: gas supply portion, 4534a: pipe heater, 4534b: pipe heater, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door

1. A method for manufacturing a film of a metal oxide, comprising:
a first step of supplying a first precursor to a chamber;
a second step of supplying a second precursor to the chamber;
a third step of supplying a third precursor to the chamber; and
a fourth step of introducing an oxidizer into the chamber after each of the first step, the second step, and the third step,
wherein the first to third precursors are different kinds of substances, and
wherein a substrate placed in the chamber in the first to fourth steps is heated to a temperature higher than or equal to 300° C. and lower than or equal to a lowest temperature among decomposition temperatures of the first to third precursors.

2. A method for manufacturing a film of a metal oxide, comprising:
a first step of supplying a first precursor to a chamber;
a second step of supplying a second precursor to the chamber;
a third step of supplying a third precursor to the chamber; and
a fourth step of making an oxidizer into a plasma state and introducing the oxidizer into the chamber after each of the first step, the second step, and the third step,
wherein the first to third precursors are different kinds of substances, and
wherein a substrate placed in the chamber in the first to fourth steps is heated to a temperature higher than or equal to 300° C. and lower than or equal to a lowest temperature among decomposition temperatures of the first to third precursors.

3. The method for manufacturing a film of a metal oxide, according to claim 1,
wherein the first precursor comprises indium,
wherein the second precursor comprises an element M,
wherein the element M is one of gallium, aluminum, yttrium and tin, and
wherein the third precursor comprises zinc.

4. The method for manufacturing a film of a metal oxide, according to claim 1, wherein each of the first to third precursors is a substance that does not comprise carbon or hydrogen.

5. The method for manufacturing a film of a metal oxide, according to claim 1, wherein each of the first to third precursors comprises chlorine.

6. The method for manufacturing a film of a metal oxide, according to claim 1, wherein the method comprises a plurality of cycles each comprising each of the first to fourth steps one or more times.

7. The method for manufacturing a film of a metal oxide, according to claim 6,
wherein the first precursor comprises indium,
wherein the second precursor comprises an element M,
wherein the element M is one of gallium, aluminum, yttrium, and tin,
wherein the third precursor comprises zinc,
wherein each of the plurality of cycles comprises the first step a first number of times, the second step a second number of times, and the third step a third number of times, and
wherein a ratio of the first number to a proportion of indium in the metal oxide, a ratio of the second number to a proportion of gallium in the metal oxide, and a ratio of the third number to a proportion of the element M in the metal oxide are the same.

8. The method for manufacturing a film of a metal oxide, according to claim 6, wherein heat treatment is performed after two or more cycles in the plurality of cycles are performed.

9. A deposition apparatus comprising:
a chamber;
first to fourth source material supply portions each connected to the chamber through valves; and
a heater configured to heat a substrate placed in the chamber,
wherein the first to third source material supply portions are configured to supply different kinds of precursors from each other,
wherein the fourth source material supply portion is configured to supply an oxidizer, and
wherein the heater is configured to heat the substrate to a temperature higher than or equal to 300° C. and lower than or equal to a lowest temperature among decomposition temperatures of the precursors.

10. A deposition apparatus comprising:
a chamber;
first to fourth source material supply portions;
a heater configured to heat a substrate placed in the chamber; and
a plasma generation apparatus,
wherein each of the first to third source material supply portions is connected to the chamber through valves,
wherein the fourth source material supply portion is connected to the chamber through the plasma generation apparatus,
wherein the first to third source material supply portions are configured to supply different kinds of precursors from each other,
wherein the fourth source material supply portion is configured to supply an oxidizer, and
wherein the heater is configured to heat the substrate placed in the chamber to a temperature higher than or equal to 300° C. and lower than or equal to a lowest temperature among decomposition temperatures of the precursors.

11. The deposition apparatus according to claim 10, wherein the plasma generation apparatus comprises a coil connected to a high-frequency power source.

12. The deposition apparatus according to claim 9,
wherein the first source material supply portion is configured to supply a first precursor comprising indium,
wherein the second source material supply portion is configured to supply a second precursor comprising one of gallium, aluminum, yttrium and tin, and
wherein the third source material supply portion is configured to supply a third precursor comprising zinc.

13. The deposition apparatus according to claim 12, wherein each of the first precursor, the second precursor, and the third precursor is not a substance that does not comprise carbon or hydrogen.

14. The deposition apparatus for a metal oxide, according to claim 12, wherein the first precursor, the second precursor and the third precursor is a substance that comprises chlorine.

15. The deposition apparatus for a metal oxide, according to claim 13, further comprising a pipe heater,
wherein the pipe heater covers pipes between the chamber and each of the first to fourth source material supply portions.

16. The deposition apparatus according to claim 9, further comprising a transfer chamber and a treatment chamber,
wherein the chamber is connected to the treatment chamber through the transfer chamber,
wherein the transfer chamber comprises a transfer arm configured to transfer a substrate from the chamber to the treatment chamber, and
wherein the treatment chamber comprises a heating apparatus.
